(19) United States
(12) Patent Application Publication
(10) Pub. No.: US 2026/0262308 A1
(43) Pub. Date: Sep. 3, 2026

(54) IMAGING ELEMENT AND ELECTRONIC DEVICE

(71) Applicant: SONY SEMICONDUCTOR SOLUTIONS CORPORATION, Kanagawa (JP)

(72) Inventors: Yasuhiro EBIHARA, Kanagawa (JP); Chihiro TOMITA, Kanagawa (JP); Koki TACHIYAMA, Tokyo (JP); Akito SHIMIZU, Kanagawa (JP); Ryota OKUNO, Kanagawa (JP)

(73) Assignee: SONY SEMICONDUCTOR SOLUTIONS CORPORATION, Kanagawa (JP)

(21) Appl. No.: 18/875,360

(22) PCT Filed: Jun. 23, 2023
(86) PCT No.: PCT/JP2023/023387

§ 371 Date: Dec. 16, 2024

(30) Foreign Application Priority Data
Jun. 24, 2022 (JP) 2022-102268

(51) Int. Cl. H10F 39/00; H10F 39/18

(52) U.S. Cl. CPC H10F 39/8037; H10F 39/182; H10F 39/802; H10F 39/807; H10F 39/811

(57) ABSTRACT

The size (occupied area) of each of a plurality of pixels arranged in an imaging element is easily reduced. The imaging element includes pixels and signal generation sections. A pixel included in the imaging element includes: a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate. A signal generation section included in the imaging element generates a pixel signal that is a signal corresponding to the charge held in the charge holding section.

### FIELD

The present disclosure relates to an imaging element and an electronic device.

### BACKGROUND

Imaging elements of a complementary metal oxide semiconductor (CMOS) type, in which a plurality of pixels is arranged, are used. In a pixel, a photoelectric conversion section that performs photoelectric conversion of incident light and a charge holding section that holds a charge generated by photoelectric conversion are arranged. A signal corresponding to the charge held in the charge holding section is generated and output as an image signal. In such an imaging element, an imaging element in which a photoelectric conversion section is formed in the vicinity of a back surface of a semiconductor substrate and a charge holding section is formed on a front surface of the semiconductor substrate is proposed (see, for example, Patent Literature 1).

In the above-described imaging element, the photoelectric conversion section performs, for each pixel, photoelectric conversion of incident light, with which the back side of the semiconductor substrate is irradiated, to generate a charge. This charge is transferred to a charge holding section (floating diffusion region) formed on the front surface of the semiconductor substrate, and a signal is generated by a circuit of the pixel.

### CITATION LIST

### Patent Literature

Patent Literature 1: JP 2021-077870 A

### SUMMARY

### Technical Problem

However, in the above-described technology in the related art, since the charge holding sections and the pixel circuit are arranged on the front surface of the semiconductor substrate, there is a problem that miniaturization is difficult.

Therefore, the present disclosure proposes an imaging element and an electronic device that are easily miniaturized.

### Solution to Problem

An imaging element according to the present disclosure includes pixels and signal generation sections. A pixel includes a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate. A signal generation section generates a pixel signal, the pixel signal corresponding to the charge held in the charge holding section.

Furthermore, an imaging element according to the present disclosure includes pixels, pixel circuits, semiconductor regions and second embedded electrodes. A pixel includes a photoelectric conversion section that performs photoelectric conversion of incident light, the photoelectric conversion section formed in a semiconductor substrate with a wiring region disposed adjacent to the semiconductor substrate. A pixel circuit generates a signal based on a charge generated by the photoelectric conversion. A semiconductor region is disposed adjacent to a side surface of an opening formed in the semiconductor substrate at a boundary of the pixel and apart from a surface of the semiconductor substrate with which the wiring region is in contact. A second embedded electrode is disposed in the opening and apart from the surface of the semiconductor substrate with which the wiring region is in contact, the second embedded electrode connected to the semiconductor region.

Furthermore, an electronic device according to the present disclosure includes pixels, signal generation sections and a processing circuit. A pixel includes a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate. A signal generation section generates a pixel signal, the pixel signal corresponding to the charge held in the charge holding section. A processing circuit processes the pixel signal generated.

### BRIEF DESCRIPTION OF DRAWINGS

FIG. 1 is a diagram illustrating a configuration example of an imaging element according to an embodiment of the present disclosure.

FIG. 2 is a circuit diagram illustrating a configuration example of a pixel block according to a first embodiment of the present disclosure.

FIG. 3 is a diagram illustrating a structure example of the pixel block according to the first embodiment of the present disclosure.

FIG. 4 is a diagram illustrating a structure example of the pixel block according to the first embodiment of the present disclosure.

FIG. 5 is a diagram illustrating a structure example of the pixel block according to the first embodiment of the present disclosure.

FIG. 6 is a diagram illustrating a structure example of the pixel block according to the first embodiment of the present disclosure.

FIG. 7A is a diagram illustrating an example of a manufacturing method of an imaging element according to the first embodiment of the disclosure.

FIG. 7B is a diagram illustrating an example of the manufacturing method of the imaging element according to the first embodiment of the disclosure.

FIG. 7C is a diagram illustrating an example of the manufacturing method of the imaging element according to the first embodiment of the disclosure.

FIG. 7D is a diagram illustrating an example of the manufacturing method of the imaging element according to the first embodiment of the disclosure.

FIG. 7E is a diagram illustrating an example of the manufacturing method of the imaging element according to the first embodiment of the disclosure.

FIG. 7F is a diagram illustrating an example of the manufacturing method of the imaging element according to the first embodiment of the disclosure.

FIG. 7G is a diagram illustrating an example of the manufacturing method of the imaging element according to the first embodiment of the disclosure.

FIG. 7H is a diagram illustrating an example of the manufacturing method of the imaging element according to the first embodiment of the disclosure.

FIG. 7I is a diagram illustrating an example of the manufacturing method of the imaging element according to the first embodiment of the disclosure.

FIG. 7J is a diagram illustrating an example of the manufacturing method of the imaging element according to the first embodiment of the disclosure.

FIG. 7K is a diagram illustrating an example of the manufacturing method of the imaging element according to the first embodiment of the disclosure.

FIG. 7L is a diagram illustrating an example of the manufacturing method of the imaging element according to the first embodiment of the disclosure.

FIG. 8 is a diagram illustrating a structure example of a pixel block according to a first modification of the first embodiment of the disclosure.

FIG. 9 is a diagram illustrating a structure example of the pixel block according to a second modification of the first embodiment of the present disclosure.

FIG. 10 is a diagram illustrating a structure example of the pixel block according to the second modification of the first embodiment of the disclosure.

FIG. 11A is a diagram illustrating a structure example of a pixel block according to a third modification of the first embodiment of the disclosure.

FIG. 11B is a diagram illustrating a structure example of the pixel block according to the third modification of the first embodiment of the disclosure.

FIG. 12A is a diagram illustrating a structure example of a pixel block according to a fourth modification of the first embodiment of the disclosure.

FIG. 12B is a diagram illustrating a structure example of the pixel block according to the fourth modification of the first embodiment of the disclosure.

FIG. 13A is a diagram illustrating a structure example of a pixel block according to a fifth modification of the first embodiment of the disclosure.

FIG. 13B is a diagram illustrating a structure example of the pixel block according to the fifth modification of the first embodiment of the disclosure.

FIG. 14 is a diagram illustrating a structure example of a pixel block according to a sixth modification of the first embodiment of the disclosure.

FIG. 15 is a diagram illustrating a structure example of a pixel block according to a second embodiment of the present disclosure.

FIG. 16A is a diagram illustrating an example of a manufacturing method of an imaging element according to the second embodiment of the disclosure.

FIG. 16B is a diagram illustrating an example of the manufacturing method of the imaging element according to the second embodiment of the disclosure.

FIG. 16C is a diagram illustrating an example of the manufacturing method of the imaging element according to the second embodiment of the disclosure.

FIG. 16D is a diagram illustrating an example of the manufacturing method of the imaging element according to the second embodiment of the disclosure.

FIG. 16E is a diagram illustrating an example of the manufacturing method of the imaging element according to the second embodiment of the disclosure.

FIG. 16F is a diagram illustrating an example of the manufacturing method of the imaging element according to the second embodiment of the disclosure.

FIG. 16G is a diagram illustrating an example of the manufacturing method of the imaging element according to the second embodiment of the disclosure.

FIG. 16H is a diagram illustrating an example of the manufacturing method of the imaging element according to the second embodiment of the disclosure.

FIG. 16I is a diagram illustrating an example of the manufacturing method of the imaging element according to the second embodiment of the disclosure.

FIG. 16J is a diagram illustrating an example of the manufacturing method of the imaging element according to the second embodiment of the disclosure.

FIG. 16K is a diagram illustrating an example of the manufacturing method of the imaging element according to the second embodiment of the disclosure.

FIG. 16L is a diagram illustrating an example of the manufacturing method of the imaging element according to the second embodiment of the disclosure.

FIG. 16M is a diagram illustrating an example of the manufacturing method of the imaging element according to the second embodiment of the disclosure.

FIG. 17 is a diagram illustrating a structure example of a pixel according to a third embodiment of the disclosure.

FIG. 18A is a diagram illustrating an example of a manufacturing method of an imaging element according to the third embodiment of the disclosure.

FIG. 18B is a diagram illustrating an example of the manufacturing method of the imaging element according to the third embodiment of the disclosure.

FIG. 18C is a diagram illustrating an example of the manufacturing method of the imaging element according to the third embodiment of the disclosure.

FIG. 18D is a diagram illustrating an example of the manufacturing method of the imaging element according to the third embodiment of the disclosure.

FIG. 18E is a diagram illustrating an example of the manufacturing method of the imaging element according to the third embodiment of the disclosure.

FIG. 19 is a diagram illustrating a structure example of a pixel according to a fourth embodiment of the disclosure.

FIG. 20A is a diagram illustrating an example of a manufacturing method of an imaging element according to the fourth embodiment of the disclosure.

FIG. 20B is a diagram illustrating an example of the manufacturing method of the imaging element according to the fourth embodiment of the disclosure.

FIG. 20C is a diagram illustrating an example of the manufacturing method of the imaging element according to the fourth embodiment of the disclosure.

FIG. 20D is a diagram illustrating an example of the manufacturing method of the imaging element according to the fourth embodiment of the disclosure.

FIG. 20E is a diagram illustrating an example of the manufacturing method of the imaging element according to the fourth embodiment of the disclosure.

FIG. 20F is a diagram illustrating an example of the manufacturing method of the imaging element according to the fourth embodiment of the disclosure.

FIG. 20G is a diagram illustrating an example of the manufacturing method of the imaging element according to the fourth embodiment of the disclosure.

FIG. 20H is a diagram illustrating an example of the manufacturing method of the imaging element according to the fourth embodiment of the disclosure.

FIG. 20I is a diagram illustrating an example of the manufacturing method of the imaging element according to the fourth embodiment of the disclosure.

FIG. 20J is a diagram illustrating an example of the manufacturing method of the imaging element according to the fourth embodiment of the disclosure.

FIG. 20K is a diagram illustrating an example of the manufacturing method of the imaging element according to the fourth embodiment of the disclosure.

FIG. 21A is a diagram illustrating a structure example of a pixel according to a first modification of the second embodiment of the disclosure.

FIG. 21B is a diagram illustrating a structure example of a pixel according to a second modification of the second embodiment of the disclosure.

FIG. 21C is a diagram illustrating a structure example of a pixel according to a third modification of the second embodiment of the disclosure.

FIG. 21D is a diagram illustrating a structure example of a pixel according to a fourth modification of the second embodiment of the disclosure.

FIG. 21E is a diagram illustrating a structure example of a pixel according to a fifth modification of the second embodiment of the disclosure.

FIG. 22 is a diagram illustrating a structure example of a pixel block according to a fifth embodiment of the present disclosure.

FIG. 23A is a diagram illustrating a structure example of the pixel block according to the fifth embodiment of the disclosure.

FIG. 23B is a diagram illustrating a structure example of the pixel block according to the fifth embodiment of the disclosure.

FIG. 23C is a diagram illustrating a structure example of the pixel block according to the fifth embodiment of the disclosure.

FIG. 24A is a diagram illustrating an example of a manufacturing method of an imaging element according to the fifth embodiment of the disclosure.

FIG. 24B is a diagram illustrating an example of the manufacturing method of the imaging element according to the fifth embodiment of the disclosure.

FIG. 24C is a diagram illustrating an example of the manufacturing method of the imaging element according to the fifth embodiment of the disclosure.

FIG. 25A is a diagram illustrating an example of the manufacturing method of the imaging element according to the fifth embodiment of the disclosure.

FIG. 25B is a diagram illustrating an example of the manufacturing method of the imaging element according to the fifth embodiment of the disclosure.

FIG. 25C is a diagram illustrating an example of the manufacturing method of the imaging element according to the fifth embodiment of the disclosure.

FIG. 26A is a diagram illustrating an example of the manufacturing method of the imaging element according to the fifth embodiment of the disclosure.

FIG. 26B is a diagram illustrating an example of the manufacturing method of the imaging element according to the fifth embodiment of the disclosure.

FIG. 26C is a diagram illustrating an example of the manufacturing method of the imaging element according to the fifth embodiment of the disclosure.

FIG. 27A is a diagram illustrating an example of the manufacturing method of the imaging element according to the fifth embodiment of the disclosure.

FIG. 27B is a diagram illustrating an example of the manufacturing method of the imaging element according to the fifth embodiment of the disclosure.

FIG. 27C is a diagram illustrating an example of the manufacturing method of the imaging element according to the fifth embodiment of the disclosure.

FIG. 28A is a diagram illustrating an example of the manufacturing method of the imaging element according to the fifth embodiment of the disclosure.

FIG. 28B is a diagram illustrating an example of the manufacturing method of the imaging element according to the fifth embodiment of the disclosure.

FIG. 28C is a diagram illustrating an example of the manufacturing method of the imaging element according to the fifth embodiment of the disclosure.

FIG. 29A is a diagram illustrating an example of the manufacturing method of the imaging element according to the fifth embodiment of the disclosure.

FIG. 29B is a diagram illustrating an example of the manufacturing method of the imaging element according to the fifth embodiment of the disclosure.

FIG. 29C is a diagram illustrating an example of the manufacturing method of the imaging element according to the fifth embodiment of the disclosure.

FIG. 30A is a diagram illustrating an example of the manufacturing method of the imaging element according to the fifth embodiment of the disclosure.

FIG. 30B is a diagram illustrating an example of the manufacturing method of the imaging element according to the fifth embodiment of the disclosure.

FIG. 30C is a diagram illustrating an example of the manufacturing method of the imaging element according to the fifth embodiment of the disclosure.

FIG. 31A is a diagram illustrating an example of the manufacturing method of the imaging element according to the fifth embodiment of the disclosure.

FIG. 31B is a diagram illustrating an example of the manufacturing method of the imaging element according to the fifth embodiment of the disclosure.

FIG. 31C is a diagram illustrating an example of the manufacturing method of the imaging element according to the fifth embodiment of the disclosure.

FIG. 32A is a diagram illustrating an example of the manufacturing method of the imaging element according to the fifth embodiment of the disclosure.

FIG. 32B is a diagram illustrating an example of the manufacturing method of the imaging element according to the fifth embodiment of the disclosure.

FIG. 32C is a diagram illustrating an example of the manufacturing method of the imaging element according to the fifth embodiment of the disclosure.

FIG. 33A is a diagram illustrating an example of the manufacturing method of the imaging element according to the fifth embodiment of the disclosure.

FIG. 33B is a diagram illustrating an example of the manufacturing method of the imaging element according to the fifth embodiment of the disclosure.

FIG. 33C is a diagram illustrating an example of the manufacturing method of the imaging element according to the fifth embodiment of the disclosure.

FIG. 34A is a diagram illustrating an example of the manufacturing method of the imaging element according to the fifth embodiment of the disclosure.

FIG. 34B is a diagram illustrating an example of the manufacturing method of the imaging element according to the fifth embodiment of the disclosure.

FIG. 34C is a diagram illustrating an example of the manufacturing method of the imaging element according to the fifth embodiment of the disclosure.

FIG. 35 is a diagram illustrating a structure example of a pixel block according to a first modification of the fifth embodiment of the disclosure.

FIG. 36 is a diagram illustrating a structure example of the pixel block according to the first modification of the fifth embodiment of the disclosure.

FIG. 37A is a diagram illustrating a structure example of a pixel block according to a second modification of the fifth embodiment of the disclosure.

FIG. 37B is a diagram illustrating a structure example of the pixel block according to the second modification of the fifth embodiment of the disclosure.

FIG. 38 is a diagram illustrating a structure example of a pixel block according to a third modification of the fifth embodiment of the disclosure.

FIG. 39 is a diagram illustrating a structure example of a pixel block according to a fourth modification of the fifth embodiment of the disclosure.

FIG. 40A is a diagram illustrating a structure example of the pixel block according to the fourth modification of the fifth embodiment of the disclosure.

FIG. 40B is a diagram illustrating a structure example of the pixel block according to the fourth modification of the fifth embodiment of the disclosure.

FIG. 41 is a diagram illustrating a structure example of a pixel block according to a fifth modification of the fifth embodiment of the disclosure.

FIG. 42 is a diagram illustrating a structure example of a pixel block according to a sixth modification of the fifth embodiment of the disclosure.

FIG. 43 is a diagram illustrating another configuration example of an imaging element.

FIG. 44 is a cross-sectional view illustrating another configuration example of the imaging element.

FIG. 45 is a diagram illustrating an example of a schematic configuration of an imaging system including an imaging device according to one of the embodiments and the modifications thereof.

FIG. 46 is a diagram illustrating an example of an imaging procedure of the imaging system illustrated in FIG. 45.

FIG. 47 is a block diagram depicting an example of schematic configuration of a vehicle control system.

FIG. 48 is a diagram of assistance in explaining an example of installation positions of an outside-vehicle information detecting section and an imaging section.

FIG. 49 is a view depicting an example of a schematic configuration of an endoscopic surgery system.

FIG. 50 is a block diagram depicting an example of a functional configuration of a camera head and a camera control unit (CCU).

### DESCRIPTION OF EMBODIMENTS

Hereinafter, embodiments of the present disclosure will be described in detail on the basis of the drawings. Description will be given in the following order. Note that in each of the following embodiments, the same parts are denoted by the same symbols, and redundant description will be omitted.
1. First Embodiment
2. Modifications of First Embodiment
3. Second Embodiment
4. Third Embodiment
5. Fourth Embodiment
6. Modifications of Second Embodiment
7. Fifth Embodiment
8. Modifications of Fifth Embodiment
9. Other Configuration Examples
10. Application Examples
11. Application Example to Mobile Body
12. Application Example to Endoscopic Surgery System

### 1. First Embodiment

### [Configuration of Imaging Element]

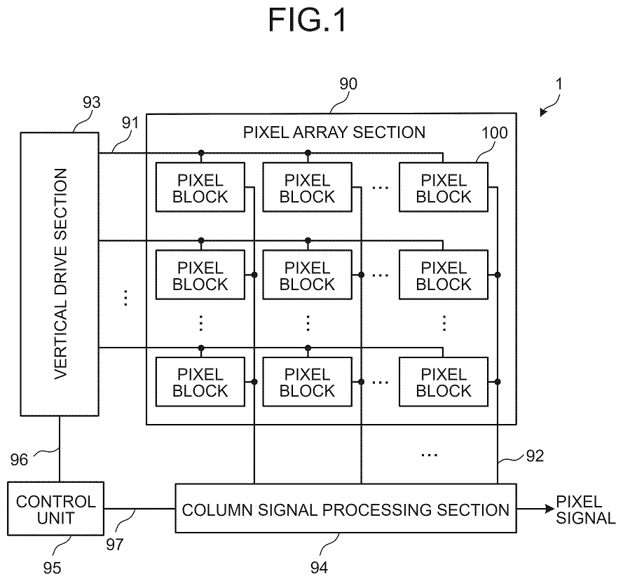

FIG. 1 is a diagram illustrating a configuration example of an imaging element according to an embodiment of the present disclosure. The drawing is a block diagram illustrating a configuration example of an imaging element 1. An electronic device according to an embodiment of the present disclosure will be described by taking the imaging element 1 as an example. The imaging element 1 is a semiconductor element that generates image data of a subject. The imaging element 1 includes a pixel array section 90, a vertical drive section 93, a column signal processing section 94, and a control unit 95.

The pixel array section 90 includes a plurality of pixel blocks 100 arranged therein. In the pixel array section 90, a plurality of pixel blocks 100 is arranged in a shape of a two-dimensional matrix. In this example, a pixel block 100 includes: a plurality of pixels having a photoelectric conversion section that performs photoelectric conversion of incident light; and a charge holding section (charge holding sections 103a to 103d to be described later) that holds a charge generated by the photoelectric conversion. For example, a photodiode can be used for the photoelectric conversion section. Furthermore, a pixel circuit (pixel circuit 120 to be described later) is disposed in each of the pixel blocks 100. The pixel circuit 120 generates a pixel signal on the basis of a charge held in charge holding sections 103a to 103d of the pixel block 100.

A signal line 91 is wired to each of the pixel blocks 100. The pixel block 100 is controlled by a control signal transmitted by the signal line 91. Furthermore, a signal line 92 is wired in the pixel block 100. A pixel signal is output from the pixel block 100 to the signal line 92. Note that a signal line 91 is disposed for each of rows shaping a two-dimensional matrix and is wired in a shared manner to a plurality of pixel blocks 100 arranged in one row. A signal line 92 is disposed in the column direction of the two-dimensional matrix and is wired in a shared manner to a plurality of pixel blocks 100 arranged in one column.

The vertical drive section 93 generates control signals for the pixel blocks 100 described above. The vertical drive section 93 in the drawing generates a control signal for each of the rows of the two-dimensional matrix of the pixel array section 90 and sequentially outputs the control signals via a signal line 91.

The column signal processing section 94 processes a pixel signal generated by a pixel block 100. The column signal processing section 94 in the drawing simultaneously processes pixel signals from a plurality of pixel blocks 100 arranged in one row of the pixel array section 90 transmitted via a signal line 92. As this processing, for example, analog-digital conversion for converting an analog pixel signal generated by a pixel block 100 into a digital pixel signal or correlated double sampling (CDS) for removing an offset error of the pixel signal can be performed. The processed pixel signal is output to a circuit or the like outside the imaging element 1.

The control unit 95 controls the vertical drive section 93 and the column signal processing section 94. The control unit 95 in the drawing outputs control signals via each of signal lines 96 and 97 to control the vertical drive section 93 and the column signal processing section 94. Note that the pixel array section 90 in the drawing is an example of an imaging element. The column signal processing section 94 is an example of the processing circuit. Furthermore, the imaging element 1 in the drawing is an example of the electronic device.

### [Configuration of Pixel]

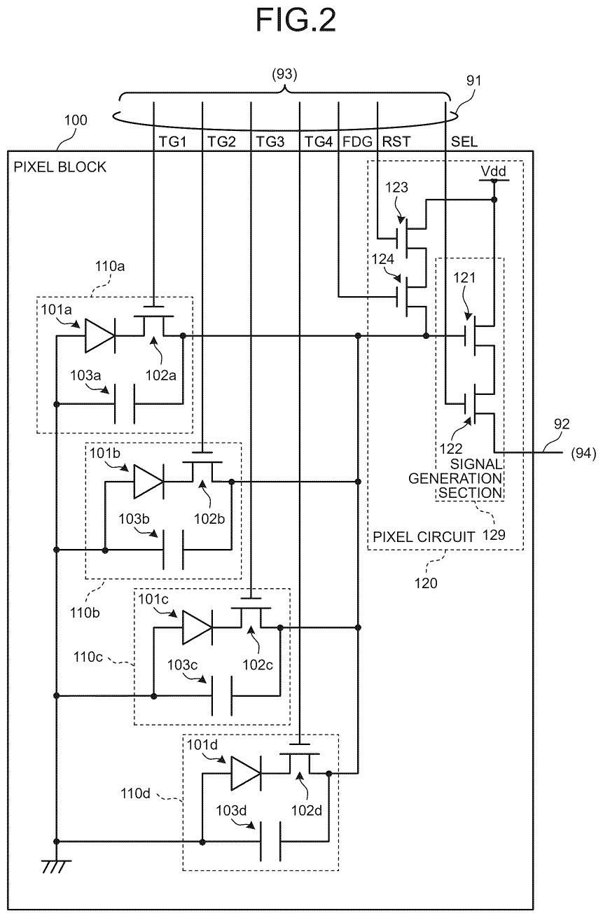

FIG. 2 is a circuit diagram illustrating a configuration example of a pixel block according to a first embodiment of the present disclosure. The drawing is a circuit diagram illustrating a configuration example of a pixel block 100. The pixel block 100 in the drawing includes pixels 110a to 110d and a pixel circuit 120.

The pixel 110a includes a photoelectric conversion section 101a, a charge transfer section 102a, and a charge holding section 103a. The pixel 110b includes a photoelectric conversion section 101b, a charge transfer section 102b, and a charge holding section 103b. The pixel 110c includes a photoelectric conversion section 101c, a charge transfer section 102c, and a charge holding section 103c. The pixel 110d includes a photoelectric conversion section 101d, a charge transfer section 102d, and a charge holding section 103d. A photodiode can be used for the photoelectric conversion sections 101a to 101d. An n-channel MOS transistor can be used for the charge transfer sections 102a to 102d.

The pixel circuit 120 includes a reset transistor 123, a coupling transistor 124, an amplification transistor 121, and a selection transistor 122. An n-channel MOS transistor can be used for the reset transistor 123, the coupling transistor 124, the amplification transistor 121, and the selection transistor 122.

As described above, the signal line 91 and the signal line 92 are wired in the pixel block 100. The signal line 91 in the drawing includes a signal line TG1 to TG4, a signal line FDG, a signal line RST, and a signal line SEL. In addition, a power supply line Vdd is wired in the pixel block 100. The power supply line Vdd supplies power to the pixel block 100.

An anode of the photoelectric conversion section 101a is grounded, and a cathode is connected to a source of the charge transfer section 102a. An anode of the photoelectric conversion section 101b is grounded, and a cathode is connected to a source of the charge transfer section 102b. An anode of the photoelectric conversion section 101c is grounded, and a cathode is connected to a source of the charge transfer section 102c. An anode of the photoelectric conversion section 101d is grounded, and a cathode is connected to a source of the charge transfer section 102d.

Drains of the charge transfer sections 102a to 102d are connected to a source of the coupling transistor 124, a gate of the amplification transistor 121, and first ends of the charge holding sections 103a to 103d. Second ends of the charge holding sections 103a to 103d are grounded. A drain of the coupling transistor 124 is connected to a source of the reset transistor 123. A drain of the reset transistor 123 and a drain of the amplification transistor 121 are connected to the power supply line Vdd. A source of the amplification transistor 121 is connected to a drain of the selection transistor 122, and a source of the selection transistor 122 is connected to the signal line 92.

Gates of the charge transfer sections 102a to 102d are connected to the signal lines TG1 to TG4, respectively. A gate of the coupling transistor 124 is connected to the signal line FDG, a gate of the reset transistor 123 is connected to the signal line RST, and a gate of the selection transistor 122 is connected to the signal line SEL.

The photoelectric conversion sections 101a to 101d perform photoelectric conversion of incident light. The photoelectric conversion sections 101a to 101d can include a photodiode formed on a semiconductor substrate 130 to be described later. The photoelectric conversion sections 101a to 101d perform photoelectric conversion of incident light in an exposure period and hold a charge generated by the photoelectric conversion.

The charge holding sections 103a to 103d hold a charge generated by the photoelectric conversion sections 101a to 101d, respectively. The charge holding sections 103a to 103d can include a floating diffusion (FD) region which is a semiconductor region formed in the semiconductor substrate 130.

The charge transfer sections 102a to 102d transfer a charge. The charge transfer sections 102a to 102d transfer the charge generated by the photoelectric conversion sections 101a to 101d to the charge holding sections 103a to 103d, respectively. The charge transfer section 102a and others transfer a charge by electrically connecting the photoelectric conversion section 101a and others to the charge holding section 103 and others, respectively. Control signals for the charge transfer sections 102a to 102d are transmitted by the signal lines TG1 to TG4, respectively.

The pixel circuit 120 generates a pixel signal on the basis of charges held by the charge holding sections 103a to 103d. As described above, the pixel circuit 120 includes the coupling transistor 124, the reset transistor 123, the amplification transistor 121, and the selection transistor 122.

The coupling transistor 124 couples the capacitance connected to the drain thereof to the charge holding sections 103a to 103d. By this coupling of the capacitance, the holding capacitance of the charge holding section 103a and others can be increased, and the sensitivity of the pixel 110a and others can be switched. A control signal for the coupling transistor 124 is transmitted by the signal line FDG.

The reset transistor 123 resets the charge holding sections 103a to 103d. This reset can be performed by discharging the charges of the charge holding sections 103a to 103d by electrically connecting the charge holding sections 103a to 103d and the power supply line Vdd. At the time of this reset, the above-described coupling transistor 124 is made conductive. A control signal for the reset transistor 123 is transmitted by the signal line RST.

The amplification transistor 121 amplifies the voltage of the charge holding sections 103a to 103d. The gate of the amplification transistor 121 is connected to the charge holding sections 103a to 103d. Therefore, a pixel signal having a voltage corresponding to the charge held in the charge holding sections 103a to 103d is generated at the source of the amplification transistor 121. Furthermore, the pixel signal can be output to the signal line 92 by making the selection transistor 122 conductive. A control signal for the selection transistor 122 is transmitted by the signal line SEL.

The photoelectric conversion sections 101a to 101d perform photoelectric conversion of incident light during an exposure period to generate a charge and accumulates the charge in itself. After the lapse of the exposure period, the charge transfer sections 102a to 102d transfers the charges of the photoelectric conversion sections 101a to 101d to the charge holding sections 103a to 103d to be held therein. A pixel signal is generated by the pixel circuit 120 on the basis of the charges that are held. Note that a circuit including the amplification transistor 121 and the selection transistor 122 constitutes a signal generation section 129.

### [Configuration of Pixel]

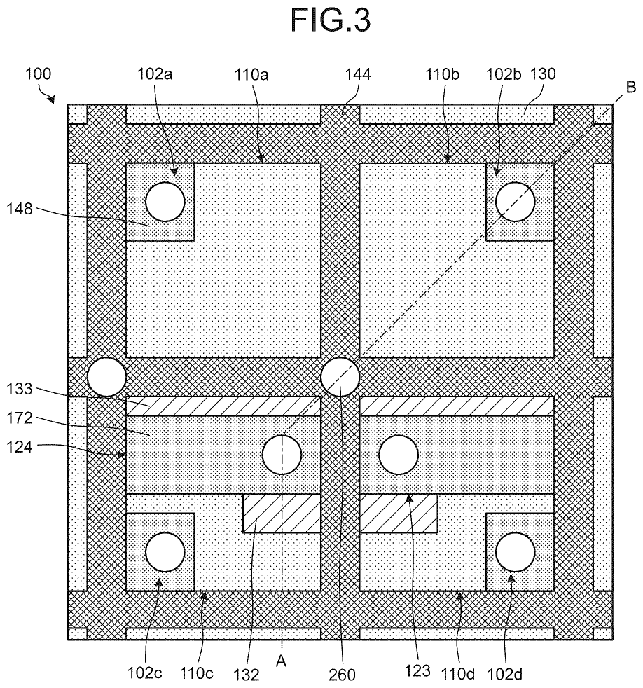

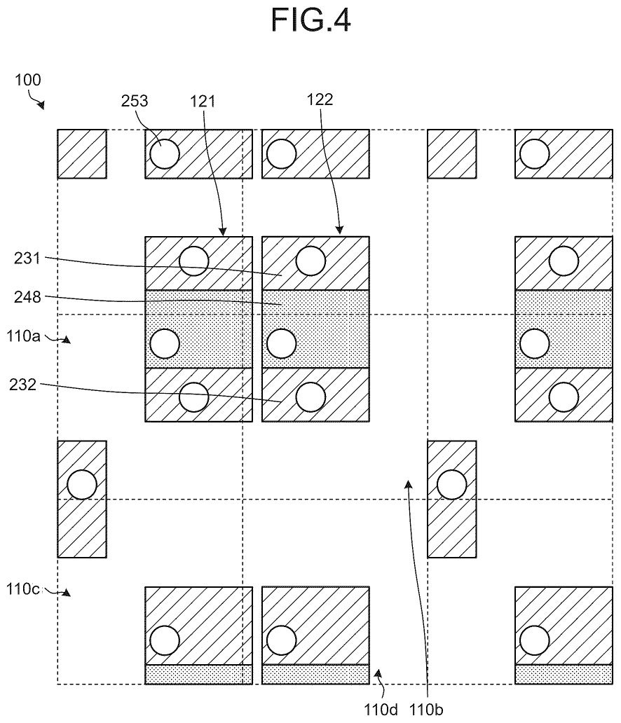

FIGS. 3 and 4 are diagrams illustrating a structure example of a pixel block according to the first embodiment of the present disclosure. FIG. 3 is a plan view illustrating a configuration example of the pixels 110a to 110d in the pixel block 100. The pixels 110a to 110d are formed on the semiconductor substrate 130. FIG. 3 is a diagram illustrating a configuration of the pixel 110a and others on the front side of the semiconductor substrate 130. The pixels 110a to 110d are structured to have a square shape in plan view. An isolation section 144 is arranged at boundaries between the pixels 110a to 110d.

Note that a hollow circle in the drawing represents a through wire 260. The through wire 260 is disposed through a semiconductor substrate (semiconductor substrate 230 to be described later) stacked on the semiconductor substrate 130. The through wire 260 disposed at the center of the drawing is commonly connected to the charge holding sections 103a to 103d (not illustrated). In addition, a through wire 260 disposed at the left end in the drawing is connected to a well region of the semiconductor substrate 130. As will be described later, the photoelectric conversion section 101 is formed in the vicinity of the back surface of the semiconductor substrate 130.

The charge transfer sections 102a to 102d are arranged at the respective pixels 110a to 110d. In FIG. 3, gate electrodes 148 of the MOS transistors included in the charge transfer section 102a and others are illustrated. The coupling transistor 124 is disposed in the pixel 110c. The coupling transistor 124 of FIG. 3 includes a semiconductor region 133 constituting a drain, a semiconductor region 132 constituting a source, and a gate electrode 172. Furthermore, the reset transistor 123 is disposed in the pixel 110d. Like the coupling transistor 124, the reset transistor 123 also includes semiconductor regions, which constitute a drain and a source, and a gate electrode.

FIG. 4 is a diagram illustrating a structure example of the pixels according to the first embodiment of the disclosure. The drawing is a diagram illustrating an arrangement example of the amplification transistor 121 and the selection transistor 122 arranged on the semiconductor substrate 230. The selection transistor 122 in the drawing includes a semiconductor region 231 constituting a drain, a semiconductor region 232 constituting a source, and a gate electrode 248. Like the selection transistor 122, the amplification transistor 121 also includes semiconductor regions, which constitute a drain and a source, and a gate electrode.

As illustrated in the drawing, the amplification transistor 121 and the selection transistor 122 can be structured to have a larger size than that of the reset transistor 123 in FIG. 3.

### [Structure of Cross-Section of Pixel]

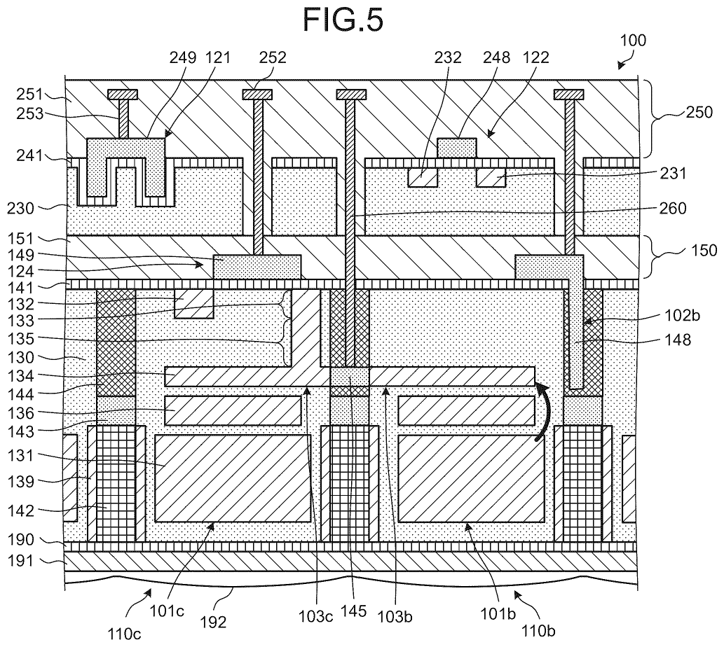

FIG. 5 is a diagram illustrating a structure example of the pixel block according to the first embodiment of the disclosure. The drawing is a cross-sectional view illustrating a structure example of the pixel block 100 in the pixel array section 90. The pixel block 100 in the drawing includes the semiconductor substrate 130, a wiring region 150, the semiconductor substrate 230, a wiring region 250, a color filter 191, and an on-chip lens 192. Note that the pixels 110b and 110c are illustrated in the drawing. The structure of the pixel block 100 will be described by taking the portion of the pixel 110c as an example. Note that the drawing schematically illustrates the shape of a cross section taken along line A-B in FIG. 3.

The semiconductor substrate 130 is a semiconductor substrate in which the photoelectric conversion section 101b and others are arranged. The semiconductor substrate 130 can be made of silicon (Si), for example. The photoelectric conversion section 101b is disposed in a well region formed in the semiconductor substrate 130. For convenience, it is based on the premise that the semiconductor substrate 130 in the drawing includes a p-type well region. An element (diffusion layer thereof) can be formed by arranging n-type and p-type semiconductor region in the p-type well region. A rectangle illustrated in the semiconductor substrate 130 in the drawing represents a semiconductor region.

An isolation section 142 and the isolation section 144 are arranged in the semiconductor substrate 130 at the boundaries between the pixels 110a to 110d. These electrically and optically separate the pixels 110 from each other. The isolation section 144 is an isolation section disposed on the front side of the semiconductor substrate 130. The isolation section 144 can be made of, for example, silicon oxide (SiO₂).

The isolation section 142 is an isolation section disposed on the back side of the semiconductor substrate 130. The isolation section 142 can be made of, for example, polycrystalline silicon. A semiconductor region 139 is disposed around the isolation section 142. The semiconductor region 139 is a p-type semiconductor region having a relatively high impurity concentration. By disposing the semiconductor region 139, the surface level of the semiconductor substrate 130 can be pinned. Note that a fixed charge film may be disposed between the semiconductor region 139 and the isolation section 142. The fixed charge film is a film made of a dielectric having a negative fixed charge. A hole accumulation region can be formed in the vicinity of the interface of the semiconductor substrate 130 by the negative fixed charge, whereby the influence of the interface state of the semiconductor substrate 130 can be reduced. This fixed charge film can be made of, for example, hafnium oxide (HfO₂), aluminum oxide (Al₂O₃), or tantalum oxide (Ta₂O₅).

An embedded electrode 143 embedded in the semiconductor substrate 130 is disposed between the isolation sections 142 and 144. The embedded electrode 143 is connected to a well region in the vicinity of a photoelectric conversion section 101 of the semiconductor substrate 130 and supplies a reference potential to the well region. A reference potential is transmitted to the embedded electrode 143 by a through wire 260 (not illustrated).

A photoelectric conversion section 101 includes an n-type semiconductor region 131. Specifically, a photodiode including a p-n junction formed at an interface between the n-type semiconductor region 131 and the surrounding p-type well region corresponds to a photoelectric conversion section 101.

A charge holding section 103 includes an n-type semiconductor region 134 having a relatively high impurity concentration. The n-type semiconductor region 134 is referred to as a floating diffusion region. The charge holding section 103 in the drawing is structured in a shape embedded in a well region formed in the semiconductor substrate 130. The charge holding sections 103a, 103b, and 103d of other pixels (pixels 110a, 110b, and 110d) are similarly structured in a shape embedded in the well region of the semiconductor substrate 130.

These charge holding sections 103a to 103d are commonly connected by a charge holding section common electrode 145. The charge holding section common electrode 145 has a shape embedded in the isolation section 144 disposed at the boundary between the pixels 110. The charge holding section common electrode 145 can be made of, for example, polycrystalline silicon containing an impurity.

The coupling transistor 124 is disposed in the pixel 110c. The coupling transistor 124 in the drawing includes the semiconductor regions 132 and 133 and the gate electrode 149 described above. The semiconductor region 133 constituting the source of the coupling transistor 124 and the charge holding section 103c are connected by a charge holding section connecting section 135. Similarly to the charge holding section 103c, the charge holding section connecting section 135 can be constituted by a semiconductor region having a relatively high impurity concentration.

An element isolation region 136 is disposed between the semiconductor region 131 included in the photoelectric conversion section 101 and the charge holding section 103. The element isolation region 136 can be constituted by, for example, a p-type semiconductor region having a relatively high impurity concentration.

Furthermore, the charge transfer section 102 is disposed in proximity to the isolation section 142 at a corner portion of the pixel 110. The charge transfer section 102 includes a MOS transistor that transfers a charge in the thickness direction of the semiconductor substrate 130. As described above, the charge transfer section 102 includes the gate electrode 148. The gate electrode 148 includes a columnar portion partially embedded in the isolation section 142 and having a depth reaching the vicinity of the charge holding section 103. When an ON voltage is applied to the gate electrode 148, a channel is formed in a well region adjacent to the gate electrode 148, and the photoelectric conversion section 101 and the charge holding section 103 are electrically connected to each other. As a result, the charge accumulated in the photoelectric conversion section 101 is transferred to the charge holding section 103. A bold arrow in the drawing indicates this transfer. As described above, the charge transfer section 102 is structured in a shape embedded in the semiconductor substrate 130. Note that the gate electrode 148 can be made of polycrystalline silicon containing an impurity.

Insulating films 141 and 190 are disposed on the front surface and the back surface of the semiconductor substrate 130, respectively. The insulating films 141 and 190 can be made of, for example, silicon oxide (SiO₂) or silicon nitride (SiN). Note that the insulating film is also disposed between the gate electrode 149 and the semiconductor substrate 130. The insulating film corresponds to a gate insulating film.

The wiring region 150 is disposed on the front surface of the semiconductor substrate 130 and is a region in which wiring that transmits a signal or the like of an element is disposed. The wiring region 150 in the drawing includes an insulating layer 151. The insulating layer 151 insulates the gate electrode 149, wiring, and others arranged on the front side of the semiconductor substrate 130. The insulating layer 151 can be made of, for example, SiO₂.

The semiconductor substrate 230 is a semiconductor substrate on which the signal generation section 129 of the pixel circuit 120 is disposed. The semiconductor substrate 230 is stacked on the semiconductor substrate 130. The back surface of the semiconductor substrate 230 is bonded to the front side of the wiring region 150 of the semiconductor substrate 130, whereby the semiconductor substrates 130 and 230 are stacked. Similarly to the semiconductor substrate 130, the semiconductor substrate 230 can be made of Si.

As described above, the amplification transistor 121 and the selection transistor 122 constituting the signal generation section 129 are arranged on the semiconductor substrate 230. The semiconductor regions 231 and 232 of the selection transistor 122 are arranged in the semiconductor substrate 230 in the drawing. In addition, the selection transistor 122 includes the gate electrode 248. Meanwhile, as illustrated in the drawing, the amplification transistor 121 represents an example of being constituted by a fin-type MOS transistor. Note that the amplification transistor 121 in the drawing illustrates an example of including one fin. As the amplification transistor 121, a MOS transistor including a plurality of fins can also be used. In addition, an insulating film 241 is disposed on the front surface of the semiconductor substrate 230.

The wiring region 250 is disposed on the front surface of the semiconductor substrate 230. The wiring region 250 includes a wire 252, a contact plug 253, and an insulating layer 251.

Similarly to the insulating layer 151, the insulating layer 251 insulates wiring and others. The insulating layer 251 can be made of, for example, SiO₂.

The wire 252 transmits a signal or the like to an element in the pixel block 100. The wire 252 can be made of metal such as copper (Cu) or W. The contact plug 253 electrically connects the wiring and a member in the semiconductor substrate. The contact plug 253 can be made of, for example, W or the like in a columnar shape.

Incidentally, the wire 252 in the drawing represents an example in which the through wire 260 is connected. As described above, the through wire 260 connects the gate electrode 149 and others of the semiconductor substrate 130 and the wiring of the semiconductor substrate 230. The through wire 260 is formed in a shape penetrating the semiconductor substrate 230. Specifically, the through wire 260 is disposed in an opening penetrating the semiconductor substrate 230 and is insulated from the semiconductor substrate 230 by the insulating layer 251. Note that the through wire 260 is also connected to the charge holding section common electrode 145.

The color filter 191 is an optical filter that transmits light having a predetermined wavelength in incident light. As the color filter 191, color filters that transmit red light, green light, or blue light can be used.

The on-chip lens 192 condenses incident light. The on-chip lens 192 is formed in, for example, a hemispherical shape and condenses incident light on the photoelectric conversion section 101 and others.

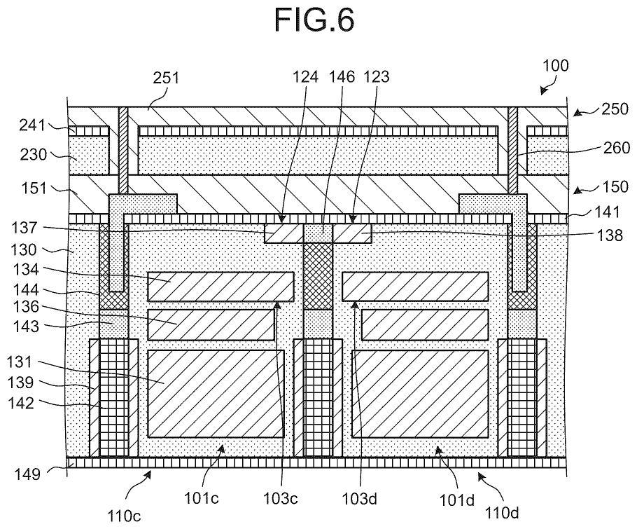

FIG. 6 is a diagram illustrating a structure example of the pixel block according to the first embodiment of the disclosure. The drawing is, similarly to FIG. 5, a cross-sectional view illustrating a structure example of the pixel block 100 in the pixel array section 90. The drawing is a diagram illustrating a configuration example of portions of the pixels 110c and 110d, and is a diagram illustrating a structure example of the reset transistor 123 and the coupling transistor 124. In the drawing, a semiconductor region 138 constituting the source of the reset transistor 123 and a semiconductor region 137 constituting the drain of the coupling transistor 124 are illustrated. An electrode 146 is disposed between the semiconductor regions 138 and 137. The electrode 146 is disposed at the boundary of the pixels 110 and connects the reset transistor 123 and the coupling transistor 124. By using the electrode 146, the reset transistor 123 and the coupling transistor 124 can be connected in the semiconductor substrate 130, whereby wiring or a contact plug for connection can be omitted.

### [Manufacturing Method of Imaging Element]

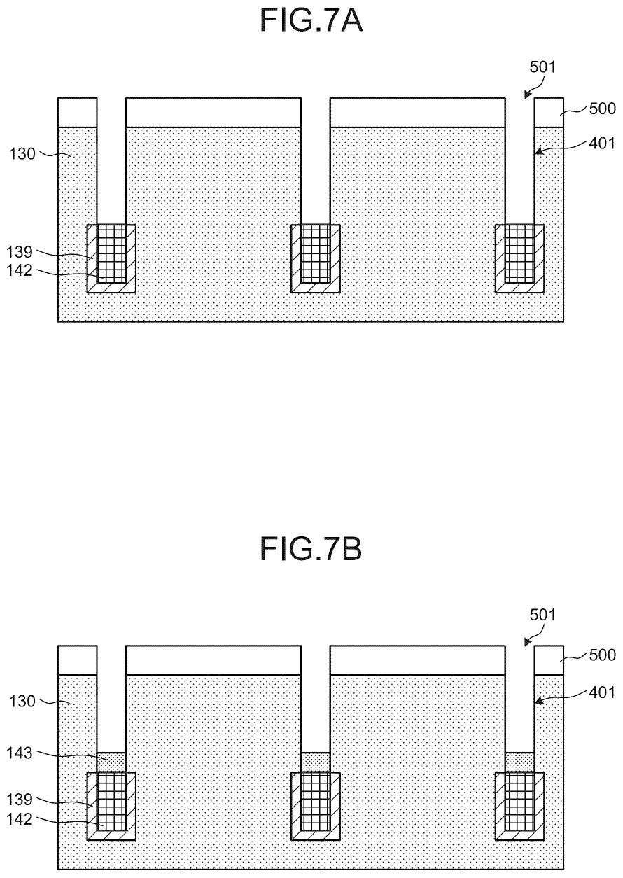

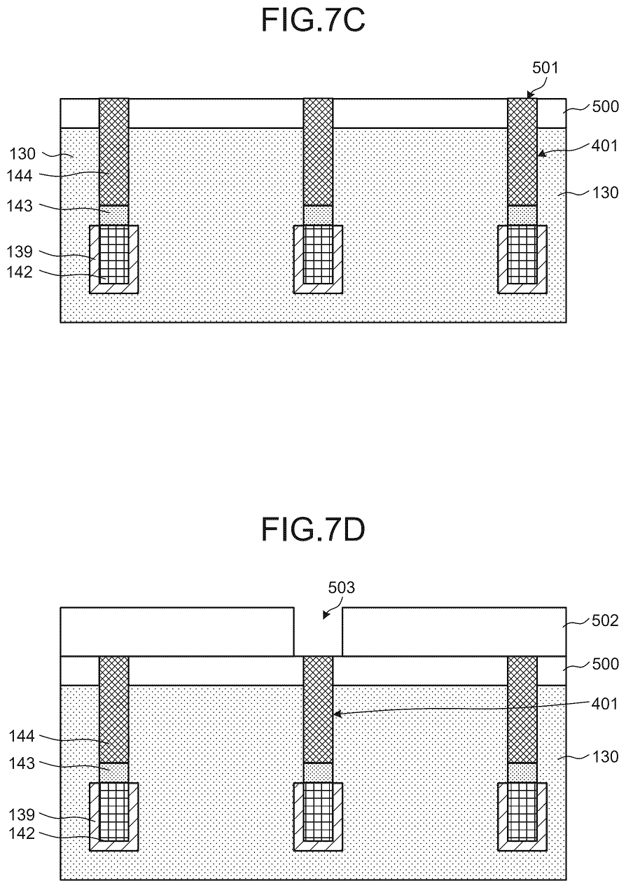

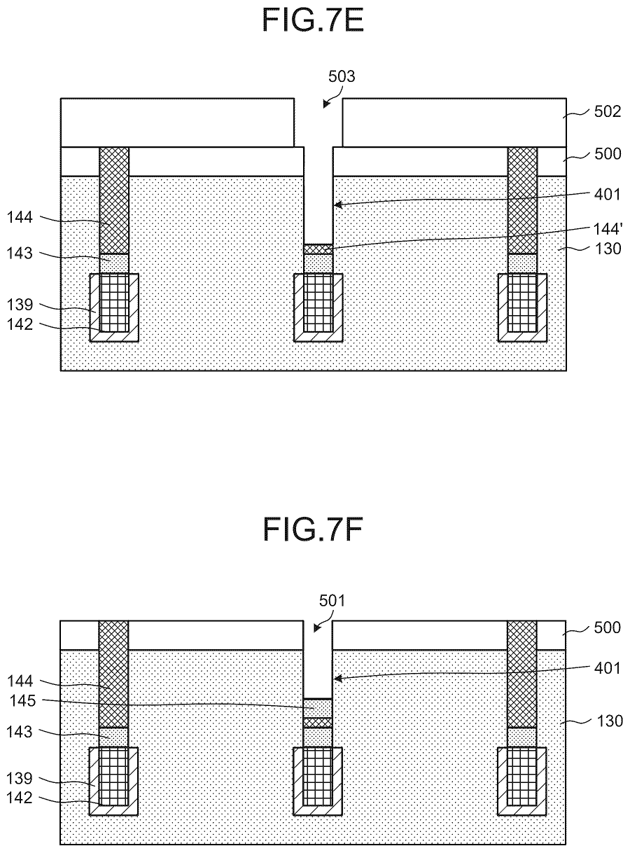

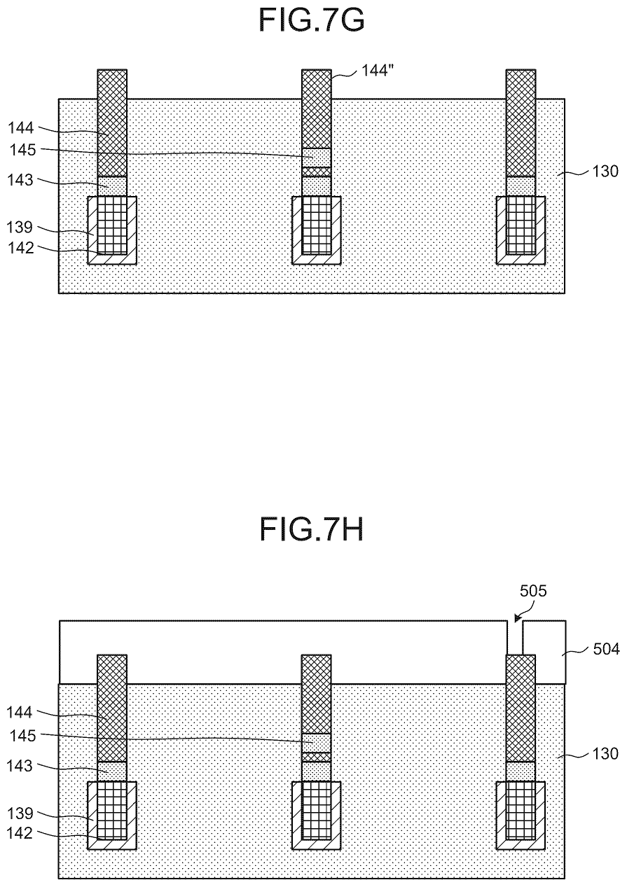

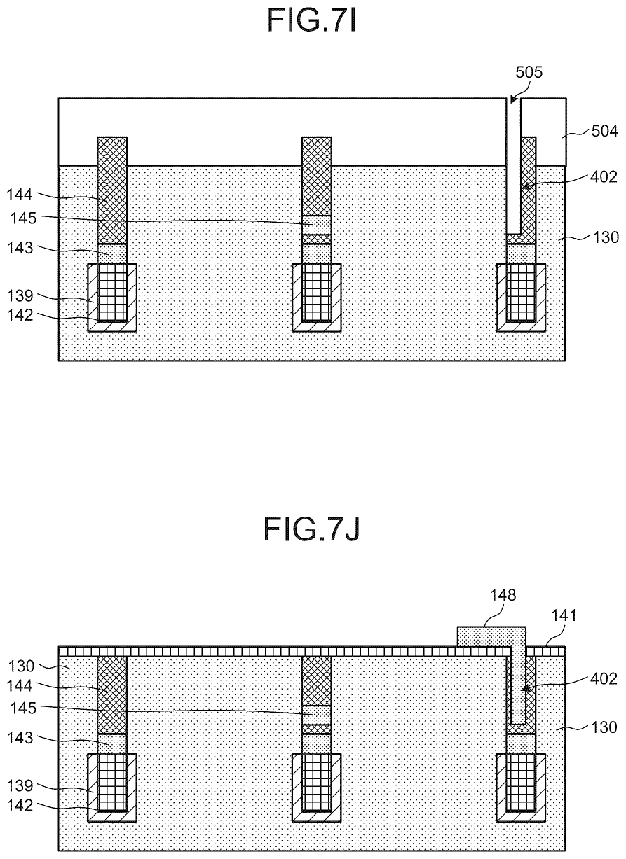

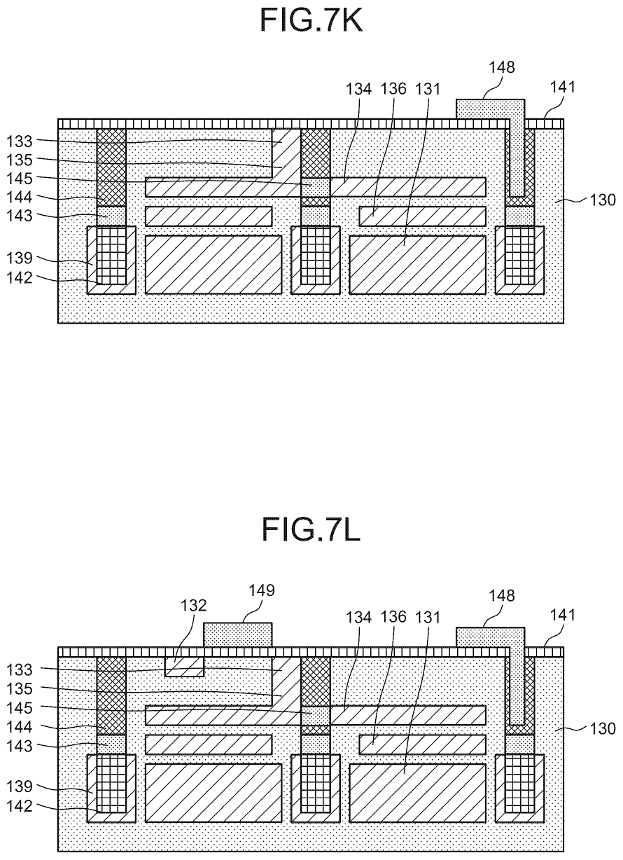

FIG. 7A to 7M are diagrams illustrating an example of the manufacturing method of the imaging element according to the first embodiment of the disclosure. The drawing illustrates an example of the manufacturing process of a pixel 110 in the imaging element 1. The manufacturing method of the pixel 110 will be described with reference to the drawings.

First, a well region is formed in the semiconductor substrate 130. Next, a resist 500 is disposed on the semiconductor substrate 130. In the resist 500, an opening 501 is formed in a region where isolation sections 142 and 144 are to be formed. Next, the semiconductor substrate 130 is etched using the resist 500 as a mask to form an opening 401. Dry etching can be applied to this etching. Next, an impurity is doped to the semiconductor substrate 130 in a lower layer portion of the opening 401 to form a semiconductor region 139. Next, a member constituting the isolation section 142, for example, a polycrystalline silicon film is disposed on the surface of the semiconductor substrate 130 and the opening 401. This can be performed by, for example, chemical vapor deposition (CVD). Next, the polycrystalline silicon film is etched back to form the isolation section 142 (FIG. 7A).

Next, an embedded electrode 143 is formed in the opening 401 (FIG. 7B). For example, the embedded electrode 143 can be formed by disposing a component of the embedded electrode 143, for example, a polycrystalline silicon film containing an impurity, on the surface of the semiconductor substrate 130 and the opening 401 and performing etch back.

Next, an isolation section 144 is formed in the opening 401 (FIG. 7C). This can be performed by, for example, disposing a component of the isolation section 144, for example, an SiO₂ film, on the surface of the semiconductor substrate 130 and in the opening 401 and grinding the surface of the semiconductor substrate 130. For this grinding, for example, chemical mechanical polishing (CMP) can be adopted.

Next, a resist 502 is disposed on the surface of the semiconductor substrate 130 (FIG. 7D). In the resist 502, an opening 503 is formed at a portion of the opening 401 where a charge holding section common electrode 145 is to be disposed.

Next, etch back is performed using the resist 502 as a mask to form an isolation section 144′ (FIG. 7E). The isolation section 144′ insulates the embedded electrode 143 and the charge holding section common electrode 145.

Next, the charge holding section common electrode 145 is formed in the opening 401. For example, a component of the charge holding section common electrode 145, for example, a polycrystalline silicon film containing an impurity is disposed on the surface of the semiconductor substrate 130 and the opening 401, and etch back is performed, whereby the charge holding section common electrode 145 can be formed. Next, the resist 502 is removed (FIG. 7F).

Next, the isolation section 144′ is formed in the opening 401. This can be performed by a process similar to that in FIG. 7C. Next, the resist 500 is removed (FIG. 7G).

Next, a resist 504 is disposed on the surface of the semiconductor substrate 130 (FIG. 7H). In the resist 504, an opening 505 is formed at a region where a columnar portion of a gate electrode 148 of a charge transfer section 102 is to be formed.

Next, etching is performed using the resist 504 as a mask to form an opening 402 (FIG. 7I).

Next, a gate electrode 148 is formed (FIG. 7J). This can be performed, for example, by disposing a film of the component of the gate electrode 148 on the surface of the semiconductor substrate 130 and the opening 402 and etching the region other than the gate electrode 148.

Next, a semiconductor region 131, an element isolation region 136, and a semiconductor region 134 are sequentially formed in the semiconductor substrate 130. This can be performed by ion implantation. Next, the charge holding section connecting section 135 and the semiconductor region 133 are formed (FIG. 7K).

Next, a gate electrode 149 and a semiconductor region 132 are formed on and in the semiconductor substrate 130 (FIG. 7L). First, the wiring region 150 is formed on the semiconductor substrate 130. Next, the semiconductor substrate 230 is stacked on the semiconductor substrate 130. Next, a through wire 260 is formed. With the above process, the imaging element 1 can be manufactured.

Note that the imaging element 1 according to the first embodiment of the disclosure is not limited to this example. For example, it is also possible to adopt a configuration in which the semiconductor substrate 230 is omitted. In this case, all the elements of the pixel block 100 are formed on or in the semiconductor substrate 130.

As described above, the pixel 110 (pixels 110a to 110d) according to the first embodiment of the present disclosure uses the charge holding sections 103 (charge holding sections 103a to 103d) having a shape embedded in the semiconductor substrate 130. Since no charge holding sections 103 are arranged on the surface of the semiconductor substrate 130, the size (area) of the pixels 110 can be easily reduced.

### 2. Modifications of First Embodiment

Next, modifications of the imaging element 1 of the first embodiment described above will be described.

### [First Modification]

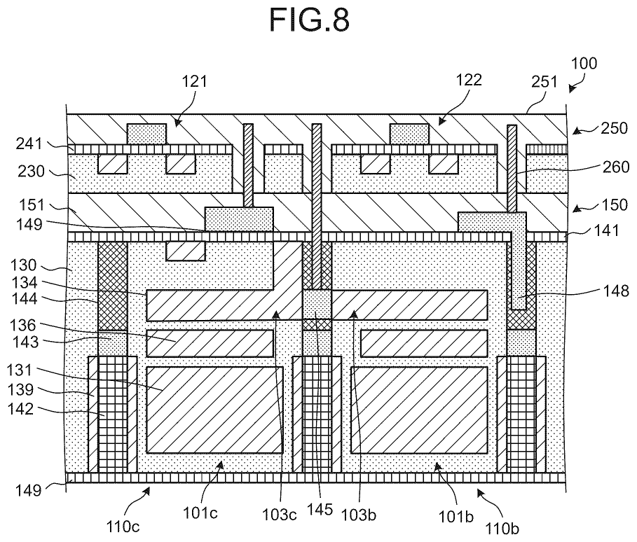

FIG. 8 is a diagram illustrating a structure example of a pixel block according to a first modification of the first embodiment of the disclosure. The drawing is a cross-sectional view illustrating a structure example of a pixel block 100 similarly to FIG. 5. The pixel block 100 in the drawing is different from the pixel block 100 in FIG. 5 in that the amplification transistor 121 includes a MOS transistor having a planar gate.

### [Second Modification]

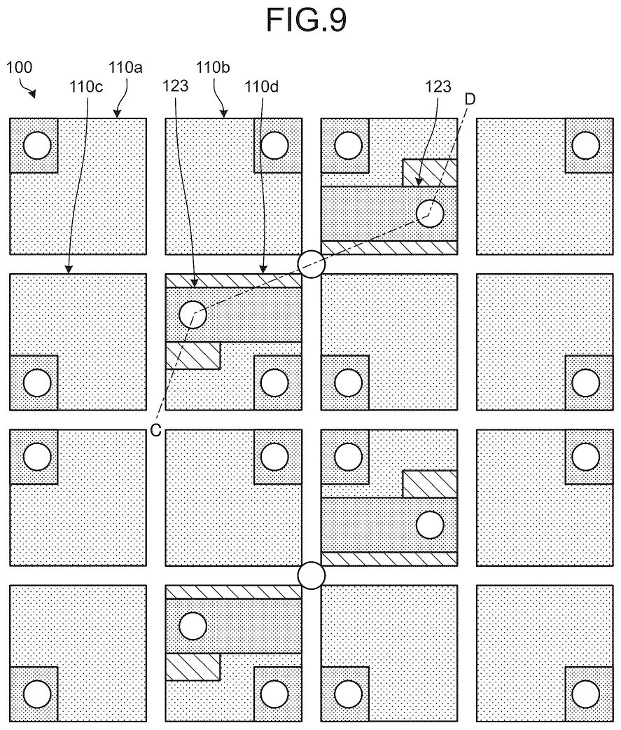

FIG. 9 is a diagram illustrating a structure example of a pixel block according to a second modification of the first embodiment of the disclosure. The drawing is a plan view illustrating a structure example of a pixel block 100 similarly to FIG. 3. The pixel block 100 in the drawing is different from the pixel block 100 in FIG. 3 in that the coupling transistor 124 is omitted. In this case, in the circuit diagram of FIG. 2, the source of the reset transistor 123 is connected to the charge holding section 103. Note that the reset transistor 123 in the drawing illustrates an example in which the through wire 260 connected to the power supply line Vdd is shared with a reset transistor 123 of an adjacent pixel block 100.

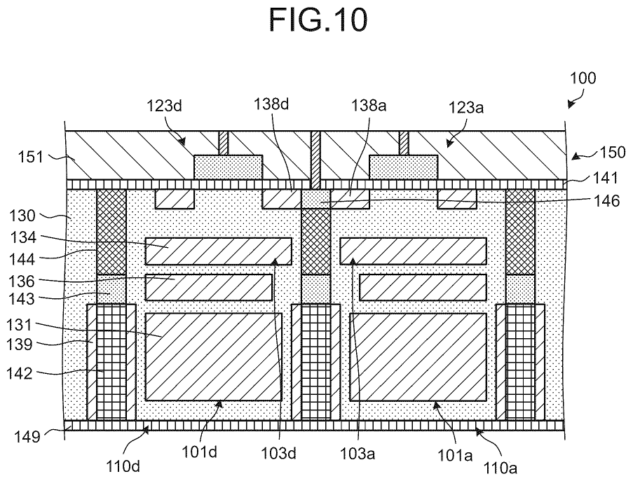

FIG. 10 is a diagram illustrating a structure example of the pixel block according to the second modification of the first embodiment of the disclosure. The drawing is a cross-sectional view illustrating a structure example of a pixel block 100 similarly to FIG. 5. The drawing also illustrates a structure example of the reset transistor 123 of the adjacent pixel block 100. A pixel 110a and a pixel 110d in the drawing are pixels arranged in the adjacent pixel block 100.

In the pixel 110a and the pixel 110d, a reset transistor 123a and a reset transistor 123d are arranged, respectively. A semiconductor region 138a constituting a drain of the reset transistor 123a and a semiconductor region 138d constituting a drain of the reset transistor 123d are commonly connected to an electrode 146. A through wire 260 is connected to the electrode 146. A power supply (Vdd) is supplied to the through wire 260 through wiring of a semiconductor substrate 230. By using this electrode 146, it is possible to share a power supply path in the adjacent reset transistor 123 and to reduce the through wire 260.

### [Third Modification]

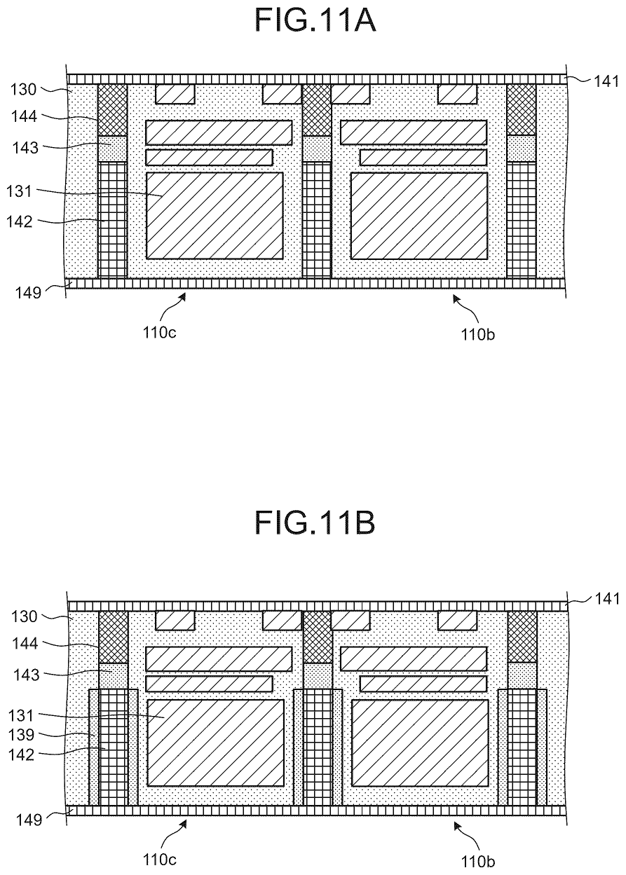

FIGS. 11A and 11B are diagrams illustrating a structure example of a pixel block according to a third modification of the first embodiment of the disclosure. The drawings are cross-sectional views illustrating a structure example of a pixel 110 of a pixel block 100. For the sake of convenience, the wiring region 150 and others are omitted in the drawing.

FIG. 11A is a diagram illustrating an example in which the semiconductor region 139 adjacent to the isolation section 142 is omitted. In this case, a fixed charge film can be disposed between an isolation section 142 and a semiconductor substrate 130. FIG. 11B is a diagram illustrating an example in which a semiconductor region 139 formed by the solid-phase diffusion method is disposed.

### [Fourth Modification]

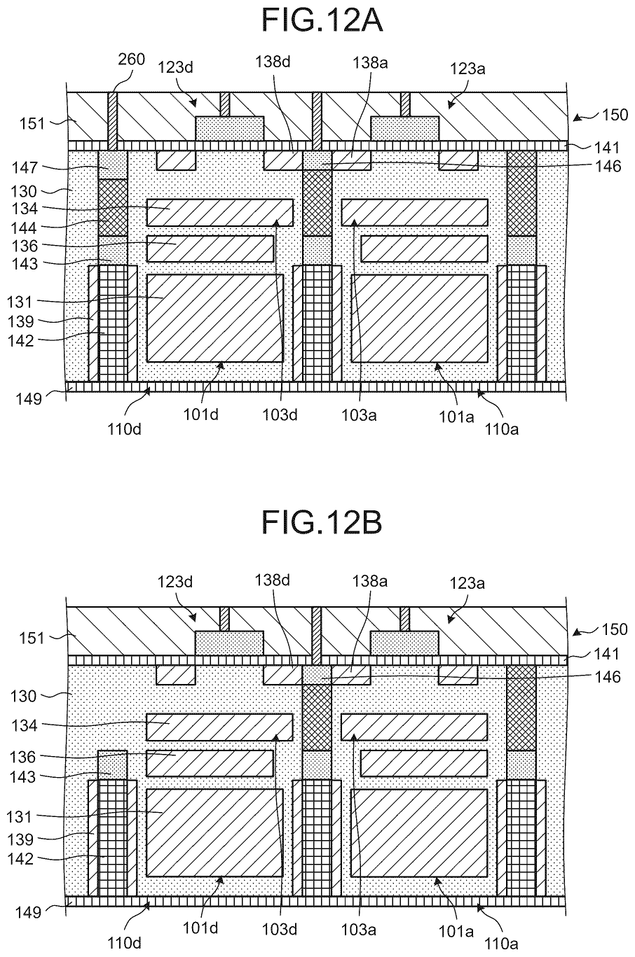

FIGS. 12A and 12B are diagrams illustrating a structure example of a pixel block according to a fourth modification of the first embodiment of the disclosure. The drawing explains an electrode that supplies a reference potential to a well region in the vicinity of an element of a pixel circuit 120.

FIG. 12A illustrates an example in which a reference potential is supplied to a well region via an electrode 147 disposed in the vicinity of the front surface of a semiconductor substrate 130 at a boundary of pixels 110. The electrode 147 is formed in a shape in contact with the well region of the semiconductor substrate 130 and is connected with the well region. A through wire 260 is connected to the electrode 147. The electrode 147 can be made of, for example, polycrystalline silicon containing an impurity.

FIG. 12B is a diagram illustrating an example in which a part of the isolation section 144 is omitted and a reference potential for an element of a pixel circuit 120 is supplied from an embedded electrode 143.

### [Fifth Modification]

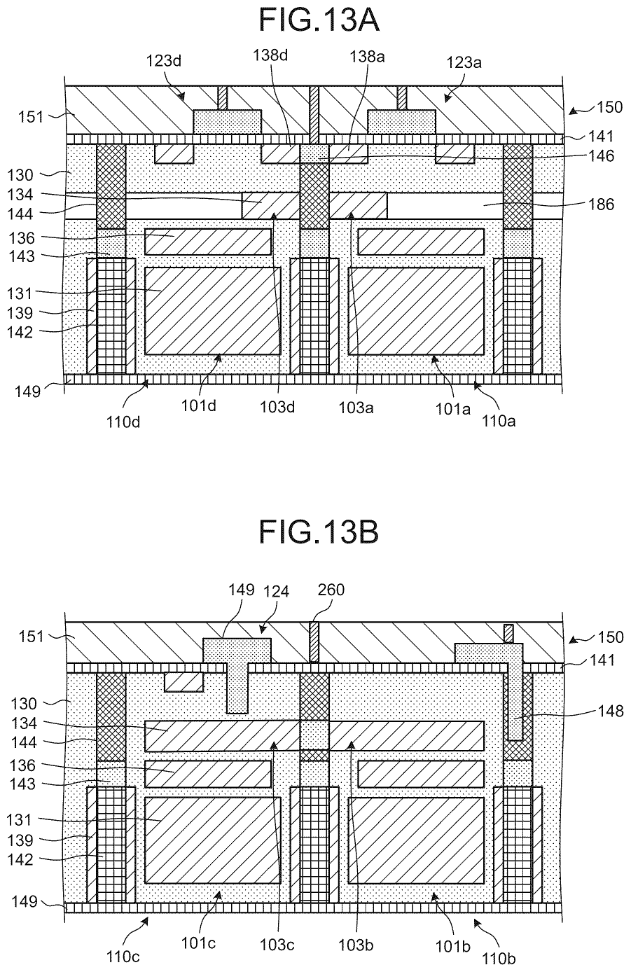

FIGS. 13A and 13B are diagrams illustrating a structure example of a pixel block according to a fifth modification of the first embodiment of the disclosure. FIG. 13A is a diagram illustrating a modification of the charge holding section 103. The drawing illustrates an example of a charge holding section 103 having a reduced size. A hollow region adjacent to the charge holding section 103 in the drawing represents a semiconductor region 186 not containing impurities.

FIG. 13B is a diagram illustrating an example of a coupling transistor 124 including a vertical transistor that transfers a charge in the thickness direction of a semiconductor substrate

### [Sixth Modification]

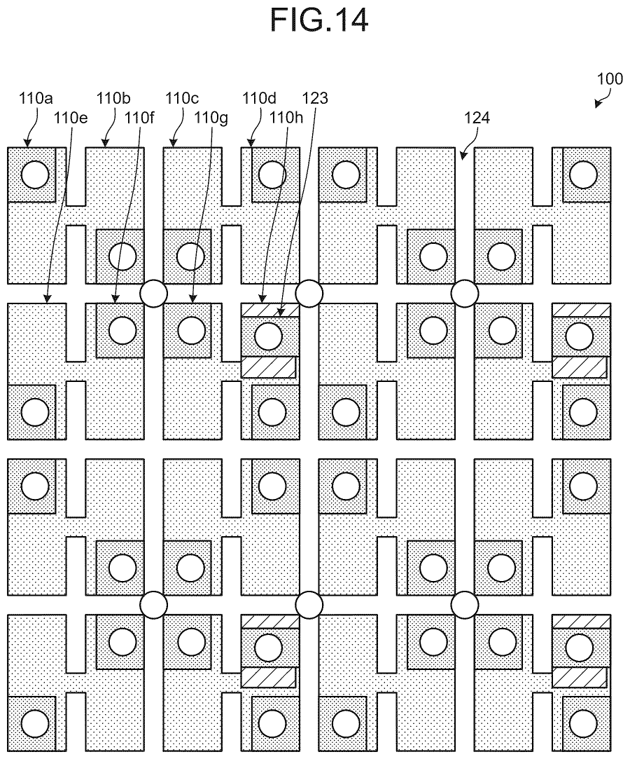

FIG. 14 is a diagram illustrating a structure example of a pixel block according to a sixth modification of the first embodiment of the disclosure. The drawing is a plan view illustrating an example of a pixel block 100 including eight pixels 110 of pixels 110a to 110h. The pixel 110a and the pixel 110b are formed to have a rectangular shape obtained by dividing a square into two. Furthermore, the pixel 110a and the pixel 110b are separated by an isolation section 144 having a cutout portion in the center. The pixel 110a and the pixel 110b can be used as phase difference pixels for detecting an image plane phase difference. Furthermore, in a case where a normal image signal is generated, charges generated by photoelectric conversion of the pixel 110a and the pixel 110b are simultaneously transferred to the charge holding section 103 to generate a pixel signal.

The pixel 110c, the pixel 110d, the pixel 110e, the pixel 110f, the pixel 110g, and the pixel 110h can also adopt a similar configuration to those of the pixel 110a and the pixel 110b. A pixel circuit 120 of the pixel block 100 in the drawing is commonly connected with these eight pixels 110. Note that, in the pixel circuit 120 in the drawing, the coupling transistor 124 is omitted. Also in the pixel block 100 in the drawing, a charge holding section 103 embedded in a semiconductor substrate 130 can be used.

The configuration of the imaging element 1 other than the above is similar to the configuration of the imaging element 1 in the first embodiment of the present disclosure, and thus description thereof is omitted.

### 3. Second Embodiment

In the imaging element 1 of the first embodiment described above, the semiconductor region 134 of the charge holding section 103 of the pixel 110 is formed by ion implantation. Meanwhile, an imaging element 1 according to a second embodiment of the present disclosure is different from the above-described first embodiment in that a semiconductor region 134 of a charge holding section 103 is formed by thermal diffusion.

### [Structure of Cross-Section of Pixel]

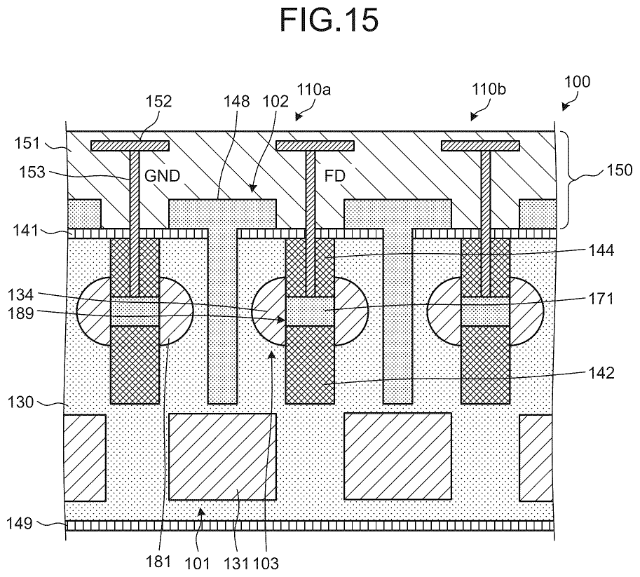

FIG. 15 is a diagram illustrating a structure example of a pixel according to the second embodiment of the disclosure. The drawing is a cross-sectional view illustrating the structure example of a pixel 110. In the drawing, a pixel 110a and a pixel 110b adjacent to each other are illustrated. The structure of the pixel 110 will be described using the pixel 110a as an example. In the pixel 110 in the drawing, a photoelectric conversion section 101, a charge transfer section 102, and a charge holding section 103 are illustrated.

The pixel 110 in the drawing is formed in a semiconductor substrate 130. A wiring region 150 is disposed on the front side of the semiconductor substrate 130. The wiring region 150 includes an insulating layer 151, a wire 152, and a contact plug 153.

An isolation section 142 and an isolation section 144 are arranged in the semiconductor substrate 130 at a boundary between pixels 110. Similarly to the pixel 110 in FIG. 5, the isolation section 144 is disposed on the front side of the semiconductor substrate 130, and the isolation section 142 is disposed on the back side of the semiconductor substrate 130. Note that the isolation section 142 and the isolation section 144 are formed in a groove-shaped opening 189 formed at the boundary between the pixels 110.

An embedded electrode 171 is disposed in the opening 189. The embedded electrode 171 is formed to have a shape in contact with the charge holding section 103 and is connected with the charge holding section 103. The embedded electrode 171 is formed in a shape adjacent to a side surface of the opening 189 and is disposed apart from the surface where the wiring region 150 is in contact with the semiconductor substrate 130. The embedded electrode 171 in the drawing represents an example of being disposed between the isolation section 142 and the isolation section 144. Note that the embedded electrode 171 in the drawing represents an example of being commonly connected to a charge holding section 103 of an adjacent pixel 110. The embedded electrode 171 can be made of polycrystalline silicon containing an impurity.

The photoelectric conversion section 101 includes a semiconductor region 131 and is disposed in the vicinity of the back surface of the semiconductor substrate 130, similarly to the photoelectric conversion section 101 in FIG. 5.

The charge holding section 103 includes a semiconductor region 134. The charge holding section 103 is structured in a shape embedded in the semiconductor substrate 130, similarly to the charge holding section 103 in FIG. 5. Specifically, the charge holding section 103 in the drawing is formed in a shape adjacent to a side surface of the opening 189 and is disposed apart from the surface where the wiring region 150 is in contact with the semiconductor substrate 130. As described above, the charge holding section 103 is in contact with the embedded electrode 171. The semiconductor region 134 included in the charge holding section 103 is a semiconductor region formed in the semiconductor substrate 130 by thermal diffusion of an impurity from the embedded electrode 171. That is, the same impurity as that of the embedded electrode 171 is added to the charge holding section 103.

The embedded electrode 171 connected to the semiconductor region 134 of the charge holding section 103 is commonly connected to a charge holding section 103 of an adjacent pixel 110. In the drawing, the charge holding sections 103 of the pixel 110a and the pixel 110b are commonly connected to the embedded electrode 171. A contact plug 153 connected to the embedded electrode 171 forms a path for transmitting the potential of the charge holding section 103 (denoted as “FD” in the drawing). Note that the embedded electrode 171 in the drawing is an example of a second embedded electrode.

The charge transfer section 102 in the drawing includes a vertical transistor that transfers a charge in the thickness direction of the semiconductor substrate 130. A gate electrode 148 of the charge transfer section 102 has a columnar portion having a depth reaching the vicinity of the photoelectric conversion section 101, the columnar portion having a shape that approaches the charge holding section 103. When an ON voltage is applied to the gate electrode 148, a channel is formed in a well region adjacent to the gate electrode 148, and the photoelectric conversion section 101 and the charge holding section 103 are electrically connected to each other. As a result, the charge accumulated in the photoelectric conversion section 101 is transferred to the charge holding section 103.

The semiconductor region 181 has a relatively high impurity concentration and transmits a reference potential to the well region of the pixel 110. The reference potential (denoted as “GND” in the drawing) is transmitted to the embedded electrode 171 connected to the semiconductor region 181 via the contact plug 153. The embedded electrode 171 is commonly connected to a semiconductor region 181 of the adjacent pixel 110. In the drawing, the semiconductor regions 181 of the pixel 110a and the pixel 110 on the left of the pixel 110a are commonly connected to the embedded electrode 171. Similarly to the semiconductor region 134, the semiconductor region 181 is formed by thermal diffusion of the impurity from the embedded electrode 171. That is, the same impurity as that of the embedded electrode 171 is added to the semiconductor regions 134 and 181.

As illustrated in the drawing, since the semiconductor region 134 included in the charge holding section 103 is embedded in the semiconductor substrate 130, the charge holding section 103 is disposed apart from the surface of the semiconductor substrate 130. As a result, the charge holding section 103 can be disposed apart from a member disposed on the surface of the semiconductor substrate 130, for example, the gate electrode 148. Concentration of an electric field between the charge holding section 103 and the gate electrode 148 can be relaxed, and deterioration of the image quality due to mixing of charges can be prevented. It is also possible to improve the reliability by relaxing the concentration of the electric field. Similarly, the semiconductor region 181 for supplying the reference potential to the well region can be disposed apart from the gate electrode 148. As a result, the size (area) of the pixel 110 can be easily reduced.

Note that the embedded electrode 171 may be connected to a semiconductor region of an element of the pixel circuit 120.

### [Manufacturing Method of Imaging Element]

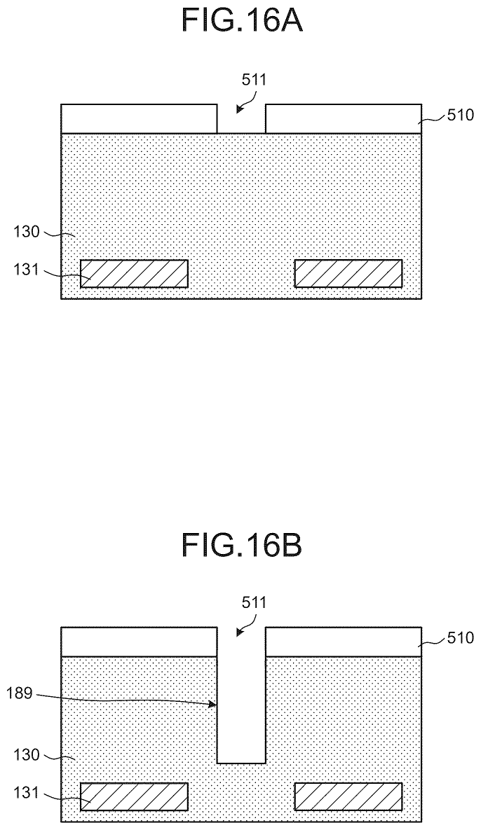

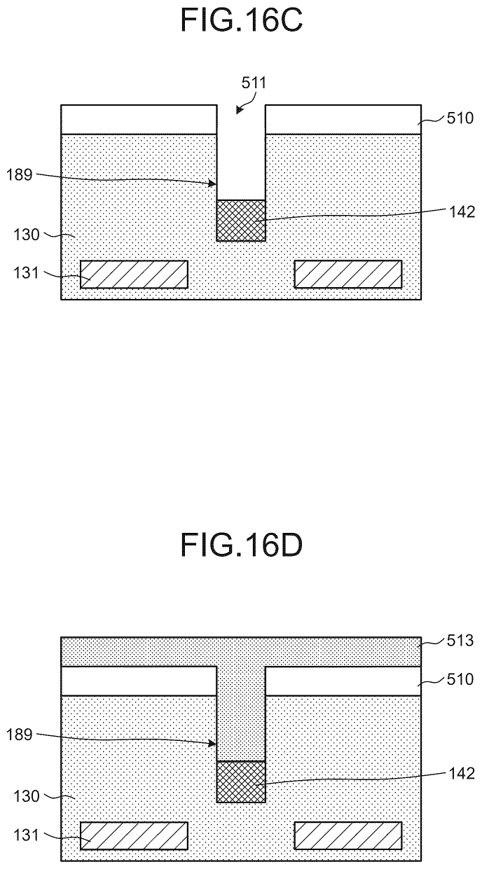

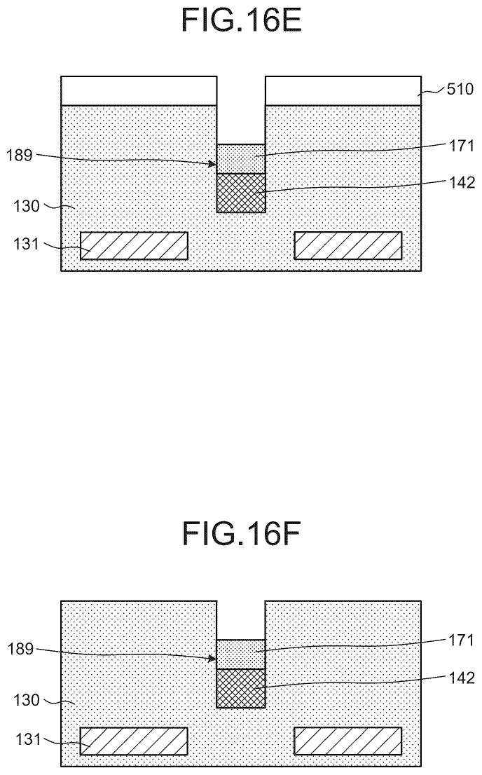

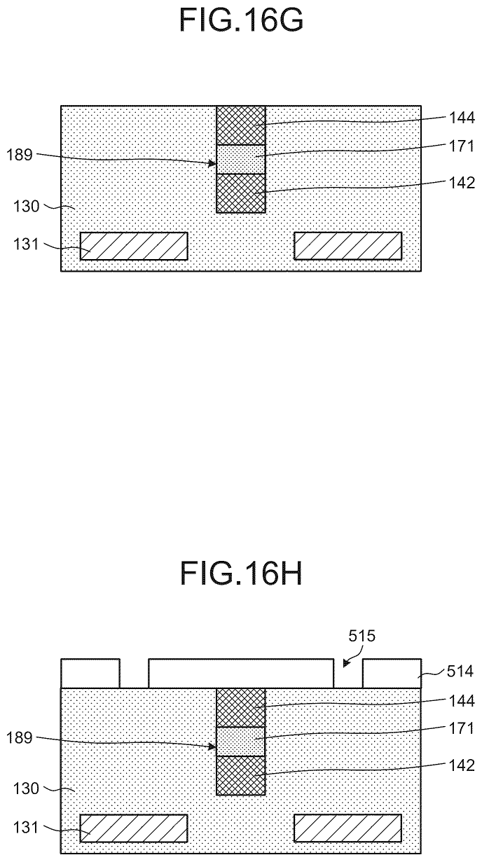

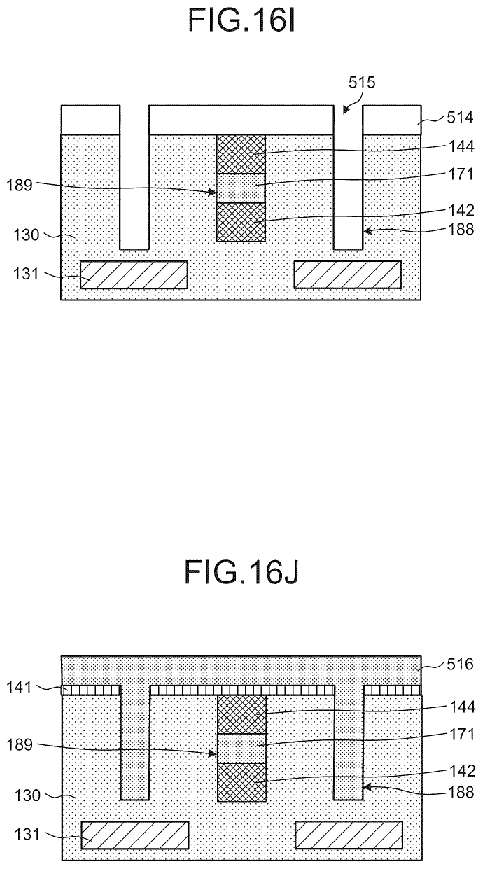

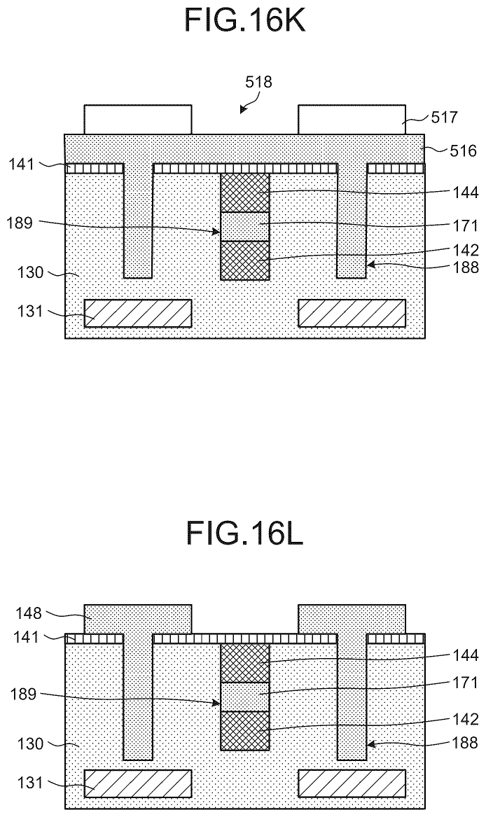

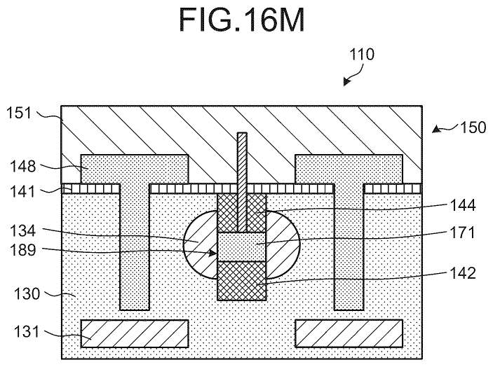

FIG. 16A to 16M are diagrams illustrating an example of the manufacturing method of the imaging element according to the second embodiment of the disclosure. The drawing illustrates an example of the manufacturing process of a pixel 110 in the imaging element 1. The manufacturing method of the pixel 110 will be described with reference to the drawings.

First, a well region is formed in a semiconductor substrate 130 to form a semiconductor region 131. Next, a resist 510 is disposed on the semiconductor substrate 130. In the resist 510, an opening 511 is formed at a region where an opening 189 is to be formed (FIG. 16A).

Next, the semiconductor substrate 130 is etched using the resist 510 as a mask to form an opening 189 (FIG. 16B).

Next, an isolation section 142 is formed in the opening 189 (FIG. 16C). For example, the isolation section 142 can be formed by disposing a component of the isolation section 142, for example, an SiO₂ film on the surface of the semiconductor substrate 130 and the opening 189 and performing etch back.

Next, a component of an embedded electrode 171, for example, a film 513 of polycrystalline silicon containing an impurity, is disposed on the surface of the semiconductor substrate 130 and in the opening 189 (FIG. 16D).

Next, the film 513 is etched back to form an embedded electrode 171 (FIG. 16E). Next, the resist 510 is removed (FIG. 16F).

Next, an isolation section 144 is formed in the opening 189 (FIG. 16G). This can be performed by, for example, disposing a component of the isolation section 144, for example, an SiO₂ film, on the surface of the semiconductor substrate 130 and in the opening 189 and grinding the surface of the semiconductor substrate 130.

Next, a resist 514 is disposed on the surface of the semiconductor substrate 130. In the resist 514, an opening 515 is formed at a region where a columnar portion of a gate electrode 148 is to be formed (FIG. 16H). Next, the semiconductor substrate 130 is etched using the resist 514 as a mask to form an opening 188 (FIG. 16I).

Next, a film 516 of a component of the gate electrode 148 is disposed on the surface of the semiconductor substrate 130 and in the opening 188 (FIG. 16J). Next, a resist 517 is disposed on the surface of the semiconductor substrate 130. In the resist 517, an opening 518 is formed in a region other than that of the gate electrode 148 (FIG. 16K).

Next, the film 516 is etched using the resist 517 as a mask to form the gate electrode 148 (FIG. 16L).

Next, a semiconductor region 134 is formed by thermal diffusion. Subsequently, a wiring region 150 is formed on the semiconductor substrate 130 (16M). With the above process, the imaging element 1 can be manufactured.

The configuration of the imaging element 1 other than the above is similar to the configuration of the imaging element 1 in the first embodiment of the present disclosure, and thus description thereof is omitted.

As described above, the imaging element 1 according to the second embodiment of the present disclosure uses the charge holding section 103 having a shape embedded in the semiconductor substrate 130. Since no charge holding sections 103 are arranged on the surface of the semiconductor substrate 130, the size (area) of the pixels 110 can be easily reduced.

### 4. Third Embodiment

The imaging element 1 of the second embodiment described above uses the charge transfer section 102 including the gate electrode 148. Meanwhile, an imaging element 1 according to a third embodiment of the present disclosure is different from the third embodiment described above in that a sidewall is disposed at a gate electrode 148.

### [Structure of Cross-Section of Pixel]

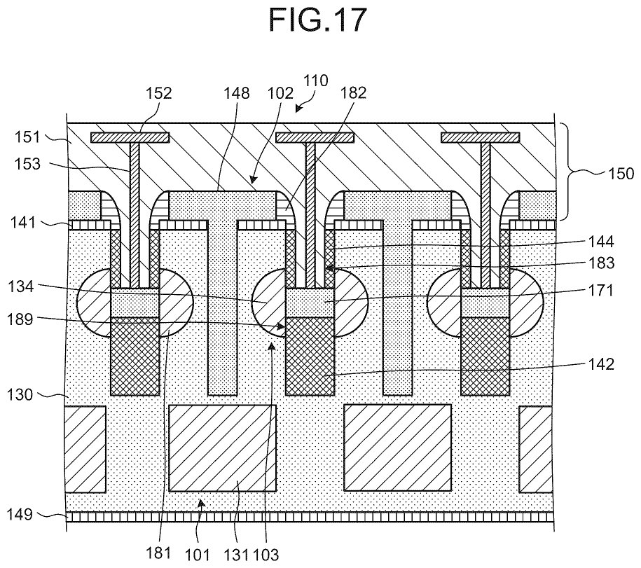

FIG. 17 is a diagram illustrating a structure example of a pixel according to the third embodiment of the disclosure. The drawing is a cross-sectional view illustrating a structure example of a pixel 110 similarly to FIG. 15. A gate electrode 148 in this drawing is provided with a sidewall, which is different from the pixel 110 in FIG. 15.

As described above, a sidewall 182 is disposed at the gate electrode 148 of a charge transfer section 102. The sidewall 182 is made of an insulator attached to a side surface of the gate electrode 148. Furthermore, an opening 183 is formed in an isolation section 144 in the drawing.

### [Manufacturing Method of Imaging Element]

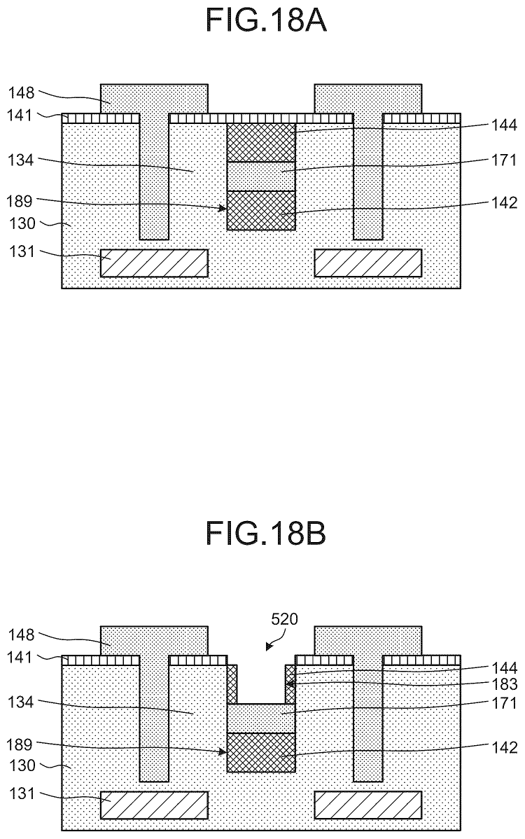

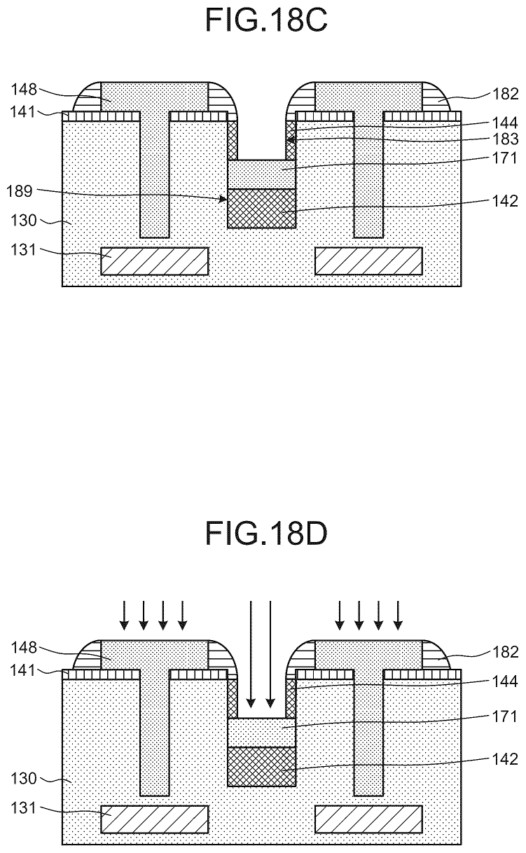

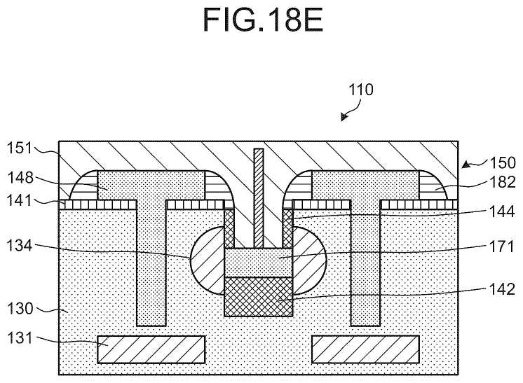

FIG. 18A to 18E are diagrams illustrating an example of the manufacturing method of an imaging element according to the third embodiment of the disclosure. The drawing illustrates an example of the manufacturing process of a pixel 110 in the imaging element 1. The manufacturing method of the pixel 110 will be described with reference to the drawings.

First, the processes of FIGS. 16A to 16L are executed to form the gate electrode 148 on the semiconductor substrate 130 (FIG. 18A). At this point, in the process of FIG. 16D, the film 513 of polycrystalline silicon not containing impurities is used. Similarly, in the process of FIG. 16J, a film 516 of polycrystalline silicon not containing impurities is used. Next, an isolation section 144 is etched to form an opening 183 (FIG. 18B).

Next, a sidewall 182 is disposed at the gate electrode 148 (FIG. 18B). For example, the sidewall 182 can be disposed by disposing a film of a component of the sidewall 182 on the surface of the semiconductor substrate 130 and in the opening 183 and performing etch back.

Next, an impurity is implanted into the gate electrode 148 and the embedded electrode 171 (FIG. 18D). This reduces the resistance of the gate electrode 148 and the embedded electrode 171.

Next, a semiconductor region 134 is formed by thermal diffusion. First, a wiring region 150 is formed in the semiconductor substrate 130 (FIG. 18E). With the above process, the imaging element 1 can be manufactured.

The configuration of the imaging element 1 other than the above is similar to the configuration of the imaging element 1 in the second embodiment of the present disclosure, and thus description thereof is omitted.

As described above, the imaging element 1 according to the third embodiment of the present disclosure uses the gate electrode 148 having the sidewall 182. The resistance of the gate electrode 148 and the embedded electrode 171 can be reduced by ion implantation.

### 5. Fourth Embodiment

In the imaging element 1 of the third embodiment described above, the sidewall 182 is disposed at the gate electrode 148. On the other hand, an imaging element 1 according to a fourth embodiment of the present disclosure is different from the above-described embodiment in that a sidewall 182, having a shape covering a step portion formed in the vicinity of an opening 189 of the semiconductor substrate 130, is used.

### [Structure of Cross-Section of Pixel]

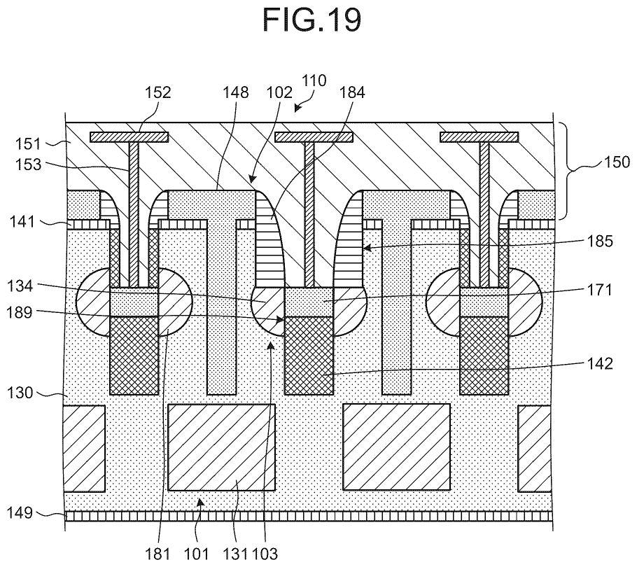

FIG. 19 is a diagram illustrating a structure example of a pixel according to a fourth embodiment of the disclosure. The drawing is a cross-sectional view illustrating a structure example of a pixel 110 similarly to FIG. 15. A step 185 is formed in an opening 189 in the drawing. The step 185 can be formed by forming, in an overlapping manner, an opening having a width wider than that of the opening 189. In addition, a sidewall 184 in a region adjacent to the step 185 has a shape that reaches the bottom portion of the step 185. In addition, a semiconductor region 134 of a charge holding section 103 is formed in a shape adjacent to the bottom portion of the step 185.

Since a gate electrode 148 on the surface of the semiconductor substrate 130 and the semiconductor region 134 are separated by the step 185, the concentration of the electric field can be further relaxed. In addition, the semiconductor region 134 can be insulated by the sidewall 184.

### [Manufacturing Method of Imaging Element]

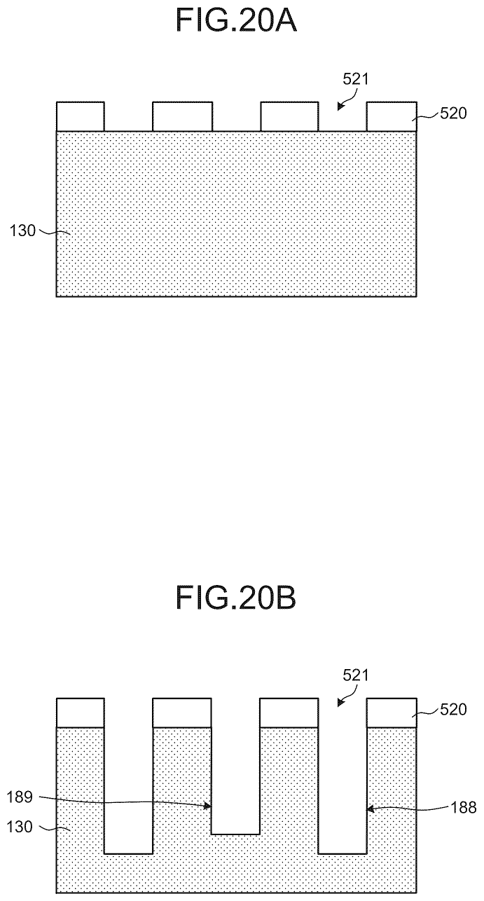

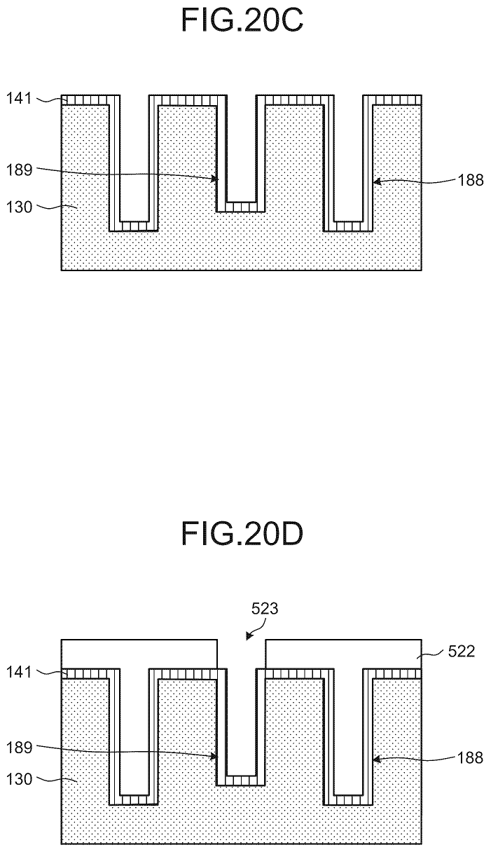

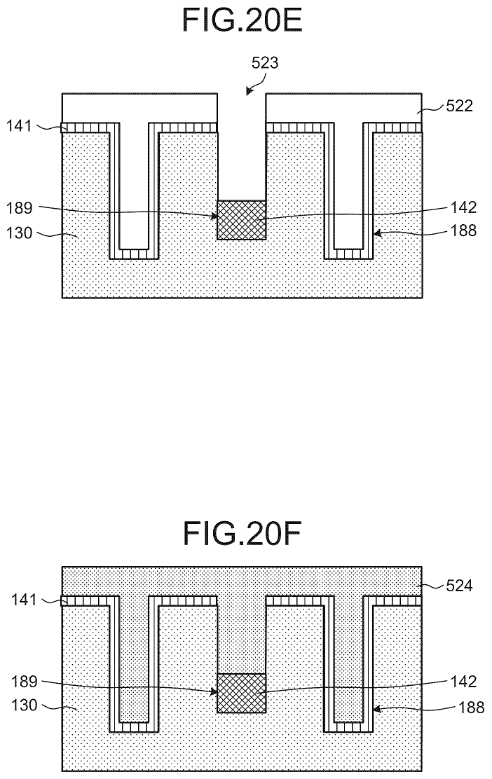

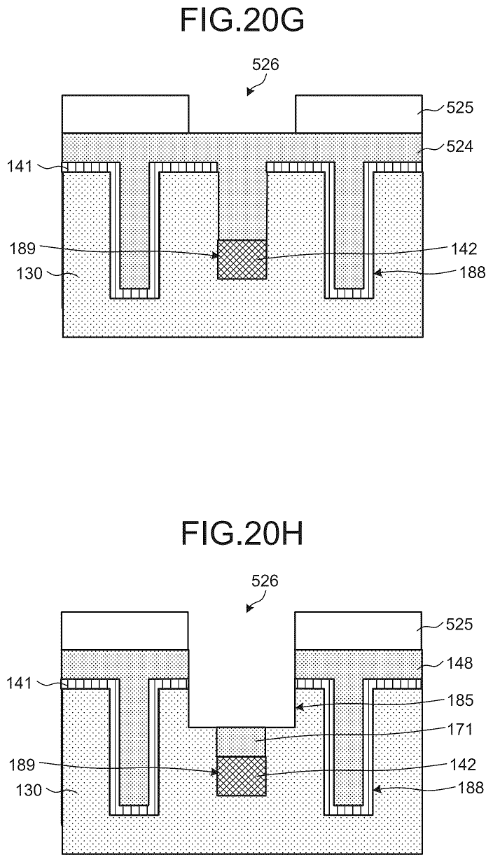

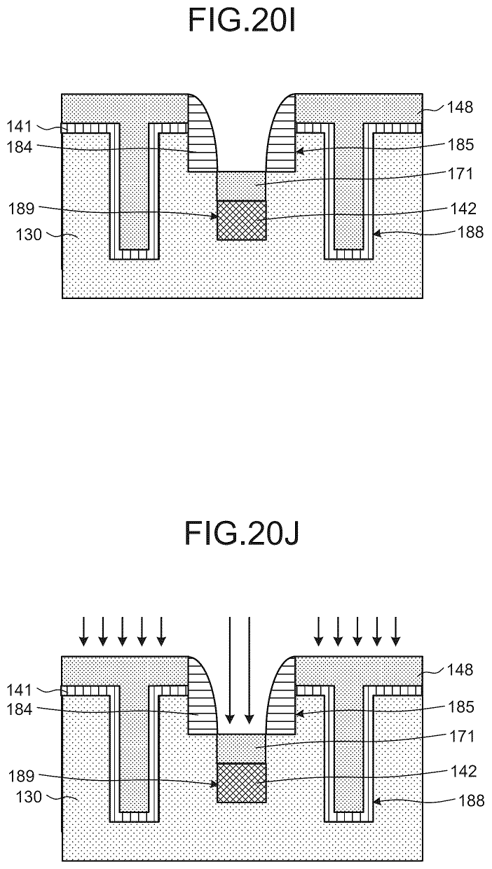

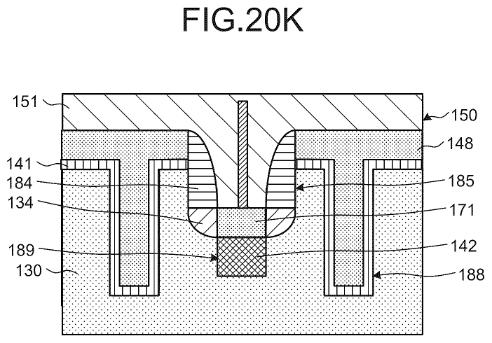

FIGS. 20A to 20K are diagrams illustrating an example of the manufacturing method of the imaging element according to the fourth embodiment of the disclosure. The drawing illustrates an example of the manufacturing process of a pixel 110 in the imaging element 1. The manufacturing method of the pixel 110 will be described with reference to the drawings.

First, a well region is formed in a semiconductor substrate 130 to form a semiconductor region 131. Next, a resist 520 is disposed on the semiconductor substrate 130. In the resist 520, openings 521 are formed at regions where openings 188 and 189 are to be formed (FIG. 20A).

Next, the semiconductor substrate 130 is etched using the resist 520 as a mask to form openings 188 and 189 (FIG. 20B).

Next, an insulating film 141 is disposed on the surfaces of the semiconductor substrate 130 and the openings 188 and 189 (FIG. 20C). Next, a resist 522 is disposed on the surface of the semiconductor substrate 130 and in the opening 188 (FIG. 20D). An opening 523 is formed in the resist 522 at a region of the opening 189.

Next, etching is performed using the resist 502 as a mask to remove the insulating film 141 in the opening 189. Next, an isolation section 142 is formed in the opening 189 (FIG. 20E).

Then, the resist 522 is removed. Subsequently, the film 524 of a component of the gate electrode 148 is disposed on the surface of the semiconductor substrate 130 and in the openings 188 and 189 (FIG. 20F).

Next, a resist 525 is disposed on the surface of the semiconductor substrate 130. In the resist 525, an opening 526 is formed in a region where the step 185 is to be formed (FIG. 20G).

Next, the semiconductor substrate 130 is etched using the resist 525 as a mask to form a step 185 (FIG. 20H). Then, the resist 525 is removed. Next, the gate electrode 148 is formed. Then, a sidewall 184 is formed (FIG. 20I).

Next, an impurity is implanted into the gate electrode 148 and the embedded electrode 171 (FIG. 20J). Next, a semiconductor region 134 is formed by thermal diffusion. Subsequently, a wiring region 150 is formed in the semiconductor substrate 130 (FIG. 20K). With the above process, the imaging element 1 can be manufactured.

The configuration of the imaging element 1 other than the above is similar to the configuration of the imaging element 1 in the third embodiment of the present disclosure, and thus description thereof is omitted.

As described above, the imaging element 1 according to the fourth embodiment of the present disclosure can further relax the concentration of the electric field by forming the step 185 to separate the gate electrode 148 and the semiconductor region 134 of the charge holding section 103.

### 6. Modifications of Second Embodiment

Next, modifications of the second embodiment will be described.

### [First Modification]

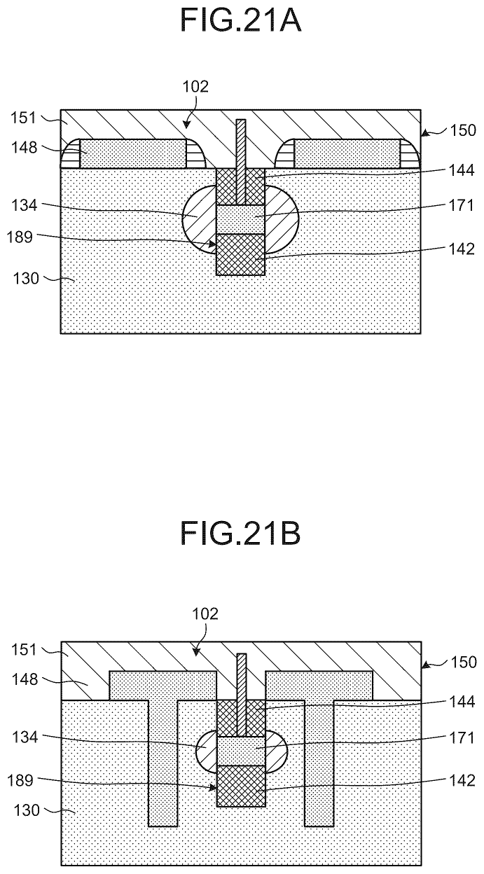

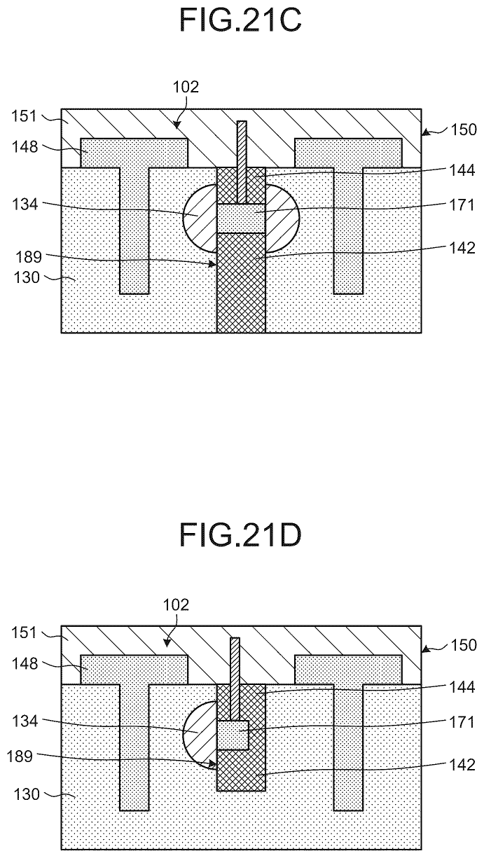

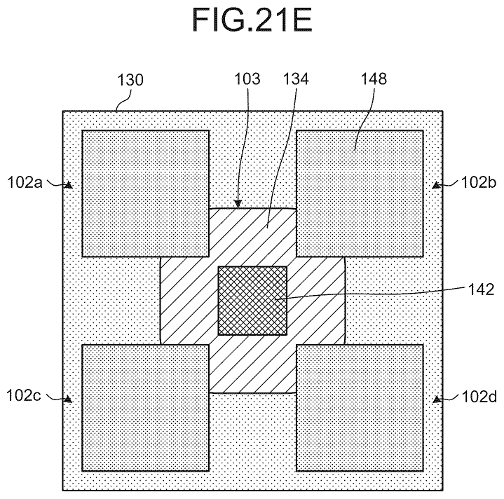

FIG. 21A is a diagram illustrating a structure example of a pixel according to a first modification of the second embodiment of the disclosure. The drawing is a cross-sectional view illustrating a structure example of a pixel 110 similarly to FIG. 17. This drawing illustrates an example of using a gate electrode 148 having a planar gate.

### [Second Modification]

FIG. 21B is a diagram illustrating a structure example of a pixel according to a second modification of the second embodiment of the disclosure. The drawing is a cross-sectional view illustrating a structure example of a pixel 110 similarly to FIG. 15. The drawing illustrates a charge transfer section 102 including a gate electrode 148 having a shape that does not overlap an opening 189 when viewed from the normal direction of the surface of the semiconductor substrate 130. The size (area) of the pixel 110 can be further reduced by bringing the gate electrode 148 close to the periphery of the opening 189.

### [Third Modification]

FIG. 21C is a diagram illustrating a structure example of a pixel according to a third modification of the second embodiment of the disclosure. The drawing is a cross-sectional view illustrating a structure example of a pixel 110 similarly to FIG. 15. The drawing illustrates an example in which an isolation section 142 having a shape reaching the back surface of the semiconductor substrate 130 is disposed.

### [Fourth Modification]

FIG. 21D is a diagram illustrating a structure example of a pixel according to a fourth modification of the second embodiment of the disclosure. The drawing is a cross-sectional view illustrating a structure example of a pixel 110 similarly to FIG. 15. The drawing illustrates an example in which an embedded electrode 171 is adjacent to one side surface of the opening 189. This drawing illustrates an example in which one charge transfer section 102 is connected to a charge holding section 103.

### [Fifth Modification]

FIG. 21E is a diagram illustrating a structure example of a pixel according to a fifth modification of the second embodiment of the disclosure. The drawing is a plan view illustrating the structure example of a pixel 110. This drawing illustrates an example in which four charge transfer sections 102 (charge transfer sections 102a to 102d) are connected to a charge holding section 103.

The pixel 110 of the embodiment can generate a pixel signal corresponding to visible light or infrared light. Furthermore, the pixel 110 of the embodiment can also be applied to a sensing device or the like other than the imaging element.

The configuration of the imaging element 1 other than the above is similar to the configuration of the imaging element 1 in the second embodiment of the present disclosure, and thus description thereof is omitted.

### 7. Fifth Embodiment

A fifth embodiment of the present disclosure proposes an imaging element 1 that reduces the number of pixel circuits 120 and connection sections connecting the pluralities of pixels 110 and the pixel circuits 120 by increasing the number of pixels 110 connected to a pixel circuit 120 in a pixel block 100.

The imaging element 1 of the first embodiment described above uses the pixel block 100 including the four pixels 110 and the pixel circuit 120. Meanwhile, an imaging element 1 according to a fifth embodiment of the present disclosure is different from the first embodiment described above in that a pixel block 100 including eight pixels 110 is used. A pixel block 100 according to the fifth embodiment of the present disclosure includes a pixel 110a, a pixel 110b, a pixel 110c, a pixel 110d, a pixel 110e, a pixel 110f, a pixel 110g, and a pixel 110h.

### [Configuration of Pixel]

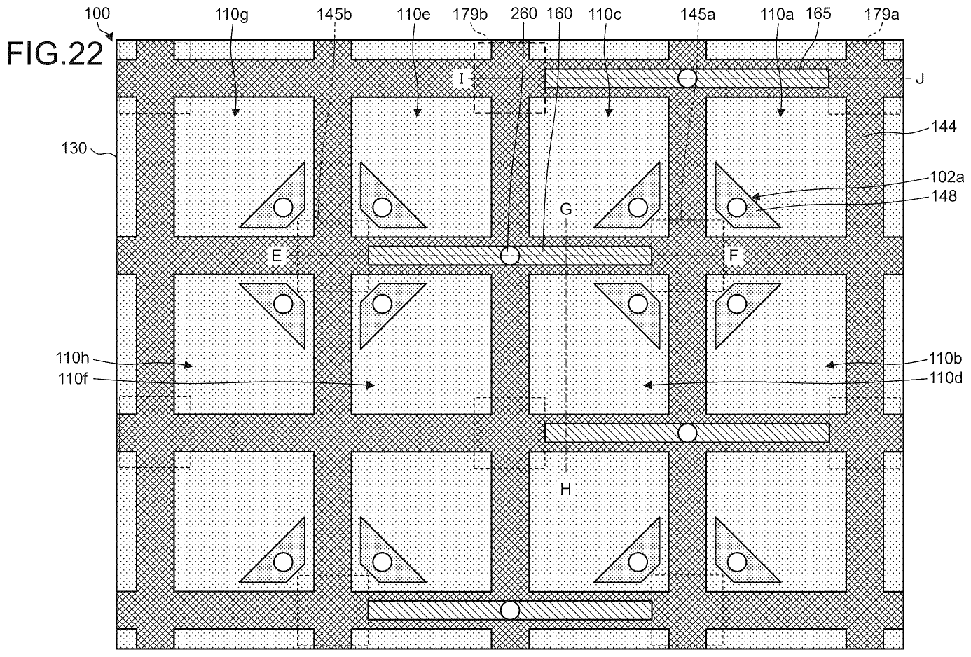

FIG. 22 is a diagram illustrating a structure example of the pixel block according to the fifth embodiment of the disclosure. The drawing is a plan view illustrating a structure example of pixels 110a to 110h in a pixel block 100. A charge transfer section 102 is disposed in each of the pixels 110. For example, a charge transfer section 102a is disposed in the pixel 110a. The charge transfer section 102 includes a gate electrode 148. The charge transfer section 102 includes a MOS transistor having a vertical gate as described later. Note that a MOS transistor having a flat plate gate can also be applied to the charge transfer section 102.

In the pixel block 100, a plurality of embedded electrodes having a shape embedded in the semiconductor substrate 130 is arranged. Specifically, in the semiconductor substrate 130, the charge holding section common electrode 145 described above and an embedded electrode 179 that transmits a reference potential to the well region in the semiconductor substrate 130 are arranged. Dotted rectangles in this figure represent these embedded electrodes. In the pixel block 100 in the drawing, charge holding section common electrodes 145a and 145b and embedded electrodes 179a and 179b are illustrated. The drawing illustrates an example in which the charge holding section common electrodes 145 and the embedded electrodes 179 are formed in a rectangular shape in plan view. Note that the charge holding section common electrodes 145 and the embedded electrodes 179 can also be formed in a cross shape in plan view. Alternatively, the charge holding section common electrodes 145 and the embedded electrodes 179 can have different shapes. As illustrated in the drawing, the charge holding section common electrodes 145 and the embedded electrodes 179 can have a shape in which a part thereof is in contact with the semiconductor region of the semiconductor substrate 130. Details of the structure of the charge holding section common electrodes 145 and the embedded electrodes 179 will be described later.

The charge holding section common electrode 145a is disposed in the vicinity of the pixels 110a to 110d and is commonly connected to charge holding sections 103 of these pixels 110. Furthermore, the charge holding section common electrode 145b is disposed in the vicinity of the pixels 110e to 110h and is commonly connected to charge holding sections 103 of these pixels 110.

The pixel block 100 in the drawing also includes a plurality of embedded wires. An embedded wire is embedded in the semiconductor substrate 130 at a boundary between pixels 110 to connect embedded electrodes to each other. Specifically, the pixel block 100 in the drawing includes: a charge holding section wire 160 that is an embedded wire connecting the charge holding section common electrodes 145; and an embedded wire 165 that is an embedded wire connecting the embedded electrodes 179. The drawing illustrates an example in which the charge holding section wire 160 and the embedded wire 165 are arranged in an isolation section 144. The charge holding section wire 160 connects the charge holding section common electrode 145a and the charge holding section common electrode 145b. Likewise, the embedded wire 165 connects the embedded electrode 179a and the embedded electrode 179b. In addition, a through wire 260 is connected to each of the charge holding section wire 160 and the embedded wire 165. The charge holding section wire 160 is connected to a pixel circuit 120 (not illustrated) via the through wires 260.

### [Structure of Cross-Section of Pixel]

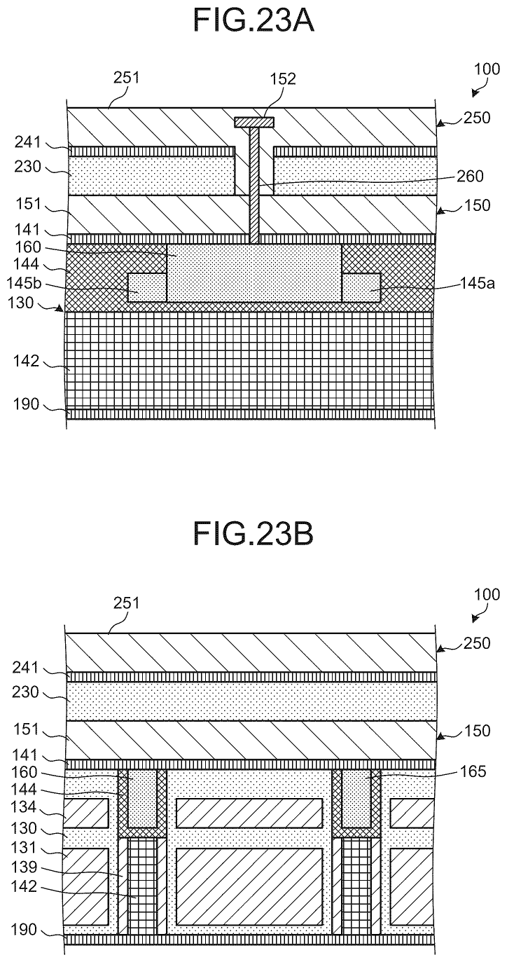

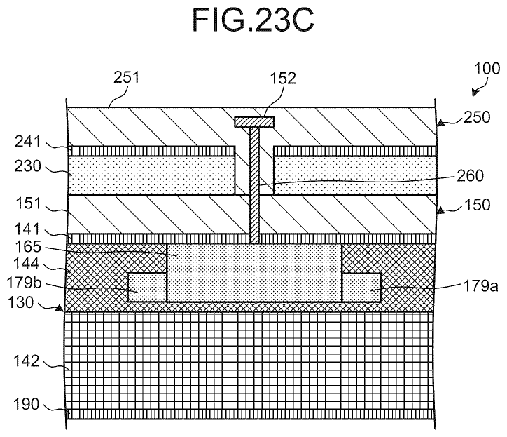

FIGS. 23A to 23C are diagrams illustrating a structure example of the pixel block according to the fifth embodiment of the disclosure. The drawing is a cross-sectional view illustrating a structure example of the pixel block 100 in the pixel array section 90. FIG. 23A is a diagram schematically illustrating the shape of a cross section taken along line E-F in FIG. 22. FIG. 23B is a diagram schematically illustrating the shape of a cross section taken along line G-H in FIG. 22. FIG. 23C is a diagram schematically illustrating the shape of a cross section taken along line I-J in FIG. 22.

In FIG. 23A, the charge holding section common electrodes 145a and 145b are embedded in the isolation section 144. The charge holding section wire 160 is disposed between and connects the charge holding section common electrodes 145a and 145b. Note that the drawing illustrates an example in which the charge holding section wire 160 has a shape in which the upper surface thereof is in contact with the surface of the semiconductor substrate 130. By adopting this structure, the through wire 260 can be disposed at any position on the upper surface of the charge holding section wire 160. The charge holding section wire 160 can be made of, for example, polycrystalline silicon containing an impurity or metal. Note that, similarly to the first embodiment of the present disclosure, the imaging element 1 according to the fifth embodiment of the present disclosure includes the semiconductor substrate 130 and the semiconductor substrate 230 that are stacked. The pixel circuit 120 (not illustrated) is disposed in the semiconductor substrate 230.

In FIG. 23B, the charge holding section wire 160 has a shape embedded in the isolation section 144. As a result, the charge holding section wire 160 is insulated from the well region and others of the semiconductor substrate 130. Similarly, the embedded wire 165 also has a shape embedded in the isolation section 144. Note that the semiconductor region 134 included in the charge holding section 103 in the drawing can be formed by ion implantation.

In FIG. 23C, the embedded electrodes 179a and 179b are embedded in the isolation section 144. Note that the embedded electrodes 179 have a shape in which a side surface perpendicular or parallel to the paper surface of the figure is in contact with the well region of the semiconductor substrate 130 and are electrically connected to the well region. The embedded wire 165 is disposed between and connects the embedded electrodes 179a and 179b. Note that the drawing illustrates an example in which the embedded wire 165 has a shape in which the upper surface thereof is in contact with the surface of the semiconductor substrate 130. The embedded electrodes 179 and the embedded wire 165 can be made of, for example, polycrystalline silicon containing an impurity or metal.

### [Manufacturing Method of Imaging Element]

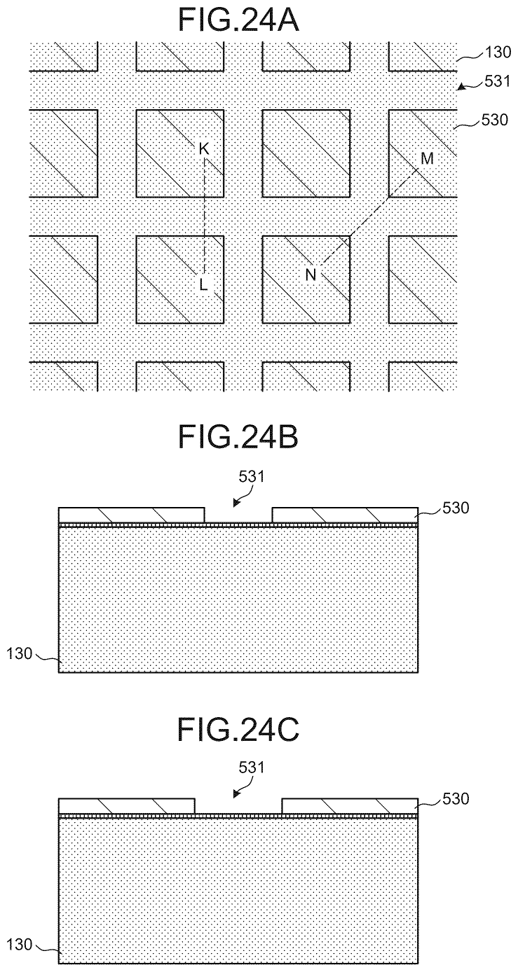

FIGS. 24A to 24C, 25A to 25C, 26A to 26C, 27A to 27C, 28A to 28C, 29A to 29C, 30A to 30C, 31A to 31C, 32A to 32C, 33A to 33C, 34A to 34C, and 35A to 34C are diagrams illustrating an example of the manufacturing method of the imaging element according to the fifth embodiment of the disclosure. The drawing illustrates an example of the manufacturing process of a pixel 110 in the imaging element 1. The manufacturing method of the pixel 110 will be described with reference to the drawings.

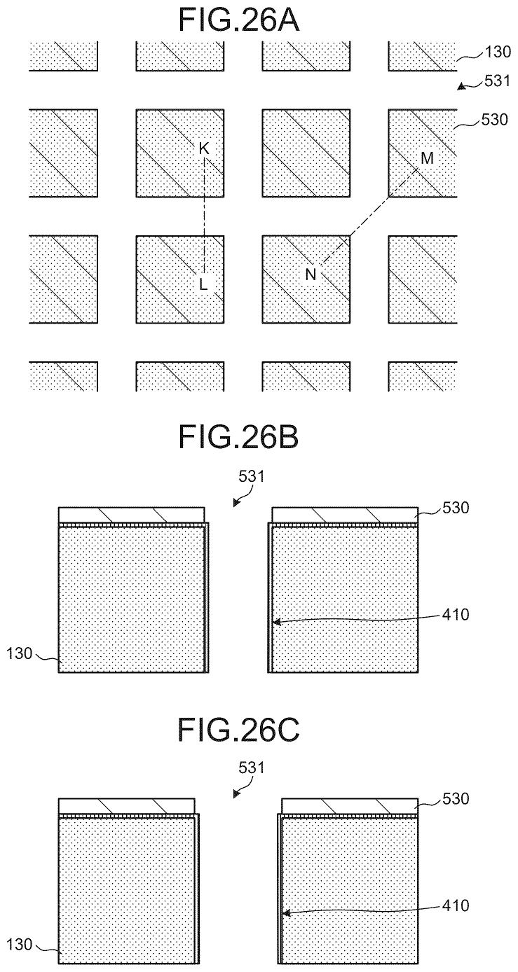

FIG. 24A is a plan view illustrating a structure of the pixel 110. FIG. 24A illustrates the semiconductor substrate 130 and a hard mask and a resist arranged on the surface of the semiconductor substrate 130 in a piece of process. FIG. 24B is a schematic cross-sectional view taken along line K-L in FIG. 24A, and FIG. 24C is a schematic cross-sectional view taken along line M-N in FIG. 24A. Hereinafter, FIGS. 26 to 35 have similar drawing structures.

In FIG. 24, a hard mask 530 is disposed on the surface of the semiconductor substrate 130 having an insulating film formed on the surface thereof (FIG. 24). In the hard mask 530, an opening 531 is formed in a region where the isolation section 144 is to be arranged. For example, an SiN film can be applied to the hard mask 530.

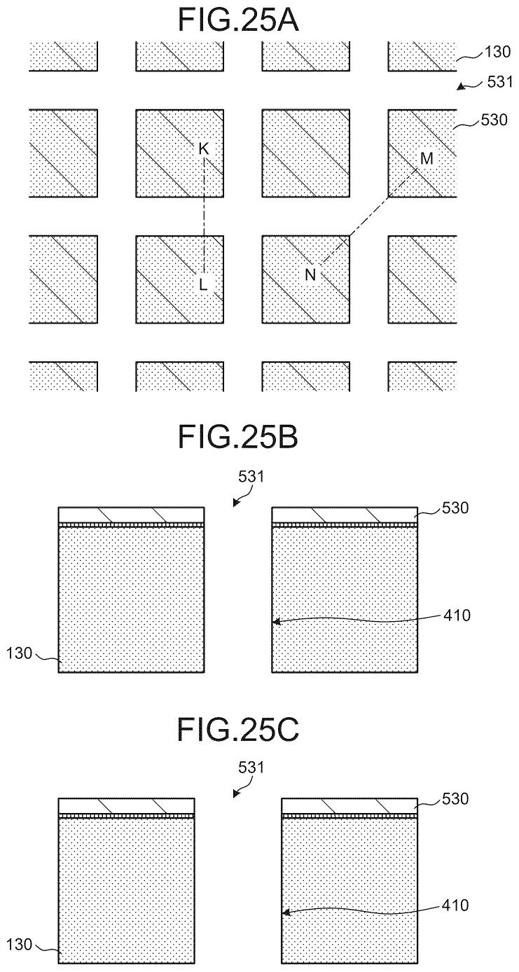

Next, the semiconductor substrate 130 is etched through the hard mask 530 to form an opening 410 (FIG. 25).

Next, an insulating film is formed on a side surface of the opening 410 (FIG. 26). This can be performed by thermal oxidation.

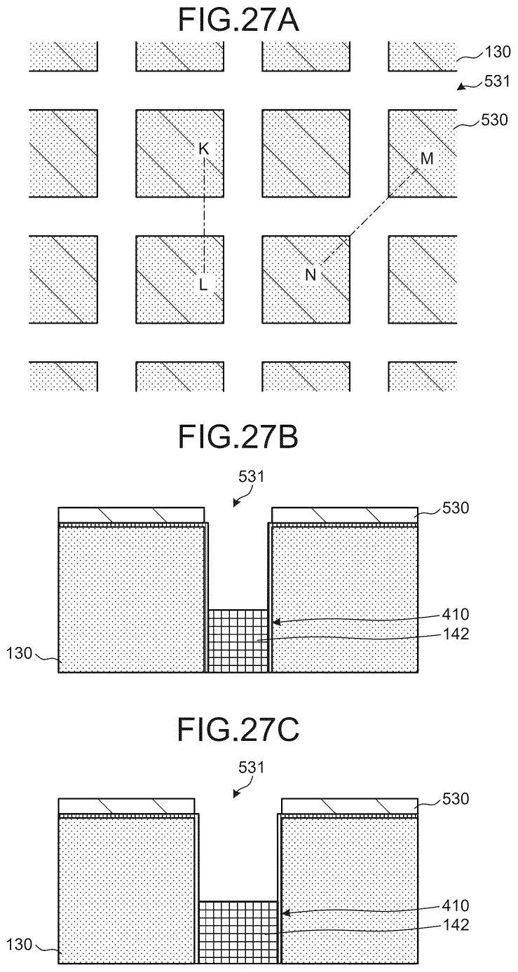

Next, an isolation section 142 is disposed in the opening 410 (FIG. 27). This can be performed by forming a material film (for example, polycrystalline silicon film) of the isolation section 142 on the surface of the semiconductor substrate 130 including the opening 410 and performing etch back to remove an unnecessary portion.

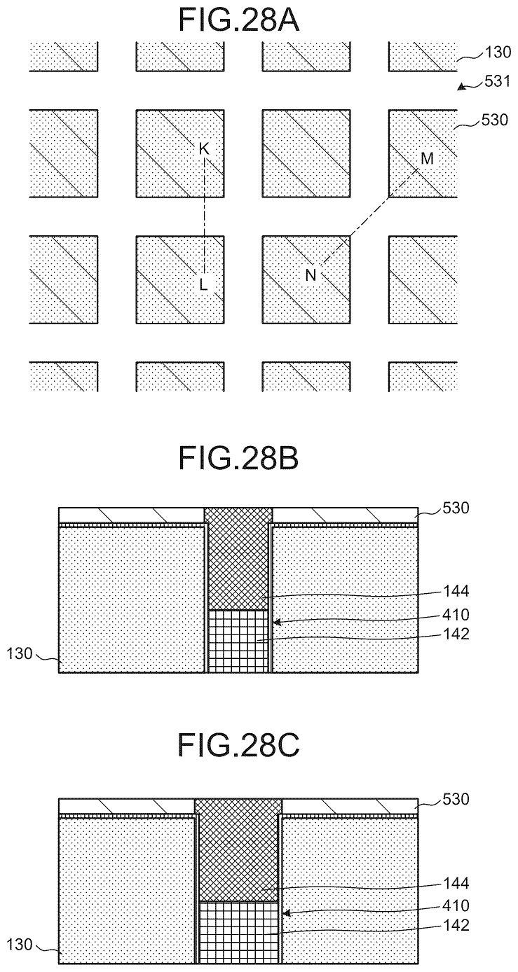

Next, an isolation section 144 is disposed in the opening 410 (FIG. 28). This can be performed by disposing a material film (for example, SiO₂ film) of the isolation section 144 on the surface of the semiconductor substrate 130 including the opening 410 and removing an unnecessary portion by performing CMP.

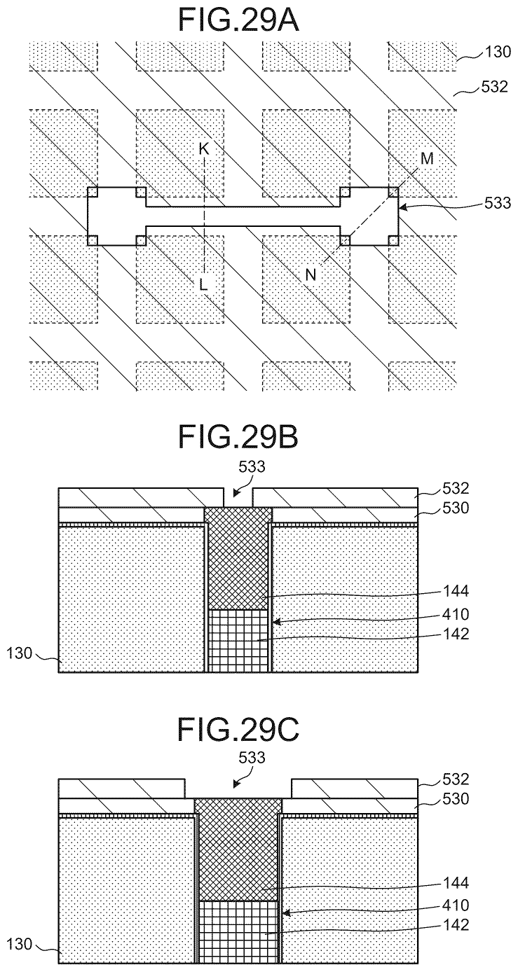

Next, a resist 532 is disposed on the surface of the semiconductor substrate 130 (FIG. 29). In the resist 532, an opening 533 is formed in a region where the charge holding section common electrodes 145 and the charge holding section wire 160 are to be arranged.

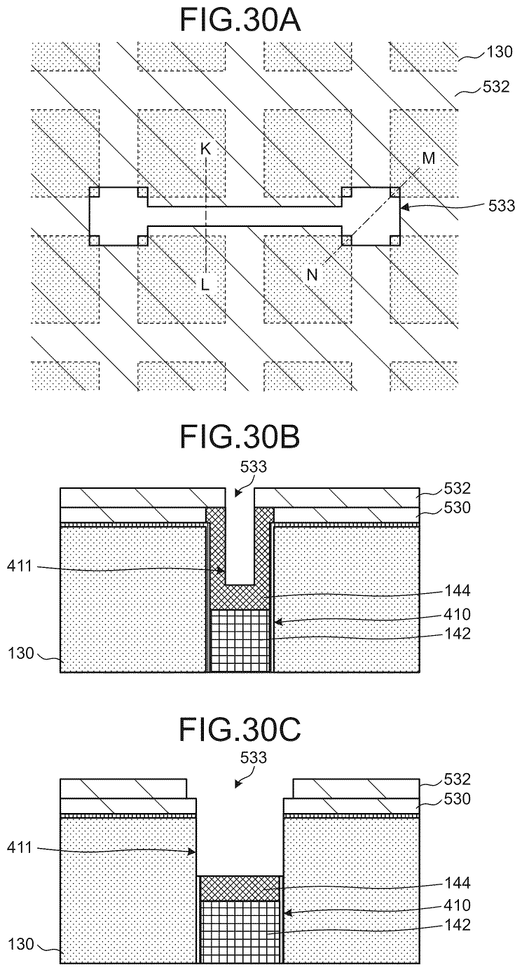

Next, the isolation section 144 is etched using the resist 532 as a mask to form an opening 411 (FIG. 30).

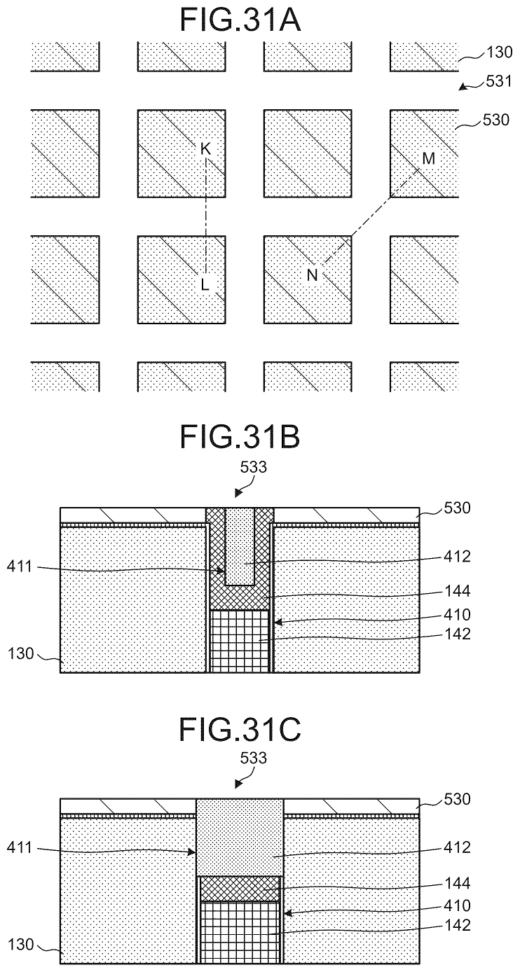

Next, the resist 532 is removed. Next, a member 412 to be a material of the charge holding section common electrodes 145 and the charge holding section wire 160 is disposed in the opening 411 (FIG. 31). This can be performed by forming a film of the member 412 on the surface of the semiconductor substrate 130 including the opening 411 and etching back to remove unnecessary portions. For example, polycrystalline silicon containing an impurity can be adopted for the member 412.

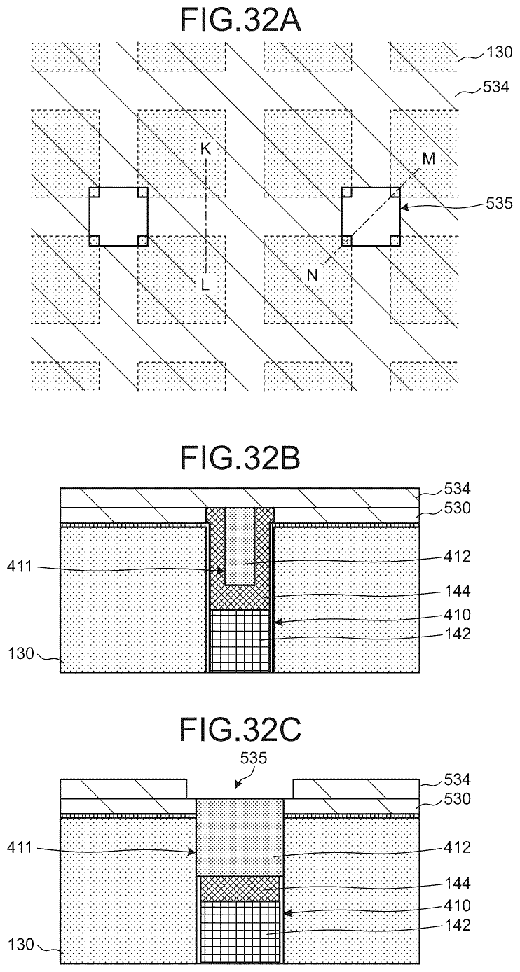

Next, a resist 534 is disposed on the surface of the semiconductor substrate 130 (FIG. 32). In the resist 534, an opening 535 is formed in a region where a charge holding section common electrode 145 is to be disposed.

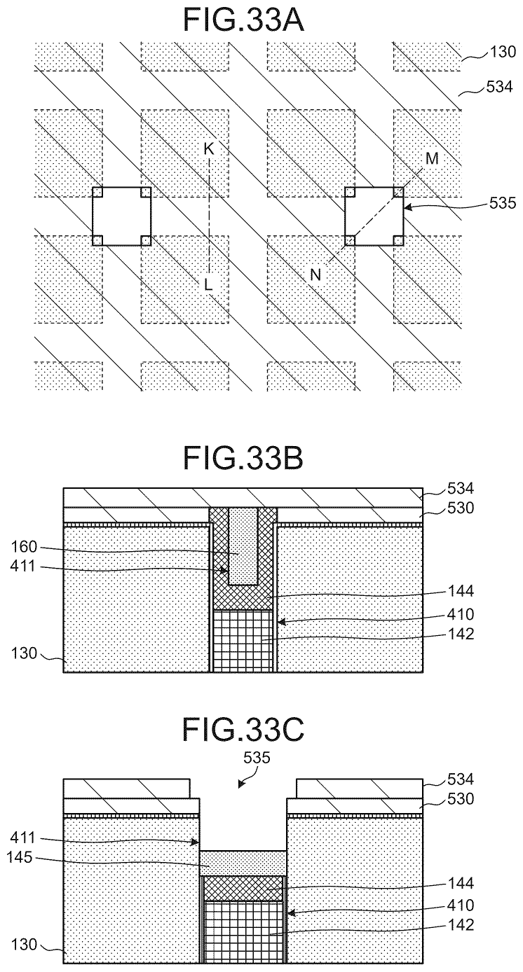

Next, the member 412 is etched using the resist 534 as a mask to thin the member 412 in the region of the opening 535. As a result, the charge holding section common electrodes 145 and the charge holding section wire 160 are formed (FIG. 33).

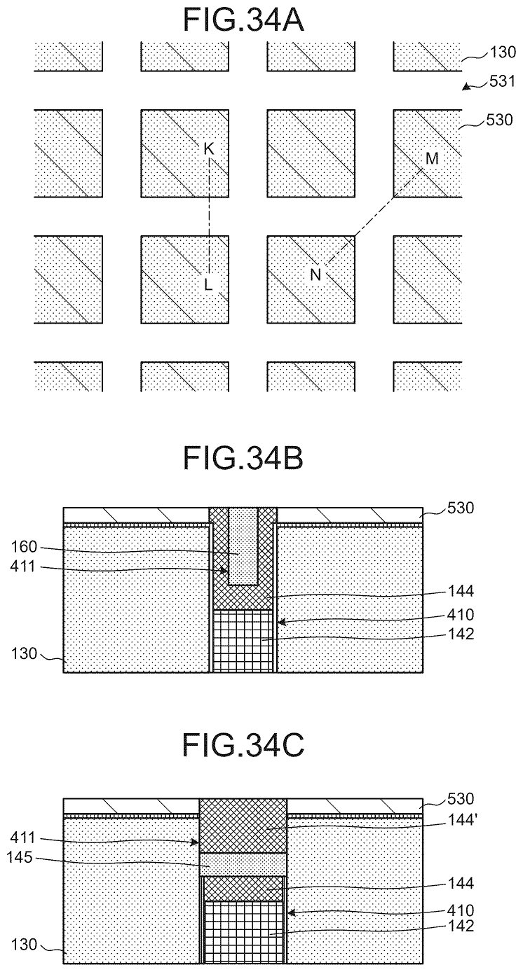

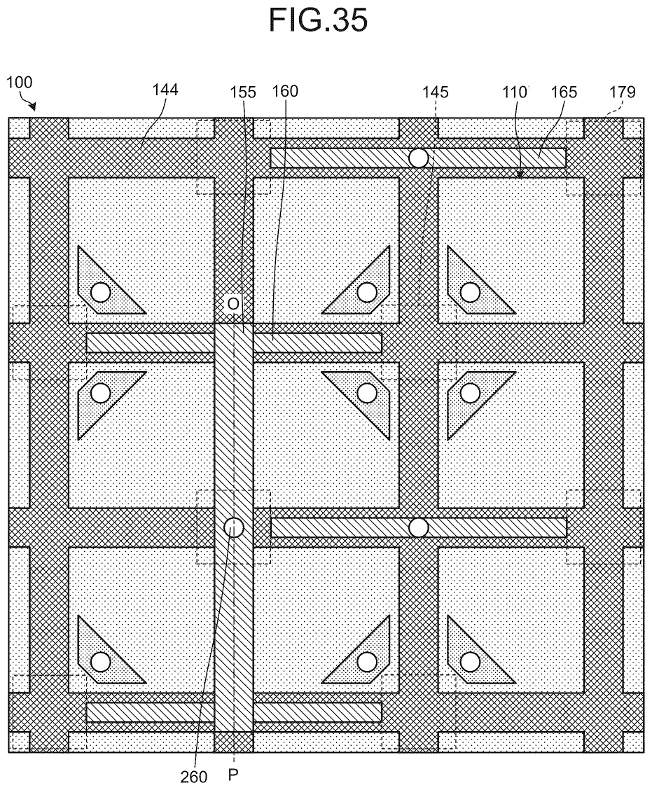

Next, the resist 534 is removed. Next, a material film of the isolation section 144 is disposed on the upper layer of the charge holding section common electrode 145 of the opening 411 to form the isolation section 144 (isolation section 144′) (FIG. 34). This can be performed by disposing the material film of the isolation section 144 on the surface of the semiconductor substrate 130 including the opening 411 and removing unnecessary portions by performing CMP.

Then, the hard mask 530 is removed. Description of the subsequent process will be omitted.

With the above process, the pixel 110 can be manufactured. Note that the manufacturing process described above illustrates an example of a case where the charge holding section common electrode 145 and the charge holding section wire 160 are simultaneously formed.

As described above, the pixel block 100 illustrated in FIG. 22 includes the charge holding section common electrode 145a and the pixels 110a to 110d commonly connected to the charge holding section common electrode 145a. The pixel block 100 further includes the charge holding section common electrode 145b and the pixels 110e to 110h commonly connected to the charge holding section common electrode 145b. Here, a plurality of pixels 110 and a charge holding section common electrode 145 commonly connected to the plurality of pixels 110 are referred to as a pixel group. The charge holding section common electrodes 145a and 145b of these pixel groups are connected by the charge holding section wire 160 embedded in the semiconductor substrate 130. The through wire 260 is disposed on the charge holding section wire 160, and the charge holding section common electrodes 145a and 145b are connected to the pixel circuit 120 via the through wire 260. As compared with the case of using the pixel block 100 in FIG. 3, the number of pixel circuits 120 arranged in the pixel array section 90 can be reduced. In addition, the number of through wires 260 connected to charge holding section common electrodes 145 can also be reduced.

Therefore, the effective region of the semiconductor substrate 230 can be expanded by applying the pixel block 100 in FIG. 22. Incidentally, the effective region refers to a region in which elements and the like of the pixel circuit 120 can be arranged. It is preferable to increase the size of the amplification transistor 121 along with the expansion of the effective region. This is because the reset transistor 123 and the like are used as a switching element, whereas the amplification transistor 121 that amplifies a signal is expected to improve performance due to size expansion. For example, noise can be reduced by expanding the size of the amplification transistor 121.

The amplification transistor 121 outputs charge fluctuations (due to heat or the like) in the gate and the channel as noise. This noise becomes random noise generated in the pixels 110. The amplification transistor 121 includes a MOS transistor. In this MOS transistor, an input capacitance is formed between the gate and the source as input terminals. Here, denoting the capacitance of the input capacitance of the gate as C, the input voltage V of the amplification transistor 121 can be expressed by the following formula.

$$V = Q / C$$

Here, Q denotes the amount of charge input to the amplification transistor 121. When fluctuation (ΔQ) occurs in Q, V fluctuates. The fluctuation (ΔV) of V is amplified and output as noise.

From the above equation, ΔV can be reduced by increasing C. Increasing C can be performed by increasing the area of the gate (gate electrode 148). That is, the noise of the pixels 110 can be reduced by expanding the size of the amplification transistor 121.

Note that the pixel block 100 according to the fifth embodiment of the disclosure is not limited to this example. For example, it is also possible to adopt a configuration in which three or more pixel groups are arranged in the pixel block 100. In this case, each charge holding section wire 160 connects charge holding section common electrodes 145 of one of pixel groups.

The configuration of the imaging element 1 other than the above is similar to the configuration of the imaging element 1 in the first embodiment of the present disclosure, and thus description thereof is omitted.

As described above, in the pixel block 100 according to the fifth embodiment of the present disclosure, the charge holding section wire 160 is disposed, and the through wire 260 and the pixel circuit 120 are shared by the plurality of pixel groups. As a result, the effective area of the pixel block 100 can be increased.

### 8. Modifications of Fifth Embodiment

Next, modifications of the imaging element 1 of the fifth embodiment described above will be described.

### [First Modification]

FIG. 35 is a diagram illustrating a structure example of a pixel block according to a first modification of the fifth embodiment of the disclosure. The drawing is a plan view illustrating a structure example of a pixel block 100 similarly to FIG. 22. The pixel block 100 in the drawing is different from the pixel block 100 in FIG. 22 in that a wire 155 that connects charge holding section wires 160 to each other is included.

### [Structure of Cross-Section of Pixel]

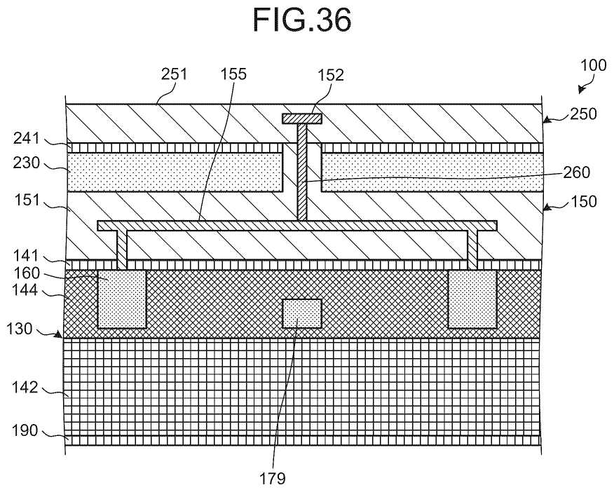

FIG. 36 is a diagram illustrating a structure example of a pixel block according to a first modification of the fifth embodiment of the disclosure. The drawing is, similarly to FIG. 23A, a cross-sectional view illustrating a structure example of a pixel block 100 in a pixel array section 90. FIG. 36 is a diagram schematically illustrating the shape of a cross section taken along line O-P in FIG. 35. As illustrated in the drawing, the wire 155 is disposed in a wiring region 150 of the semiconductor substrate 130. The wire 155 also connects a plurality of charge holding section wires 160. A through wire 260 is connected to the wire 155. The wire 155 can be made of, for example, polycrystalline silicon containing an impurity. By using the wire 155, the number of through wires 260 can be reduced as compared with a case where a through wire 260 is disposed for each charge holding section wire 160.

### [Second Modification]

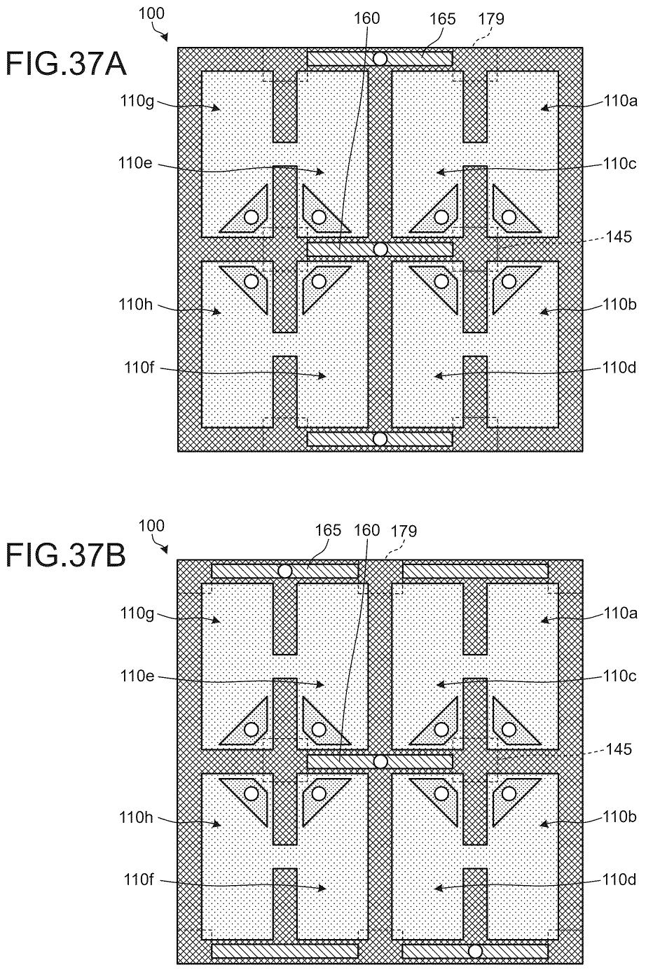

FIGS. 37A and 37B are diagrams illustrating a structure example of a pixel block according to a second modification of the fifth embodiment of the disclosure. The drawing is a plan view illustrating a configuration example of a pixel block 100. The pixel block 100 in the drawing illustrates an example in which each pixel of a pixel 110a and a pixel 110c, a pixel 110b and a pixel 110d, a pixel 110e and a pixel 110g, and a pixel 110f and a pixel 110h is formed in a rectangular shape obtained by dividing a square into two. Since the functions and others of the pixel 110a and the pixel 110c are similar to those in FIG. 14, the description thereof will be omitted.

The pixel block 100 in FIG. 37A represents an example in which four embedded electrodes 179 and two embedded wires 165 are included. Meanwhile, FIG. 37B illustrates an example in which six embedded electrodes 179 and four embedded wires 165 are included.

### [Third Modification]

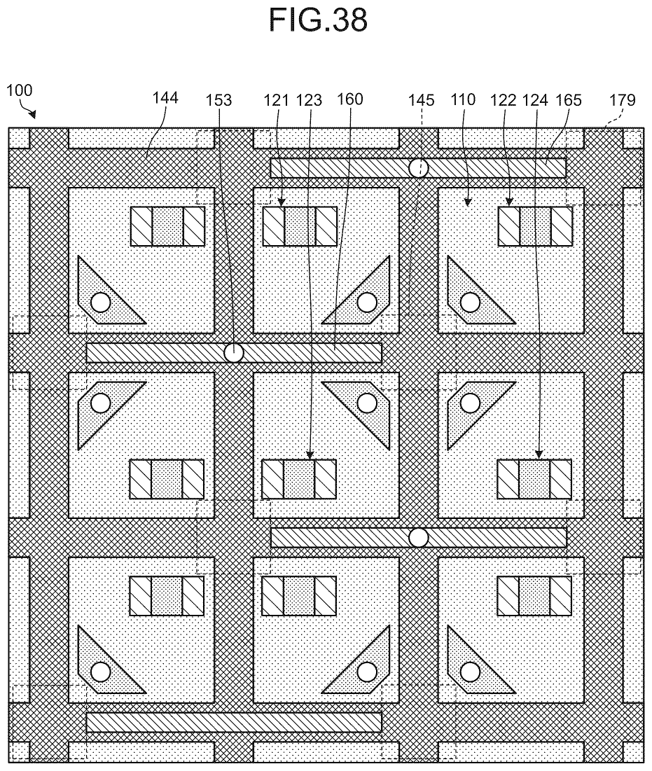

FIG. 38 is a diagram illustrating a structure example of a pixel block according to a third modification of the fifth embodiment of the disclosure. The drawing is a plan view illustrating a structure example of a pixel block 100 similarly to FIG. 22. The pixel block 100 in the drawing represents an example of a case where the semiconductor substrate 230 is omitted. In the pixel block 100 in the drawing, a pixel circuit 120 is arranged in the semiconductor substrate 130. Specifically, an amplification transistor 121, a selection transistor 122, a reset transistor 123, and a coupling transistor 124 are arranged for each pixel 110. Note that a contact plug 153 is connected to a charge holding section wire 160 or the like instead of the through wire 260.

### [Fourth Modification]

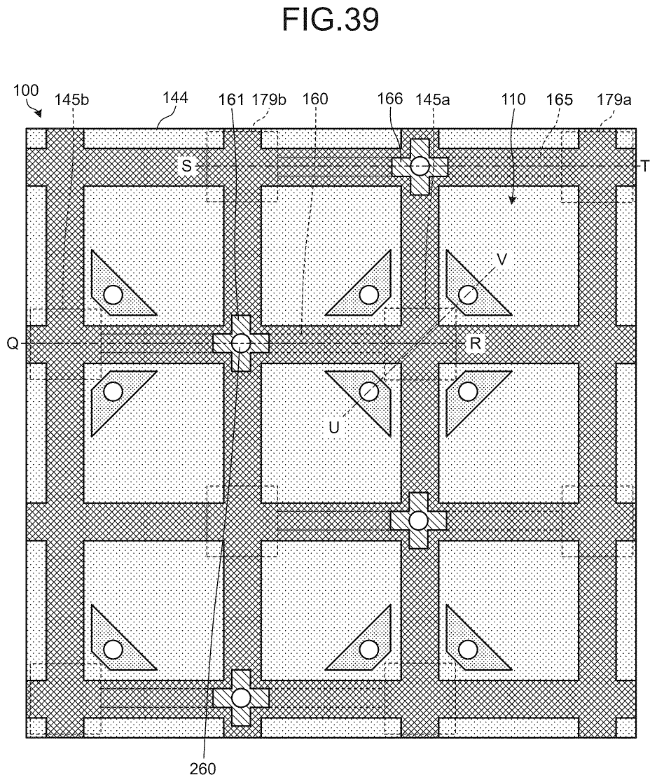

FIG. 39 is a diagram illustrating a structure example of a pixel block according to a fourth modification of the fifth embodiment of the disclosure. The drawing is a plan view illustrating a structure example of a pixel block 100 similarly to FIG. 22. The pixel block 100 in the drawing is different from the pixel block 100 in FIG. 22 in including a charge holding section wire 160 and an embedded wire 165 arranged apart from the surface with which a wiring region 150 is in contact with a semiconductor substrate 130. By adopting a structure in which the charge holding section wire 160 is disposed inside an isolation section 144 in this manner, the parasitic capacitance can be reduced.

In addition, the charge holding section wire 160 in the drawing represents an example in which a wiring connection section 161 is included. The wiring connection section 161 has a shape protruding from the front surface of the semiconductor substrate 130 and is connected to another wire. Similarly, the wiring connection section 166 is disposed at the embedded wire 165.

### [Structure of Cross-Section of Pixel]

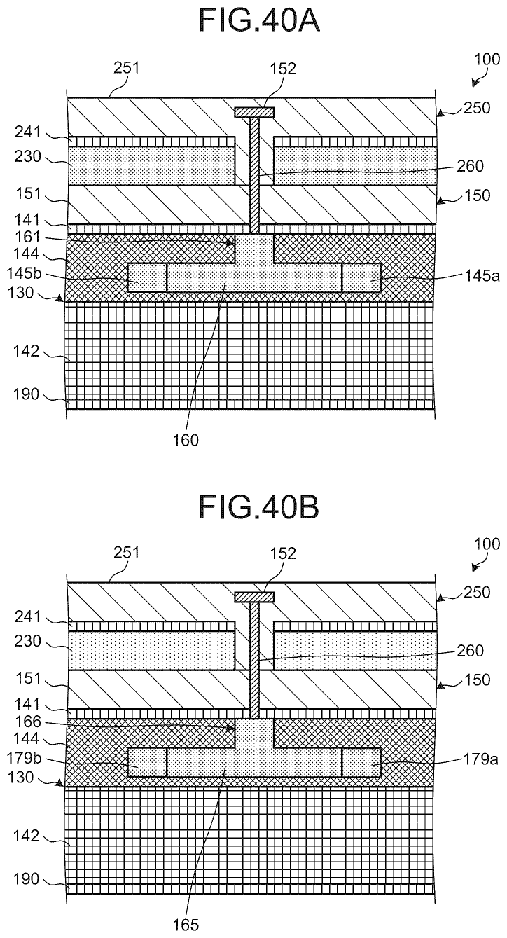

FIGS. 40A and 40B are diagrams illustrating a structure example of a pixel block according to the fourth modification of the fifth embodiment of the disclosure. The drawing is, similarly to FIG. 23A, a cross-sectional view illustrating a structure example of a pixel block 100 in a pixel array section 90.

FIG. 40A is a diagram schematically illustrating the shape of a cross section taken along line Q-R in FIG. 39. As illustrated in the drawing, a through wire 260 is connected to the wiring connection section 161. FIG. 40B schematically illustrates the shape of a cross section taken along line S-T in FIG. 39. As illustrated in the drawing, a through wire 260 is connected to the wiring connection section 166.

### [Fifth Modification]

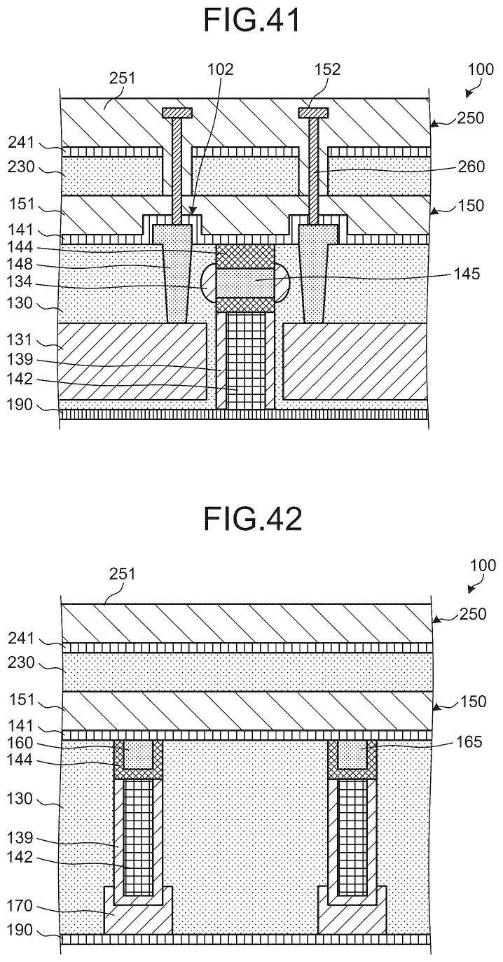

FIG. 41 is a diagram illustrating a structure example of a pixel block according to a fifth modification of the fifth embodiment of the disclosure. The drawing is a cross-sectional view illustrating a structure example of the pixel block 100 in the pixel array section 90. The drawing schematically illustrates the shape of a cross section taken along line U-V in FIG. 39. As illustrated in the drawing, the charge transfer section 102 includes a gate electrode 148 structured as a vertical gate. Furthermore, a semiconductor region 134 included in a charge holding section 103 in the drawing illustrates an example of formation by thermal diffusion. Specifically, the semiconductor region 134 in the drawing is formed by thermal diffusion of an impurity contained in a charge holding section common electrode 145 into a well region of the semiconductor substrate 130.

### [Sixth Modification]

FIG. 42 is a diagram illustrating a structure example of a pixel block according to a sixth modification of the fifth embodiment of the disclosure. The drawing is, similarly to FIG. 23B, a cross-sectional view illustrating a structure example of a pixel block 100 in a pixel array section 90. An isolation section 142 in the drawing illustrates an example in which a bottom portion thereof has a shape reaching the vicinity of the back surface of a semiconductor substrate 130. The isolation section 170 is disposed between the bottom portion of the isolation section 142 and the back surface of the semiconductor substrate 130. The isolation section 170 can be formed by a semiconductor region having a relatively high impurity concentration.

The configuration of the imaging element 1 other than the above is similar to the configuration of the imaging element 1 in the fifth embodiment of the present disclosure, and thus description thereof is omitted.

### 9. Other Configuration Examples

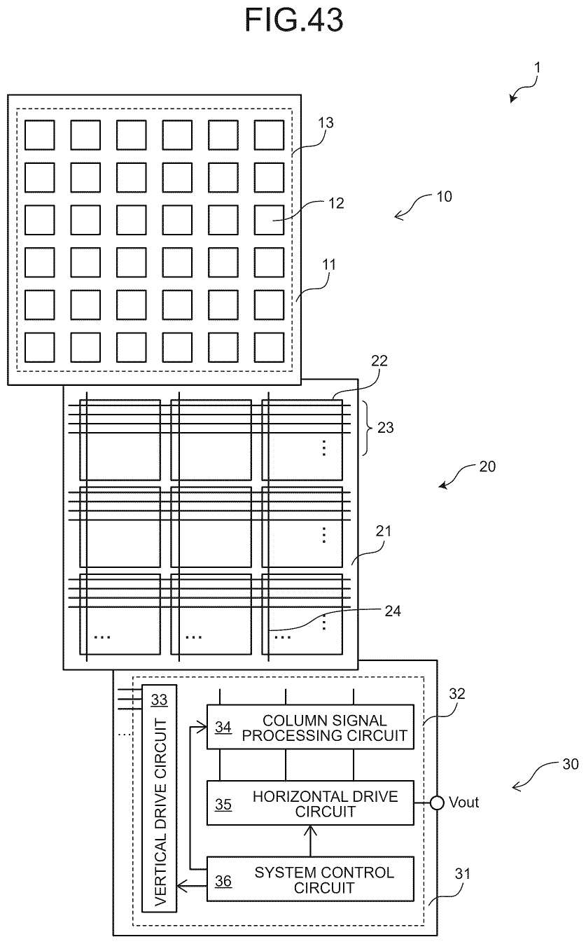

FIG. 43 is a diagram illustrating another configuration example of an imaging element. An imaging element 1 includes three substrates (first substrate 10, second substrate 20, and third substrate 30). The imaging element 1 has a three-dimensional structure formed by bonding the three substrates (first substrate 10, second substrate 20, and third substrate 30). The first substrate 10, the second substrate 20, and the third substrate 30 are stacked in this order.

The first substrate 10 includes, in a semiconductor substrate 11, a plurality of sensor pixels 12 that performs photoelectric conversion. The semiconductor substrate 11 corresponds to a specific example of the “first semiconductor substrate” of the present disclosure. The plurality of sensor pixels 12 is provided in a matrix shape in a pixel region 13 of the first substrate 10. The second substrate 20 includes, in a semiconductor substrate 21, a readout circuit 22 that outputs a pixel signal based on charges output from sensor pixels 12, the readout circuit 22 each provided for every four sensor pixels 12. The semiconductor substrate 21 corresponds to a specific example of the “second semiconductor substrate” of the present disclosure. The second substrate 20 includes a plurality of pixel drive lines 23 extending in the row direction and a plurality of vertical signal lines 24 extending in the column direction. The third substrate 30 includes, in a semiconductor substrate 31, a logic circuit 32 that processes a pixel signal. The semiconductor substrate 31 corresponds to a specific example of the “third semiconductor substrate” of the present disclosure. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each of the sensor pixels 12 to the outside. In the logic circuit 32, for example, a low resistance region, made of silicide formed using a self-aligned silicide process such as CoSi2 or NiSi, may be formed on a surface of an impurity diffusion region in contact with a source electrode and a drain electrode.

The vertical drive circuit 33 sequentially selects, for example, a plurality of sensor pixels 12 row by row. The column signal processing circuit 34 performs, for example, correlated double sampling (CDS) processing on a pixel signal output from each of the sensor pixels 12 of the row selected by the vertical drive circuit 33. The column signal processing circuit 34 extracts a signal level of a pixel signal by performing, for example, the CDS processing and holds pixel data corresponding to the amount of light received by each of the sensor pixels 12. The horizontal drive circuit 35 sequentially outputs, for example, the pixel data held in the column signal processing circuit 34 to the outside. The system control circuit 36 controls driving of each block (the vertical drive circuit 33, the column signal processing circuit 34, and the horizontal drive circuit 35) in the logic circuit 32, for example.

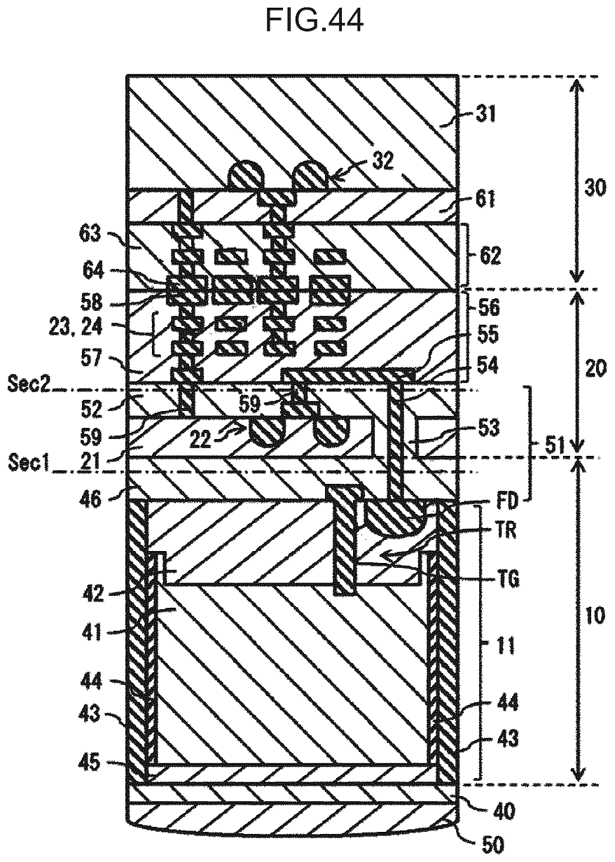

FIG. 44 is a cross-sectional view illustrating another configuration example of the imaging element. The drawing illustrates an example of a cross-sectional structure in the vertical direction of the imaging element 1 in FIG. 43. FIG. 44 illustrates an example of a cross-sectional structure of a portion facing a sensor pixel 12 in the imaging element 1. The imaging element 1 is structured by stacking the first substrate 10, the second substrate 20, and the third substrate 30 in this order and further includes a color filter 40 and a light receiving lens 50 on the back surface side (light incident surface side) of the first substrate 10. For example, one color filter 40 and one light receiving lens 50 are provided for every sensor pixel 12. That is, the imaging element 1 is a back-illuminated type.

The first substrate 10 is formed by stacking an insulating layer 46 on the semiconductor substrate 11. The first substrate 10 includes the insulating layer 46 as a part of an interlayer insulating film 51. The insulating layer 46 is included in a gap between the semiconductor substrate 11 and the semiconductor substrate 21 to be described later. The semiconductor substrate 11 is formed of a silicon substrate. The semiconductor substrate 11 has, for example, a p-well layer 42 at a part of the front surface and in the vicinity thereof and a PD 41 having a conductivity type different from that of the p-well layer 42 in another region (region deeper than the p-well layer 42). The p-well layer 42 is formed of a p-type semiconductor region. The PD41 is formed of a semiconductor region of a conductivity type (specifically, n-type) different from that of the p-well layer 42. The semiconductor substrate 11 has, in the p-well layer 42, a floating diffusion FD as a semiconductor region of a conductivity type (specifically, n-type) different from that of the p-well layer 42.

The first substrate 10 includes a photodiode PD, a transfer transistor TR, and a floating diffusion FD for each sensor pixel 12. The first substrate 10 has a structure in which the transfer transistor TR and the floating diffusion FD are included in a portion on the front surface side (side opposite to the light incident surface side, second substrate 20 side) of the semiconductor substrate 11. The first substrate 10 includes an element isolation section 43 that isolates each sensor pixel 12. The element isolation section 43 is formed to extend in the normal direction of the semiconductor substrate 11 (direction perpendicular to the front surface of the semiconductor substrate 11). The element isolation section 43 is included between two sensor pixels 12 adjacent to each other. The element isolation section 43 electrically isolates the sensor pixels 12 adjacent to each other from each other. The element isolation section 43 is made of, for example, silicon oxide. The element isolation section 43 penetrates the semiconductor substrate 11, for example. The first substrate 10 further includes a p-well layer 44 that is, for example, a side surface of the element isolation section 43 and is in contact with a surface on the photodiode PD side. The p-well layer 44 is formed of a semiconductor region of a conductivity type (specifically, p-type) different from that of the photodiode PD. The first substrate 10 further includes, for example, a fixed charge film 45 in contact with the back surface of the semiconductor substrate 11. The fixed charge film 45 is negatively charged in order to suppress generation of a dark current caused by an interface state on the light-receiving surface side of the semiconductor substrate 11. The fixed charge film 45 is formed of, for example, an insulating film having a negative fixed charge. Examples of the material of such an insulating film include hafnium oxide, zircon oxide, aluminum oxide, titanium oxide, and tantalum oxide. A hole accumulation layer is formed at an interface on the light-receiving surface side of the semiconductor substrate 11 by an electric field induced by the fixed charge film 45. The hole accumulation layer suppresses generation of electrons from the interface. The color filter 40 is provided on the back surface side of the semiconductor substrate 11. The color filter 40 is, for example, in contact with the fixed charge film 45 and is included at a position facing the sensor pixel 12 via the fixed charge film 45. The light receiving lens 50 is, for example, in contact with the color filter 40 and is included at a position facing the sensor pixel 12 via the color filter 40 and the fixed charge film 45.

The second substrate 20 is formed by stacking an insulating layer 52 on the semiconductor substrate 21. The second substrate 20 includes the insulating layer 52 as a part of the interlayer insulating film 51. The insulating layer 52 is included in a gap between the semiconductor substrate 21 and the semiconductor substrate 31. The semiconductor substrate 21 is formed of a silicon substrate. The second substrate 20 includes one readout circuit 22 for every four sensor pixels 12. The second substrate 20 has a structure in which a readout circuit 22 is included in a portion on the front surface side (third substrate 30 side) of the semiconductor substrate 21. The second substrate 20 is bonded to the first substrate 10 with the back surface of the semiconductor substrate 11 facing the front surface side of the semiconductor substrate 21. That is, the second substrate 20 is bonded to the first substrate 10 in a face-to-back manner. The second substrate 20 further includes an insulating layer 53 penetrating the semiconductor substrate 21 in the same layer as the semiconductor substrate 21. The second substrate 20 includes the insulating layer 53 as a part of the interlayer insulating film 51. The insulating layer 53 is included in such a manner as to cover a side surface of a through wire 54 to be described later.

The stacked body including the first substrate 10 and the second substrate 20 includes the interlayer insulating film 51 and the through wire 54 included in the interlayer insulating film 51. The stacked body has one through wire 54 for each sensor pixel 12. The through wire 54 extends in the normal direction of the semiconductor substrate 21 and penetrates a portion including the insulating layer 53 in the interlayer insulating film 51. The first substrate 10 and the second substrate 20 are electrically connected to each other by the through wire 54. Specifically, the through wire 54 is electrically connected to the floating diffusion FD and a connection wire 55 to be described later.

The stacked body including the first substrate 10 and the second substrate 20 further includes through wires 47 and 48 included in the interlayer insulating film 51. The stacked body has one through wire 47 and one through wire 48 for each sensor pixel 12. Each of the through wires 47 and 48 extends in the normal direction of the semiconductor substrate 21 and penetrates the portion including the insulating layer 53 in the interlayer insulating film 51. The first substrate 10 and the second substrate 20 are electrically connected to each other by the through wires 47 and 48. Specifically, the through wire 47 is electrically connected to the p-well layer 42 of the semiconductor substrate 11 and a wire in the second substrate 20. The through wire 48 is electrically connected to a transfer gate TG and a pixel drive line 23.

The second substrate 20 includes, for example, in the insulating layer 52, a plurality of connection sections 59 electrically connected to the readout circuits 22 and the semiconductor substrate 21. The second substrate 20 further includes, for example, a wiring layer 56 on the insulating layer 52. The wiring layer 56 includes, for example, an insulating layer 57 and a plurality of pixel drive lines 23 and a plurality of vertical signal lines 24 included in the insulating layer 57. The wiring layer 56 further includes, for example, a plurality of connection wires 55 in the insulating layer 57 with one connection wire provided for every four sensor pixels 12. The connection wire 55 electrically connects through wires 54, electrically connected to floating diffusions FD included in four sensor pixels 12 sharing a readout circuit 22, to each other. Here, the total number of the through wires 54 and 48 is larger than the total number of the sensor pixels 12 included in the first substrate 10 and is twice the total number of the sensor pixels 12 included in the first substrate 10. In addition, the total number of the through wires 54, 48, and 47 is larger than the total number of the sensor pixels 12 included in the first substrate 10 and is three times the total number of the sensor pixels 12 included in the first substrate 10.

The wiring layer 56 further includes, for example, a plurality of pad electrodes 58 in the insulating layer 57. Each of the pad electrodes 58 is formed of metal such as copper (Cu) or aluminum (Al). Each of the pad electrodes 58 is exposed on the front surface of the wiring layer 56. Each of the pad electrodes 58 is used for electrical connection between the second substrate 20 and the third substrate 30 and bonding between the second substrate 20 and the third substrate 30. For example, one pad electrode 58 is provided for each pair of a pixel drive line 23 and a vertical signal line 24. Here, the total number of pad electrodes 58 (or the total number of junctions between the pad electrodes 58 and the pad electrodes 64 (described later) is smaller than the total number of sensor pixels 12 included in the first substrate 10.

The third substrate 30 is formed by stacking an interlayer insulating film 61 on the semiconductor substrate 31, for example. As will be described later, since the third substrate 30 is bonded to the second substrate 20 with the front surfaces thereof facing each other, the description in the vertical direction is opposite to the vertical direction in the drawings when the structure in the third substrate 30 is described. The semiconductor substrate 31 is formed of a silicon substrate. The third substrate 30 has a structure in which a logic circuit 32 is included in a portion on the front surface side of the semiconductor substrate 31. The third substrate 30 further includes, for example, a wiring layer 62 on the interlayer insulating film 61. The wiring layer 62 includes, for example, an insulating layer 63 and a plurality of pad electrodes 64 included in the insulating layer 63. The plurality of pad electrodes 64 is electrically connected to the logic circuit 32. Each of the pad electrodes 64 is formed of, for example, Cu (copper). Each of the pad electrodes 64 is exposed on the front surface of the wiring layer 62. Each of the pad electrodes 64 is used for electrical connection between the second substrate 20 and the third substrate 30 and bonding between the second substrate 20 and the third substrate 30. In addition, the number of pad electrodes 64 is not necessarily plural, and even one pad electrode can implement electric connection with the logic circuit 32. The second substrate 20 and the third substrate 30 are electrically connected to each other by bonding between the pad electrodes 58 and 64. That is, the gate (transfer gate TG) of the transfer transistor TR is electrically connected to the logic circuit 32 via the through wire 54 and the pad electrodes 58 and 64. The third substrate 30 is bonded to the second substrate 20 with the front surface of the semiconductor substrate 31 facing the front surface side of the semiconductor substrate 21. That is, the third substrate 30 is bonded to the second substrate 20 in a face-to-face manner.

The first substrate 10 and the second substrate 20 in FIGS. 43 and 44 correspond to the semiconductor substrate 130 and the semiconductor substrate 230 of the first embodiment, respectively. A semiconductor substrate corresponding to the third substrate 30 described above can also be stacked on the semiconductor substrate 230. Furthermore, four or more semiconductor substrates can be stacked. Such a configuration in which three or more layers of semiconductor substrates are stacked can be applied to each of the embodiments of the present disclosure.

Note that the arrangement of circuit elements constituting a pixel block 100 is not limited to the example of FIG. 5. For example, all the elements of the pixel circuit 120 may be included in the semiconductor substrate 130. A pixel circuit, a signal processing circuit, a memory circuit, a logic circuit, and others formed by an analog circuit or a digital circuit can be desirably disposed in the semiconductor substrate 230 or a semiconductor substrate further added desirably.

### 10. Application Examples

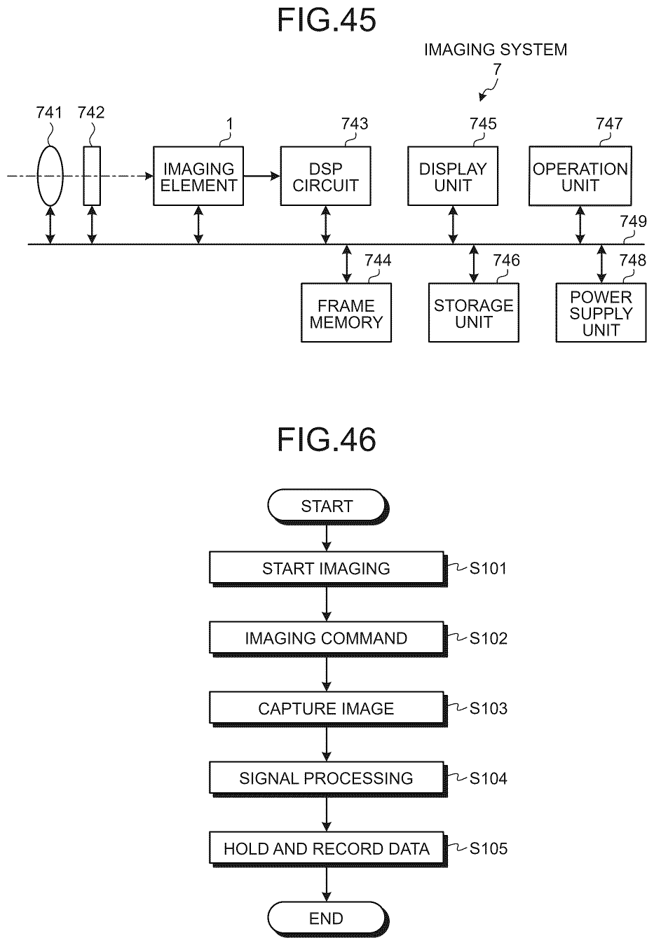

FIG. 45 is a diagram illustrating an example of a schematic configuration of an imaging system 7 including the imaging device 1 according to one of the embodiments and the modifications thereof.

The imaging system 7 is an electronic device such as an imaging device, such as a digital still camera or a video camera, or a portable terminal device such as a smartphone or a tablet terminal. The imaging system 7 includes, for example, the imaging device 1 according to one of the above-described embodiments and the modifications thereof, a DSP circuit 743, a frame memory 744, a display section 745, a storage section 746, an operation section 747, and a power supply section 748. In the imaging system 7, the imaging device according one of the embodiments and the modifications thereof, the DSP circuit 743, the frame memory 744, the display section 745, the storage section 746, the operation section 747, and the power supply section 748 are mutually connected via a bus line 749.

The imaging device 1 according to one of the embodiments and the modifications thereof outputs image data corresponding to incident light. The DSP circuit 743 is a signal processing circuit that processes a signal (image data) output from the imaging device 1 according to one of the embodiments and the modifications thereof. The frame memory 744 temporarily holds image data processed by the DSP circuit 743 for every frame. The display section 745 includes a panel-type display device such as a liquid crystal panel or an organic electro luminescence (EL) panel and displays a moving image or a still image captured by the imaging device 1 according to one of the embodiments and the modifications thereof. The storage section 746 records the image data of a moving image or a still image captured by the imaging device 1 according to one of the embodiments and the modifications thereof in a recording medium such as a semiconductor memory or a hard disk. The operation section 747 issues operation commands for various functions of the imaging system 7 on the basis of an operation by a user. The power supply section 748 supplies various power sources that serve as operation power sources of the imaging device 1 according to one of the embodiments and the modifications thereof, the DSP circuit 743, the frame memory 744, the display section 745, the storage section 746, and the operation section 747 to these supply targets as appropriate.

Next, an imaging procedure in the imaging system 7 will be described.

FIG. 46 is a diagram illustrating an example of a flowchart of an imaging operation in the imaging system 7. A user instructs to start imaging by operating the operation section 747 (Step S101). Then, the operation section 747 transmits an imaging command to the imaging device 1 (Step S102). Upon receiving the imaging command, the imaging device 1 (specifically, system control circuit 36) executes imaging by a predetermined imaging scheme (Step S103).

The imaging device 1 outputs image data obtained by the imaging to the DSP circuit 743. Incidentally, the image data refers to data, for all the pixels, of pixel signals generated on the basis of charges temporarily held in floating diffusions FD. The DSP circuit 743 performs predetermined signal processing (for example, noise reduction processing) on the basis of the image data input from the imaging device 1 (Step S104). The DSP circuit 743 causes the frame memory 744 to hold the image data having been subjected to the predetermined signal processing, and the frame memory 744 causes the storage section 746 to record the image data (Step S105). In this manner, imaging in the imaging system 7 is performed.

In the present application example, the imaging device 1 according to one of the above-described embodiments and the modifications thereof is applied to the imaging system 7. As a result, the imaging device 1 can be downsized or have high definition, and thus it is possible to provide the imaging system 7 that is downsized or has high definition.

### 11. Application Example to Mobile Body

The technology according to the present disclosure (present technology) can be applied to various products. For example, the technology according to the present disclosure may be implemented as a device to be mounted on a mobile body of any type such as automobiles, electric vehicles, hybrid electric vehicles, motorcycles, bicycles, personal mobilities, airplanes, drones, ships, and robots.

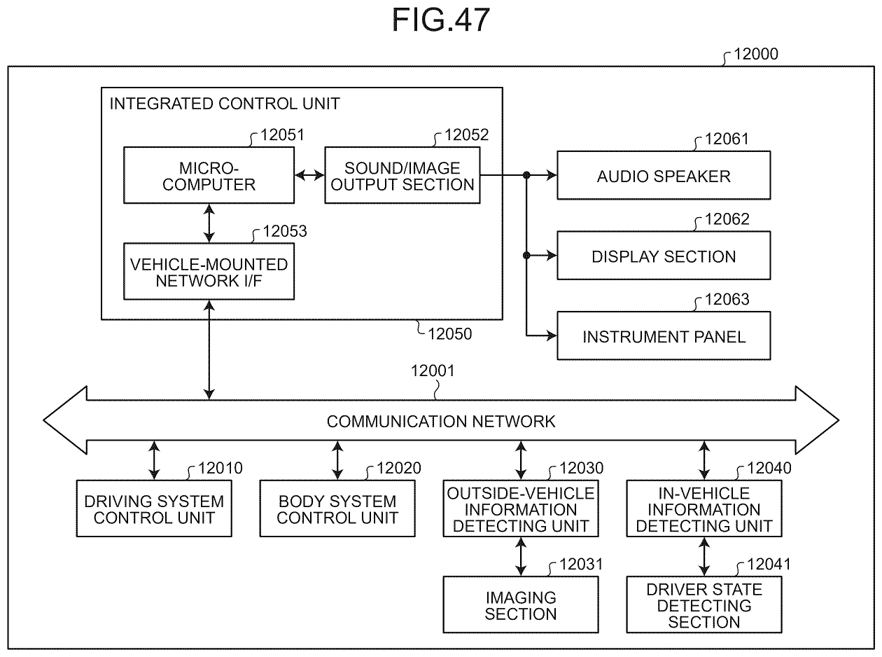

FIG. 47 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 47, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 47, an audio speaker 12061, a display section 12062, and an instrument panel 12063 are illustrated as the output device. The display section 12062 may, for example, include at least one of an on-board display and a head-up display.

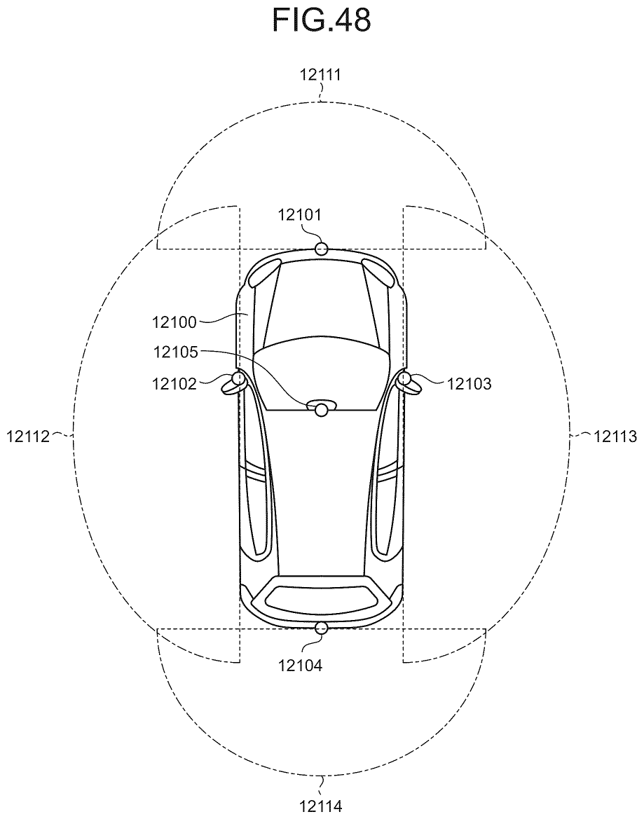

FIG. 48 is a diagram depicting an example of the installation position of the imaging section 12031.

In FIG. 48, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 48 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 in the above-described configuration. Specifically, the imaging element 1 in FIG. 1 can be applied to the imaging section 12031. By applying the technology according to the present disclosure to the imaging section 12031, it is possible to prevent deterioration of the image quality of the imaging section 12031.

### 12. Application Example to Endoscopic Surgery System

The technology according to the present disclosure (present technology) can be applied to various products. For example, the technology according to the present disclosure may be applied to an endoscopic surgery system.

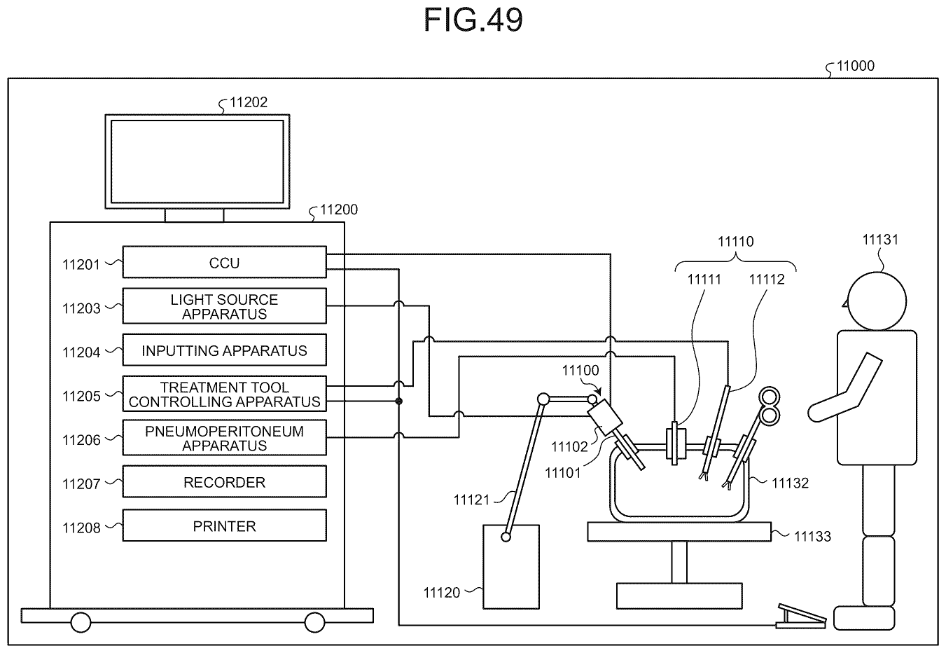

FIG. 49 is a view depicting an example of a schematic configuration of an endoscopic surgery system to which the technology according to an embodiment of the present disclosure (present technology) can be applied.

In FIG. 49, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

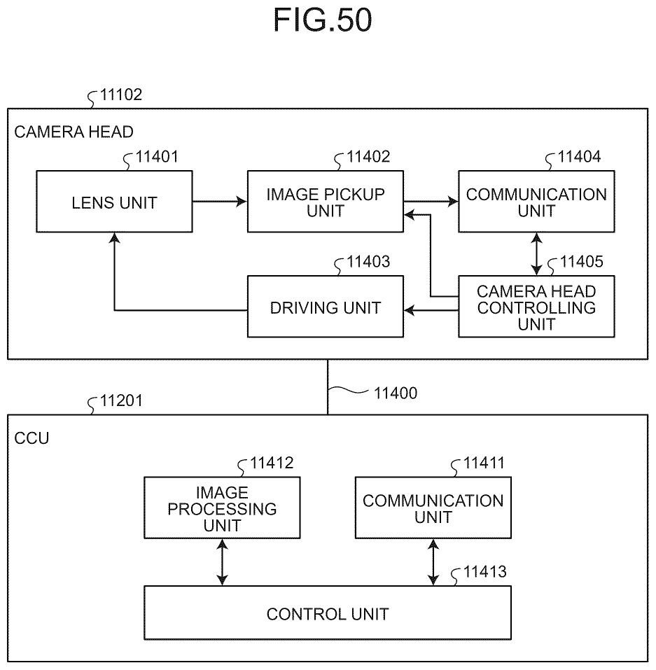

FIG. 50 is a block diagram depicting an example of a functional configuration of the camera head 11102 and the CCU 11201 depicted in FIG. 49.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of an endoscopic surgery system to which the technology according to the present disclosure can be applied has been described above. The technology according to the present disclosure can be applied to the endoscope 11100 or the image pickup unit 11402 of the camera head 11102 among the above-described components. Specifically, the imaging element 1 in FIG. 1 can be applied to the image pickup unit 11402. By applying the technology according to the present disclosure to the image pickup unit 11402, it is possible to prevent deterioration of the image quality of the image pickup unit 11402.

Note that, in this example, the endoscopic surgery system has been described as an example, however, the technology according to the present disclosure may be applied to other systems such as a microscopic surgery system.

Although the embodiments of the present disclosure have been described above, the technical scope of the present disclosure is not limited to the above embodiments as they are, and various modifications can be made without departing from the gist of the present disclosure. In addition, components of different embodiments and modifications may be combined as appropriate.

Note that the effects described herein are merely examples and are not limited, and other effects may also be achieved.

Note that the present technology can also have the following configurations.
(1) An imaging element comprising:
   a pixel including: a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate; and
   a signal generation section that generates a pixel signal, the pixel signal corresponding to the charge held in the charge holding section.
(2) The imaging element according to the above (1), wherein the charge holding section is disposed by being embedded in a well region formed in the semiconductor substrate.
(3) The imaging element according to the above (2), further comprising a reset section that discharges the charge being held, the reset section configured by a MOS transistor formed in a vicinity of a surface of the semiconductor substrate.
(4) The imaging element according to the above (3), further comprising a charge holding section connecting section that connects the charge holding section and a semiconductor region of the reset section.
(5) The imaging element according to any one of the above (1) to (4), wherein the pixel further includes a charge transfer section that transfers the charge generated by the photoelectric conversion to the charge holding section, the charge transfer section disposed by being embedded in the semiconductor substrate.
(6) The imaging element according to the above (5), wherein the charge transfer section is disposed in an isolation section formed at a boundary of the pixel.
(7) The imaging element according to any one of the above (1) to (6), further comprising an embedded electrode disposed by being embedded in the semiconductor substrate, the embedded electrode connected to a well region of the semiconductor substrate.
(8) The imaging element according to any one of the above (1) to (7), further comprising a charge holding section common electrode commonly connected to the charge holding sections of a plurality of the pixels adjacent to each other.
(9) The imaging element according to any one of the above (1) to (8), further comprising an element isolation region disposed between the photoelectric conversion section and the charge holding section.
(10) The imaging element according to any one of the above (1) to (9), further comprising a second semiconductor substrate in which the signal generation section is disposed, the second semiconductor substrate stacked on the semiconductor substrate.
(11) The imaging element according to the above (1), further comprising
   a wiring region disposed adjacent to a front surface of the semiconductor substrate,
   wherein the charge holding section has a shape adjacent to a side surface of an opening formed in the semiconductor substrate at a boundary of the pixel, the charge holding section disposed apart from a surface of the semiconductor substrate with which the wiring region is in contact.
(12) The imaging element according to the above (11), further comprising an embedded electrode disposed in the opening and apart from the surface of the semiconductor substrate with which the wiring region is in contact, the embedded electrode connected to the charge holding section.
(13) The imaging element according to the above (12),
   wherein the charge holding section is configured by a semiconductor region added with an impurity, the semiconductor region formed in the semiconductor substrate, and
   the embedded electrode is added with the impurity.
(14) The imaging element according to any one of the above (11) to (13),
   wherein the pixel further includes a charge transfer section that transfers the charge generated by the photoelectric conversion to the charge holding section, and
   the charge transfer section configured by a MOS transistor including a gate electrode having a shape that does not overlap with the opening when viewed from a normal direction of a surface of the semiconductor substrate.
(15) The imaging element according to any one of the above (11) to (14), wherein the charge holding section has a shape adjacent to a bottom portion of a step formed in the opening.
(16) An imaging element comprising:
   a pixel including a photoelectric conversion section that performs photoelectric conversion of incident light, the photoelectric conversion section formed in a semiconductor substrate with a wiring region disposed adjacent to the semiconductor substrate;
   a pixel circuit that generates a signal based on a charge generated by the photoelectric conversion;
   a semiconductor region adjacent to a side surface of an opening formed in the semiconductor substrate at a boundary of the pixel, the semiconductor region disposed apart from a surface of the semiconductor substrate with which the wiring region is in contact; and
   a second embedded electrode disposed in the opening and apart from the surface of the semiconductor substrate with which the wiring region is in contact, the second embedded electrode connected to the semiconductor region.
(17) The imaging element according to the above (16), wherein the semiconductor region is a semiconductor region of an element of the pixel circuit.
(18) The imaging element according to the above (16), wherein the semiconductor region is a well region of the semiconductor substrate.
(19) The imaging element according to the above (16), wherein the second embedded electrode is added with a same impurity as an impurity of the semiconductor region.
(20) The imaging element according to the above (8), further comprising:
   a plurality of the charge holding section common electrodes; and
   a charge holding section wire that connects a plurality of the charge holding sections to each other, the charge holding section wire disposed by being embedded in the semiconductor substrate at a boundary of the pixel.
(21) The imaging element according to the above (20), wherein the charge holding section wire is disposed in an isolation section formed at a boundary of the pixel.
(22) The imaging element according to the above (21), wherein the isolation section is configured by an insulating member disposed in an opening formed on a front surface of the semiconductor substrate.
(23) The imaging element according to the above (22), wherein the isolation section is disposed in the opening having a shape penetrating the semiconductor substrate.
(24) The imaging element according to any one of the above (20) to (23), wherein the pixel has a rectangular shape when viewed from a normal direction of a surface of the semiconductor substrate.
(25) The imaging element according to the above (24), wherein the pixel has a square shape when viewed from the normal direction of the surface of the semiconductor substrate.
(26) The imaging element according to any one of the above (20) to (25), wherein the charge holding section wire is made of polycrystalline silicon containing an impurity.
(27) The imaging element according to any one of the above (20) to (25), wherein the charge holding section wire is made of metal.
(28) The imaging element according to any one of the above (20) to (27), further comprising
   a wiring region disposed adjacent to a front surface of the semiconductor substrate,
   wherein the charge holding section wire is disposed apart from a surface of the semiconductor substrate with which the wiring region is in contact.
(29) The imaging element according to the above (28), wherein the charge holding section wire includes a wiring connection section for connection with another wire, the wiring connection section having a shape protruding from the front surface of the semiconductor substrate.
(30) The imaging element according to the above (16), further comprising:
   a plurality of the second embedded electrodes; and
   an embedded wire that connects the plurality of the second embedded electrodes to each other, the embedded wire disposed by being embedded in the semiconductor substrate at a boundary of the pixel.
(31) The imaging element according to the above (16), further comprising a second semiconductor substrate that is stacked on the semiconductor substrate and in which a part of the pixel circuit is disposed.
(32) An electronic device comprising:
   a pixel including: a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate;
   a signal generation section that generates a pixel signal, the pixel signal corresponding to the charge held in the charge holding section; and
   a processing circuit that processes the pixel signal generated.

### REFERENCE SIGNS LIST

1 IMAGING ELEMENT
90 PIXEL ARRAY SECTION
94 COLUMN SIGNAL PROCESSING SECTION
100 PIXEL BLOCK
101, 101a, 101b, 101c, 101d PHOTOELECTRIC CONVERSION SECTION
102, 102a, 102b, 102c, 102d CHARGE TRANSFER SECTION
103, 103a, 103b, 103c, 103d CHARGE HOLDING SECTION
110, 110a, 110b, 110c, 110d, 110e, 110f, 110g, 110h PIXEL
120 PIXEL CIRCUIT
121 AMPLIFICATION TRANSISTOR
122 SELECTION TRANSISTOR
123, 123a, 123b, 123c, 123d RESET TRANSISTOR
124 COUPLING TRANSISTOR
129 SIGNAL GENERATION SECTION
130, 230 SEMICONDUCTOR SUBSTRATE
131 to 134, 137, 138, 138a, 138b, 139, 181, 186, 231, 232 SEMICONDUCTOR REGION
135 CHARGE HOLDING SECTION CONNECTING SECTION
136 ELEMENT ISOLATION REGION
142, 144, 144′, 170 ISOLATION SECTION
143 EMBEDDED ELECTRODE
146, 147 ELECTRODE
145, 145a, 145b CHARGE HOLDING SECTION COMMON ELECTRODE
148, 149, 248 GATE ELECTRODE
150, 250 WIRING REGION
160 CHARGE HOLDING SECTION WIRE
161, 166 WIRING CONNECTION SECTION
165 EMBEDDED WIRE
179, 179a, 179b EMBEDDED ELECTRODE
182, 184 SIDEWALL
185 STEP
260 THROUGH WIRE

What is claimed is:

1. An imaging element, comprising:
a pixel including: a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate; and
a signal generation section that generates a pixel signal, the pixel signal corresponding to the charge held in the charge holding section.

2. The imaging element according to claim 1, wherein the charge holding section is disposed by being embedded in a well region formed in the semiconductor substrate.

3. The imaging element according to claim 2, further comprising a reset section that discharges the charge being held, the reset section configured by a MOS transistor formed in a vicinity of a surface of the semiconductor substrate.

4. The imaging element according to claim 3, further comprising a charge holding section connecting section that connects the charge holding section and a semiconductor region of the reset section.

5. The imaging element according to claim 1, wherein the pixel further includes a charge transfer section that transfers the charge generated by the photoelectric conversion to the charge holding section, the charge transfer section disposed by being embedded in the semiconductor substrate.

6. The imaging element according to claim 5, wherein the charge transfer section is disposed in an isolation section formed at a boundary of the pixel.

7. The imaging element according to claim 1, further comprising an embedded electrode disposed by being embedded in the semiconductor substrate, the embedded electrode connected to a well region of the semiconductor substrate.

8. The imaging element according to claim 1, further comprising a charge holding section common electrode commonly connected to the charge holding sections of a plurality of the pixels adjacent to each other.

9. The imaging element according to claim 1, further comprising an element isolation region disposed between the photoelectric conversion section and the charge holding section.

10. The imaging element according to claim 1, further comprising a second semiconductor substrate in which the signal generation section is disposed, the second semiconductor substrate stacked on the semiconductor substrate.

11. The imaging element according to claim 1, further comprising
a wiring region disposed adjacent to a front surface of the semiconductor substrate,
wherein the charge holding section has a shape adjacent to a side surface of an opening formed in the semiconductor substrate at a boundary of the pixel, the charge holding section disposed apart from a surface of the semiconductor substrate with which the wiring region is in contact.

12. The imaging element according to claim 11, further comprising an embedded electrode disposed in the opening and apart from the surface of the semiconductor substrate with which the wiring region is in contact, the embedded electrode connected to the charge holding section.

13. The imaging element according to claim 12,
wherein the charge holding section is configured by a semiconductor region added with an impurity, the semiconductor region formed in the semiconductor substrate, and
the embedded electrode is added with the impurity.

14. The imaging element according to claim 11,
wherein the pixel further includes a charge transfer section that transfers the charge generated by the photoelectric conversion to the charge holding section, and
the charge transfer section configured by a MOS transistor including a gate electrode having a shape that does not overlap with the opening when viewed from a normal direction of a surface of the semiconductor substrate.

15. The imaging element according to claim 11, wherein the charge holding section has a shape adjacent to a bottom portion of a step formed in the opening.

16. An imaging element, comprising:
a pixel including a photoelectric conversion section that performs photoelectric conversion of incident light, the photoelectric conversion section formed in a semiconductor substrate with a wiring region disposed adjacent to the semiconductor substrate;
a pixel circuit that generates a signal based on a charge generated by the photoelectric conversion;
a semiconductor region adjacent to a side surface of an opening formed in the semiconductor substrate at a boundary of the pixel, the semiconductor region disposed apart from a surface of the semiconductor substrate with which the wiring region is in contact; and
a second embedded electrode disposed in the opening and apart from the surface of the semiconductor substrate with which the wiring region is in contact, the second embedded electrode connected to the semiconductor region.

17. The imaging element according to claim 16, wherein the semiconductor region is a semiconductor region of an element of the pixel circuit.

18. The imaging element according to claim 16, wherein the semiconductor region is a well region of the semiconductor substrate.

19. The imaging element according to claim 16, wherein the second embedded electrode is added with a same impurity as an impurity of the semiconductor region.

20. The imaging element according to claim 8, further comprising:
a plurality of the charge holding section common electrodes; and
a charge holding section wire that connects a plurality of the charge holding sections to each other, the charge holding section wire disposed by being embedded in the semiconductor substrate at a boundary of the pixel.

21. The imaging element according to claim 20, wherein the charge holding section wire is disposed in an isolation section formed at a boundary of the pixel.

22. The imaging element according to claim 21, wherein the isolation section is configured by an insulating member disposed in an opening formed on a front surface of the semiconductor substrate.

23. The imaging element according to claim 22, wherein the isolation section is disposed in the opening having a shape penetrating the semiconductor substrate.

24. The imaging element according to claim 20, wherein the pixel has a rectangular shape when viewed from a normal direction of a surface of the semiconductor substrate.

25. The imaging element according to claim 24, wherein the pixel has a square shape when viewed from the normal direction of the surface of the semiconductor substrate.

26. The imaging element according to claim 20, wherein the charge holding section wire is made of polycrystalline silicon containing an impurity.

27. The imaging element according to claim 20, wherein the charge holding section wire is made of metal.

28. The imaging element according to claim 20, further comprising
a wiring region disposed adjacent to a front surface of the semiconductor substrate,
wherein the charge holding section wire is disposed apart from a surface of the semiconductor substrate with which the wiring region is in contact.

29. The imaging element according to claim 28, wherein the charge holding section wire includes a wiring connection section for connection with another wire, the wiring connection section having a shape protruding from the front surface of the semiconductor substrate.

30. The imaging element according to claim 16, further comprising:
a plurality of the second embedded electrodes; and
an embedded wire that connects the plurality of the second embedded electrodes to each other, the embedded wire disposed by being embedded in the semiconductor substrate at a boundary of the pixel.

31. The imaging element according to claim 16, further comprising a second semiconductor substrate that is stacked on the semiconductor substrate and in which a part of the pixel circuit is disposed.

32. An electronic device, comprising:
a pixel including: a photoelectric conversion section that performs photoelectric conversion of incident light, the photoelectric conversion section formed in a semiconductor substrate; and a charge holding section that holds a charge generated by the photoelectric conversion, the charge holding section disposed by being embedded in the semiconductor substrate;
a signal generation section that generates a pixel signal, the pixel signal corresponding to the charge held in the charge holding section; and
a processing circuit that processes the pixel signal generated.
